(19) United States
(12) Patent Application Publication
(10) Pub. No.: US 2026/0305430 A1
(43) Pub. Date: Oct. 1, 2026

(54) LAMINATE AND MANUFACTURING METHOD OF LAMINATE

(71) Applicant: FUJIFILM Corporation, Tokyo (JP)

(72) Inventor: Daisuke Kashiwagi, Shizuoka (JP)

(73) Assignee: FUJIFILM Corporation, Tokyo (JP)

(21) Appl. No.: 19/567,567

(22) Filed: Mar. 16, 2026

Related U.S. Application Data
(63) Continuation of application No. PCT/JP2024/033166, filed on Sep. 18, 2024.

(30) Foreign Application Priority Data
Sep. 22, 2023 (JP) 2023-158192

(51) Int. Cl. H10W 70/695; C08G 73/14; H10W 70/09; H10W 72/00; H10W 74/00; H10W 90/00; H10W 90/10

(52) U.S. Cl. CPC H10W 70/695; C08G 73/14; H10W 70/09; H10W 72/823; H10W 74/00; H10W 90/10; H10W 90/701

(57) ABSTRACT

There are provided a laminate including a sealing layer including a member having a circuit and a sealing material; a re-distribution layer A in contact with one surface of the sealing layer and connected to the circuit of the member; and a re-distribution layer B in contact with the other surface of the sealing layer and not directly connected to the circuit of the member, in which the re-distribution layer A and the re-distribution layer B are formed to be electrically connectable to other members, the re-distribution layer A includes an insulating pattern A and a conductive pattern A existing between patterns of the insulating pattern A, the re-distribution layer B includes an insulating pattern B and a conductive pattern B existing between patterns of the insulating pattern B, and the insulating pattern A is formed of a composition having a mass reduction rate of 10% or less when a cured product obtained by curing the composition at 230° C. for 3 hours is held at 250° C. for 1 hour, and a manufacturing method of a laminate.

### CROSS-REFERENCE TO RELATED APPLICATIONS

This application is a Continuation of PCT International Application No. PCT/JP2024/033166 filed on Sep. 18, 2024, which claims priority under 35 U.S.C § 119(a) to Japanese Patent Application No. 2023-158192 filed on Sep. 22, 2023. Each of the above application(s) is hereby expressly incorporated by reference, in its entirety, into the present application.

### BACKGROUND OF THE INVENTION

### 1. Field of the Invention

The present invention relates to a laminate and a manufacturing method of a laminate.

### 2. Description of the Related Art

Currently, a semiconductor package is used in a mobile phone, a tablet terminal, and various other electronic apparatuses. The semiconductor package is a case for protecting a delicate member such as a semiconductor chip or an electronic circuit from an external environment and mounting the member on a base material such as a printed wiring board. The semiconductor package has a function of transmitting a signal generated from the member to another device and transmitting a signal from the other device to the member.

In the mobile phone, the tablet terminal, and other electronic apparatuses, the size reduction, the weight reduction, and the multifunctionalization are advanced, and in order to meet the demand, there is a demand for further size reduction, high integration, high-density mounting, and the like in the semiconductor package, and for example, the progress of a wiring technique using a re-distribution layer is desired.

For example, US2023/0089795A discloses a semiconductor package including a semiconductor die, a sealing material that seals the semiconductor die, a connector disposed on the sealing material, a first conductive pad that is disposed on the sealing material, is in contact with the connector, and is disposed between the sealing material and the connector, a second conductive pad that is in contact with the re-distribution conductive layer, and a semiconductor member that is electrically connected to the second conductive pad, and having a bridge structure in which the first conductive pad is installed at a height lower than a height of the second conductive pad, a first interlayer dielectric layer is disposed on the semiconductor die and the re-distribution conductive layer, the first interlayer dielectric layer includes an opening portion, a part of the opening portion is occupied by a first conductive pad and a first electrical connector, a second interlayer dielectric layer and a third interlayer dielectric layer are disposed above the semiconductor die and below the first interlayer dielectric layer, a third conductive pad is disposed on the second interlayer dielectric layer, is covered by the first interlayer dielectric layer, is fitted in the second interlayer dielectric layer, is disposed on the third interlayer dielectric layer, and connects the first conductive pad and the third conductive pad, the bridge structure including a first conductive via, a routing line, and a second conductive via, in which the via and the first conductive via directly connect the first conductive pad and the routing line, the routing line directly connects the first conductive via and the second conductive via, the second conductive via directly connects the routing line and the third conductive pad, and a bottom surface of the entire routing line is in direct contact with an upper surface of the third interlayer dielectric layer.

### SUMMARY OF THE INVENTION

Here, in the laminate used in the semiconductor package or the like using the re-distribution layer, it is required to have excellent reliability over a long period of time. The reliability refers to a property of continuously exhibiting a required performance such as insulating properties and adhesiveness, and particularly refers to a property of continuously exhibiting the required performance such as the insulating properties and the adhesiveness even after an accelerated test under a high temperature and high humidity condition or the like.

An object of the present invention is to provide a laminate having excellent reliability over a long period of time and a manufacturing method of the laminate.

Examples of representative embodiments according to the present invention are described below.
<1> A laminate comprising:
a sealing layer including a member having a circuit and a sealing material;
a re-distribution layer Ain contact with one surface of the sealing layer and connected to the circuit of the member; and
a re-distribution layer B in contact with the other surface of the sealing layer and not directly connected to the circuit of the member,
wherein the re-distribution layer A and the re-distribution layer B are formed to be electrically connectable to other members,
the re-distribution layer A includes an insulating pattern A and a conductive pattern A existing between patterns of the insulating pattern A,
the re-distribution layer B includes an insulating pattern B and a conductive pattern B existing between patterns of the insulating pattern B, and
the insulating pattern A is formed of a composition having a mass reduction rate of 10% or less when a cured product obtained by curing the composition at 230° C. for 3 hours is held at 250° C. for 1 hour.
<2> The laminate according to <1>,
in which the member having the circuit is a functional die.
<3> The laminate according to <2>, further comprising:
a functional die electrically connected to the re-distribution layer A.
<4> The laminate according to <1>,
in which the member having the circuit is a wiring layer, and the laminate further includes two or more semiconductor devices electrically connected to the re-distribution layer A.
<5> The laminate according to any one of <1> to <4>, further comprising:
a circuit member connected to the re-distribution layer B and including wiring and an insulating layer.
<6> The laminate according to any one of <1> to <5>,
in which the re-distribution layer A and the re-distribution layer B are connected to each other through wiring.
<7> The laminate according to any one of <1> to <6>,
in which the re-distribution layer A includes two or more layers including the insulating pattern A and the conductive pattern A.
<8> The laminate according to any one of <1> to <7>,
in which the conductive pattern A includes a line pattern, and a minimum line width of the line pattern is 0.1 to 10 μm.
<9> The laminate according to any one of <1> to <8>,
in which a thickness of the re-distribution layer A is 1 to 100 μm.
<10> The laminate according to any one of <1> to <9>,
in which at least a part of the conductive pattern A has a barrier layer.
<11> The laminate according to any one of <1> to <10>, further comprising:
a connecting member A provided on a surface of the re-distribution layer A different from a surface of the re-distribution layer A in contact with the sealing layer.
<12> The laminate according to <11>,
in which the connecting member A has a substantially spherical cap shape.
<13> The laminate according to <12>,
in which a height of the connecting member A is 50 μm or less.
<14> The laminate according to <11>,
in which the connecting member A has a substantially columnar shape.
<15> The laminate according to <14>,
in which a height of the connecting member A is 20 μm or less.
<16> The laminate according to <11>,
in which the connecting member A includes a bonding pad structure having an average diameter of 5 μm or less.
<17> A manufacturing method of a laminate, comprising:
a sealing layer forming step of embedding a member having a circuit in a sealing material, and forming a sealing layer in which the circuit of the member is exposed on one surface and the circuit of the member is not exposed on the other surface;
a re-distribution layer A forming step of forming a re-distribution layer A, which includes an insulating pattern A and a conductive pattern A existing between patterns of the insulating pattern A, on the surface of the sealing layer on which the circuit is exposed; and
a re-distribution layer B forming step of forming a re-distribution layer B, which includes an insulating pattern B and a conductive pattern B existing between patterns of the insulating pattern B, on the surface of the sealing layer on which the circuit is not exposed,
in which the insulating pattern A has a mass reduction rate of 10% or less when held at 250° C. for 1 hour.
<18> The manufacturing method of a laminate according to <17>,
in which the member having the circuit is a functional die.
<19> The manufacturing method of a laminate according to <17>,
in which the member having the circuit is a wiring layer, and the manufacturing method further includes a step of bonding two or more functional dies to the re-distribution layer A.
<20> The manufacturing method of a laminate according to any one of <17> to <19>,
in which the re-distribution layer A forming step includes applying a composition for forming the insulating pattern A onto the sealing material to form a film.
<21> The manufacturing method of a laminate according to <20>,
in which the composition for forming the insulating pattern A contains a resin having at least one repeating unit selected from the group consisting of a repeating unit represented by Formula (2) and a repeating unit represented by Formula (4).

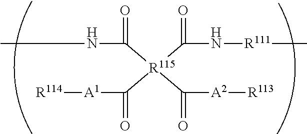

In Formula (2), A¹ and A² each independently represent an oxygen atom or —NR^{z}—, R¹¹¹ represents a divalent organic group, R¹¹⁵ represents a tetravalent organic group, R¹¹³ and R¹¹⁴ each independently represent a hydrogen atom or a monovalent organic group, and R^{z} represents a hydrogen atom or a monovalent organic group.

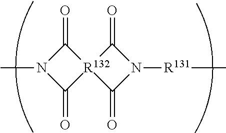

In Formula (4), R¹³¹ represents a divalent organic group, and R¹³² represents a tetravalent organic group.
<22> The manufacturing method of a laminate according to <20> or <21>,
in which the composition for forming the insulating pattern A includes at least one solvent selected from γ-butyrolactone, dimethyl sulfoxide, or N-methyl-2-pyrrolidone.
<23> The manufacturing method of a laminate according to any one of <20> to <22>,
in which the composition for forming the insulating pattern A further includes a polymerizable compound.
<24> The manufacturing method of a laminate according to <23>,
in which the polymerizable compound includes a compound having two or more ethylenically unsaturated bonds.
<25> The manufacturing method of a laminate according to <20> to <24>,
in which the composition for forming the insulating pattern A further includes a photopolymerization initiator.
<26> The manufacturing method of a laminate according to <25>,
in which the photopolymerization initiator includes an oxime compound.

According to the present invention, a laminate having excellent reliability over a long period of time and a manufacturing method of the laminate are provided.

### BRIEF DESCRIPTION OF THE DRAWINGS

FIGS. 1A to 1C are schematic cross-sectional views showing a specific example of a connecting member A.

FIG. 2 is a schematic cross-sectional view showing an example of a laminate according to the embodiment of the present invention.

FIG. 3 is a schematic cross-sectional view showing an example of a re-distribution layer A.

FIG. 4 is a schematic cross-sectional view showing another example of a laminate according to the embodiment of the present invention.

FIGS. 5A to 5D are schematic cross-sectional views showing an example of a manufacturing method of a laminate according to the embodiment of the present invention.

FIG. 6 is a schematic cross-sectional view showing another example of a manufacturing method of a laminate according to the embodiment of the present invention.

FIG. 7 is a schematic cross-sectional view showing another example of a manufacturing method of a laminate according to the embodiment of the present invention.

### DESCRIPTION OF THE PREFERRED EMBODIMENTS

Hereinafter, the main embodiments according to the present invention will be described. However, the present invention is not limited to the specified embodiments.

In the present specification, a numerical value range described by using “to” means a range including numerical values described before and after the preposition “to” as a lower limit value and an upper limit value, respectively.

In the present specification, the term “step” means not only an independent step but also a step that cannot be clearly distinguished from other steps as long as the desired action of the step can be achieved.

In describing a group (an atomic group) in the present specification, in a case where a description of substitution and unsubstitution is not provided, the description means the group includes a group (an atomic group) having a substituent as well as a group (an atomic group) having no substituent. For example, the “alkyl group” includes not only an alkyl group that does not have a substituent (an unsubstituted alkyl group) but also an alkyl group that has a substituent (a substituted alkyl group).

In the present specification, the “exposure” includes not only exposure using light but also exposure using corpuscular beams such as an electron beam and an ion beam, unless otherwise specified. In addition, examples of the light that is used for exposure include an actinic ray such as a bright line spectrum of a mercury lamp, a far ultraviolet ray represented by an excimer laser, an extreme ultraviolet ray (EUV light), an X-ray, or an electron beam, and a radioactive ray.

In the present specification, “(meth)acrylate” means one or both of “acrylate” and “methacrylate”, “(meth)acryl” means one or both of “acryl” and “methacryl”, and “(meth)acryloyl” means one or both of “acryloyl” and “methacryloyl”.

In the structural formulae of the present specification, Me represents a methyl group, Et represents an ethyl group, Bu represents a butyl group, and Ph represents a phenyl group.

In the present specification, the total solid content refers to the total mass of components excluding a solvent from the entire components of the composition. In addition, in the present specification, the concentration of solid contents is a mass percentage of other components excluding a solvent with respect to the total mass of the composition.

In the present specification, weight-average molecular weight (Mw) and number-average molecular weight (Mn) are each a value measured using gel permeation chromatography (GPC) unless otherwise specified, which are defined as a polystyrene equivalent value. In the present specification, the weight-average molecular weight (Mw) and the number-average molecular weight (Mn) can be determined, for example, by using HLC-8220 GPC (manufactured by Tosoh Corporation) and using GUARD COLUMN HZ-L, TSKgel Super HZM-M, TSK gel Super HZ4000, TSK gel Super HZ3000, and TSK gel Super HZ2000 (all of which are manufactured by Tosoh Corporation) as a column connected in series. The measurements of the above molecular weights are carried out using tetrahydrofuran (THF) as an eluent unless otherwise specified. However, N-methyl-2-pyrrolidone (NMP) can also be used in a case where THF is not suitable as the eluent, for example, in a case where the solubility is low. In addition, the detection in GPC measurement is carried out using a detector with an ultraviolet ray (a UV ray) of a wavelength of 254 nm unless otherwise specified.

In the present specification, in a case where the positional relationship of respective layers constituting the laminate is described as “upper” or “lower”, it suffices that another layer is on the upper side or the lower side of the reference layer among the plurality of layers of interest. That is, a third layer or element may be further interposed between the reference layer and the other layer, and the reference layer and the other layer need not be in contact with each other. Unless otherwise specified, the direction in which the layers are laminated on the base material (sealing layer) is referred to as “upward”, or in a case where a resin composition layer is present, the direction from the base material to the resin composition layer is referred to as “upper”. The opposite direction thereof is referred to as “downward”. Furthermore, such a setting of upward and downward directions is for convenience in the present specification, and in a practical aspect, the “upward” direction in the present specification may be different from a vertically upward direction.

In the present specification, a composition may contain, as each component contained in the composition, two or more compounds corresponding to the component unless otherwise specified. The content of each component in the composition means the total content of all the compounds corresponding to the component unless otherwise specified.

In the present specification, unless otherwise specified, the temperature is 23° C., the atmospheric pressure is 101,325 Pa (1 atm), and the relative humidity is 50% RH.

In addition, in the present specification, a combination of preferred aspects is a more preferred aspect.

### (Laminate)

A laminate according to the embodiment of the present invention (hereinafter, also simply referred to as a “laminate”) comprises a sealing layer including a member having a circuit and a sealing material; a re-distribution layer A in contact with one surface of the sealing layer and connected to the circuit of the member; and a re-distribution layer B in contact with the other surface of the sealing layer and not directly connected to the circuit of the member, in which the re-distribution layer A and the re-distribution layer B are formed to be electrically connectable to other members, the re-distribution layer A includes an insulating pattern A and a conductive pattern A existing between patterns of the insulating pattern A, the re-distribution layer B includes an insulating pattern B and a conductive pattern B existing between patterns of the insulating pattern B, and the insulating pattern A is formed of a composition having a mass reduction rate of 10% or less when a cured product obtained by curing the composition at 230° C. for 3 hours is held at 250° C. for 1 hour.

The laminate according to the embodiment of the present invention has excellent reliability over a long period of time.

Although the mechanism by which the above effect is obtained is not revealed, it is presumed as follows. In general, since outgas is generated from the insulating pattern A, the insulating pattern contracts due to long-term use. However, the amount of contraction is extremely small, and peeling does not occur between the insulating pattern A and the member in contact with the insulating pattern A, so it is unlikely that the device reliability is immediately deteriorated. It is considered that, due to the extremely small contraction, microcracks that cannot be detected in the insulating pattern A occur, moisture enters the microcracks as time elapses, and as a result, the partial corrosion of the member in contact with the insulating pattern A, that is, the wiring metal proceeds, which deteriorates the long-term reliability of the device.

In the present invention, the insulating pattern A is formed of a composition in which a mass reduction rate in a case of holding a cured substance cured at 230° C. for 3 hours at 250° C. for 1 hour is 10% or less. Therefore, it is considered that the insulating pattern A is less likely to contract further as compared with the conventional material, and since microcracks do not occur and moisture invasion is suppressed, the wiring metal is protected over a long period of time, which results in high long-term reliability.

Hereinafter, the laminate according to the embodiment of the present invention will be described in detail.

### <Sealing Layer>

It is preferable that the sealing layer includes a sealing material and a member having a circuit, and the member having a circuit is embedded in the sealing material.

### [Sealing Material]

The sealing material is not particularly limited, and a known material can be used, but it is preferably a material obtained by curing a curable composition (curable adhesive).

As the curable composition, various curable compositions such as a photocurable composition such as an ultraviolet curable type, a reactive curable composition such as an anaerobic curable type or a moisture curable type, and a thermosetting composition can be used. In addition, a two-liquid mixed composition, an adhesive sheet, or the like may be used.

As the curable composition, a curable resin composition is preferable, and examples of the resin used include an epoxy resin, a silicone resin, an acrylic resin, a phenol resin, a polyimide resin, an imide resin, a polyvinyl chloride (PVC) resin, a polyvinyl butyral (PVB) resin, and an ethylene vinyl acetate (EVA) resin.

The curable resin composition may further include other components such as a filler, a polymerization initiator, a curing agent, and a drying agent, in addition to the resin. As these components, components known in the related art can be used without particular limitation.

### [Member Having Circuit]

The member having a circuit is not particularly limited, and examples thereof include a functional die and a wiring layer.

It is preferable that, on one surface of the sealing layer, the circuit of the member having a circuit or the conductive member connected to the circuit is exposed, and it is preferable that, on one surface of the sealing layer, the circuit of the member having a circuit or the conductive member connected to the circuit is exposed, and on the other surface, neither the circuit nor the conductive member connected to the circuit is exposed.

In addition, it is preferable that the exposed circuit or the conductive member connected to the circuit is connected to the re-distribution layer A described later.

Examples of the conductive member include a conductive pad.

Examples of the material of the conductive member include copper, aluminum, nickel, vanadium, titanium, chromium, cobalt, gold, tungsten, tin, silver, and an alloy containing at least one of these metals, and copper, aluminum, or an alloy containing at least one of these metals is preferable, copper or an alloy containing copper is more preferable, and copper is still more preferable.

### —Functional Die—

In one aspect of the present invention, the member having a circuit is preferably a functional die.

In the present invention, the functional die refers to a chip in which a circuit is incorporated, and refers to a die that exhibits a function such as a memory and a logic.

The functional die is preferably a semiconductor chip. The functional die is obtained, for example, by forming a circuit pattern on a base material such as silicon and dicing the circuit pattern.

The functional die is not particularly limited, and examples thereof include a memory IC, a logic IC, an ASIC, and an integrated circuit obtained by further integrating these.

The number of functional dies sealed in the sealing layer is not particularly limited, and may be one or a plurality. However, an aspect in which the sealing layer includes only one functional die is also one of the preferred aspects of the present invention.

The size of the functional die is not particularly limited, and examples thereof include a functional die having one side of 100 μm to 10 cm.

### —Wiring Layer—

In another aspect of the present invention, the member having a circuit is preferably a wiring layer.

In the present invention, the wiring layer refers to a layer consisting of simple wiring that does not exhibit a function such as a memory and a logic.

The number of wiring layers sealed in the sealing layer is not particularly limited, and the sealing layer may have only one wiring layer that is electrically independent or may have a plurality of wiring layers that are electrically independent. The electrically independent wiring layer in the sealing layer means that the wiring layer may be electrically connected to a structure (for example, the conductive pattern A in the re-distribution layer A) outside the sealing layer.

The wiring layer may be a single layer or a layer consisting of a plurality of layers.

### —Conductive Portion—

It is preferable that the sealing layer further includes a conductive portion that causes the one surface and the other surface of the sealing layer to communicate with each other. Such a conductive portion is preferably included as, for example, a conductive through-via penetrating the sealing layer.

For example, the re-distribution layer A and the re-distribution layer B are connected to each other by the conductive portion.

The thickness of the sealing layer is not particularly limited, and may be determined in consideration of the thickness of the member having a circuit or the like, but is, for example, preferably 1 μm to 500 μm and more preferably 10 μm to 200 μm.

### <Re-Distribution Layer A>

The re-distribution layer A is a layer that is in contact with one surface of the sealing layer and is connected to the circuit of the member, and is a layer including the insulating pattern A and the conductive pattern A that is present between patterns of the insulating pattern A.

Here, the conductive pattern A is connected to the member having a circuit in the sealing layer.

For example, an aspect in which at least a part of the conductive pattern A and the circuit of the member having a circuit or the conductive member connected to the circuit, which are exposed on one surface of the sealing layer, are in contact with each other is also one of the preferred aspects.

### [Insulating Pattern A]

A volume resistivity of the insulating pattern A at 25° C. is not particularly limited, but is preferably 1×10⁸Ω ·cm or more, more preferably 1×10¹¹ Ω ·cm or more, and still more preferably 1×10¹² Ω·cm or more. The upper limit thereof is not particularly limited, but is, for example, preferably 1×10¹⁸ Ω ·cm or less.

The insulating pattern A preferably contains a resin, and more preferably includes a polyimide.

In addition, the insulating pattern A is preferably a cured substance of a composition for forming an insulating pattern A, which will be described later.

The insulating pattern A is formed of a composition in which a mass reduction rate in a case of holding a cured substance cured at 230° C. for 3 hours at 250° C. for 1 hour is 10% or less. The mass reduction rate is preferably 7.5% or less and more preferably 5% or less.

The lower limit of the mass reduction rate is not particularly limited, but is, for example, preferably 0% or more.

The mass reduction rate is calculated by measuring a mass (mass A) before (1) and a mass (mass B) after (2) by changing the temperature conditions in the order of (1) and (2) in a nitrogen atmosphere, and using the following expression.
(1) The temperature is raised from 25° C. to 250° C. at a rate of 10° C./min and maintained at 250° C. for 1 hour.
(2) The temperature is cooled to 25° C.

$$Mass reduction rate ( \% ) = ( 1 - mass B / mass A ) \times 100$$

The mass reduction rate can be adjusted by a structure, a content, and a content of a low-molecular-weight component of a specific resin, a polymerizable compound, and the like contained in the composition for forming an insulating pattern A, which will be described later.

The cured substance is produced by the following method.

First, the composition is applied to a silicon wafer. The application method is not particularly limited, but a spin coating method can be used. In addition, in a case where it is difficult to form a film having a film thickness of 15 μm, which will be described later, by one spin coating method, the spin coating method may be performed a plurality of times. In addition, even in this case, in a case where it is difficult to form a film having a film thickness of 15 μm by a spin coating method, a coating method may be appropriately selected from known methods such as a dip coating method, an air knife coating method, a curtain coating method, a wire bar coating method, a gravure coating method, an extrusion coating method, a spray coating method, a slit coating method, and an ink jet method.

In a case where the composition includes a solvent, the composition is dried after the application. In this case, a distance from the surface of the silicon wafer to the surface of the film after drying (that is, the film thickness) is 15 μm.

It is preferable that the drying is carried out until the amount of the solvent in the film is 0.5% by mass or less.

The drying conditions are not particularly limited, but can be carried out by drying with heating. In addition, in a case where it is difficult to sufficiently dry the composition only by heating, the pressure may be further reduced.

The drying can be carried out in the atmosphere. However, in a case where the resin composition contains a component or the like that is likely to be modified by oxygen, the treatment can also be carried out under an inert gas replacement such as nitrogen, under vacuum, or the like.

The drying means is not particularly limited, but can be performed by a hot plate. However, in a case where the above-described pressure reduction, inert gas replacement, and the like are required, an oven with a pressure reduction function, an oven with a gas replacement function, or the like can also be used.

In a case of carrying out drying by heating, the heating temperature (drying temperature) can be set to, for example, 100° C. However, in a case where it is difficult to dry at 100° C., the drying temperature may be appropriately changed to 70° C. to 130° C., preferably 90° C. to 120° C., depending on the kind or the like of the solvent contained in the resin composition.

In a case where the drying is performed by heating, the drying time (the time during which the heating is performed at the above-described heating temperature) can be, for example, 5 minutes. However, in a case where it is difficult to carry out drying for 5 minutes, the drying time may be appropriately changed to 30 seconds to 20 minutes, and preferably 1 minute to 10 minutes, depending on the kind or the like of the solvent contained in the resin composition.

In a case where the drying is performed by heating, the temperature rising rate during heating is not particularly limited, and for example, it can be set to 5° C./min. In a case where the drying at the above-described temperature rising rate is difficult, the temperature rising rate may be appropriately changed to 1 to 12° C./min or 2 to 10° C./min depending on the kind or the like of the solvent contained in the resin composition.

The entire surface of the coating film obtained by the above-described application and drying as necessary was exposed to i-rays with an exposure energy of 500 mJ/cm² using a stepper (Nikon NSR 2005 i9C). In addition to the i-rays by the stepper, for example, exposure with a laser can also be applied.

The composition layer (resin layer) after the exposure is cured by heating at 230° C. for 3 hours to form a cured substance (cured resin).

The heating can be carried out in an oven under a nitrogen atmosphere.

The pressure in the heating is set to 1 atm (101,325 Pa).

The temperature rising rate in the heating can be, for example, 10° C./min. In a case where the drying at the above-described temperature rising rate is difficult, the temperature rising rate may be appropriately changed to 1 to 12° C./min or 2 to 10° C./min depending on the kind or the like of the solvent contained in the resin composition.

The heating time (time exposed to 230° C.) in the above-described heating is set to 3 hours.

The silicon wafer on which the cured resin is formed by the above-described heating is immersed in a 4.9% by mass hydrofluoric acid aqueous solution, and the cured film is peeled off from the silicon wafer.

The mass reduction rate of the peeled cured film in a case of being held at 250° C. for 1 hour by the above-described method is measured.

The breaking elongation of the insulating pattern A is preferably 30% or more, more preferably 40% or more, and still more preferably 50% or more.

In addition, the breaking elongation of the cured resin film is preferably 30% or more, more preferably 40% or more, and still more preferably 50% or more.

The upper limit of the breaking elongation is not particularly limited, but is, for example, preferably 100% or less.

The breaking elongation is measured at 25° C. and 65% RH (relative humidity) in an environment using a tensile tester (TENSILON) at a crosshead speed of 300 mm/min, with reference to the method described in JIS-K6251.

The breaking elongation can be adjusted by a structure, a content, and the like of a resin, a polymerizable compound, and the like contained in the composition for forming an insulating pattern A, which will be described later.

The glass transition temperature of the insulating pattern A is preferably 215° C. to 275° C., more preferably 225° C. to 265° C., and still more preferably 235° C. to 255° C.

The glass transition temperature can be measured as a temperature of an intersection of a straight line obtained by extending a baseline on a low-temperature side in a differential scanning calorimetry curve to a high-temperature side and a tangent line drawn at a point where a gradient of a curve of a step-like change portion of the glass transition is maximized, by changing the temperature conditions of the insulating pattern A in the order of (1) to (4) and creating the differential scanning calorimetry curve.
(1) The temperature is raised from 25° C. to 300° C. at a rate of 10° C./min.
(2) Cooling is carried out from 300° C. to 25° C.
(3) The temperature is raised from 25° C. to 500° C. at a rate of 10° C./min.
(4) Cooling is carried out from 500° C. to 25° C.

The glass transition temperature can be adjusted by a structure, a content, and the like of a specific resin, a polymerizable compound, and the like contained in the composition for forming an insulating pattern A, which will be described later.

A coefficient of thermal expansion (CTE) of the insulating pattern A is preferably 20 to 80 ppm/K, more preferably 30 to 70 ppm/K, and still more preferably 40 to 60 ppm/K.

The coefficient of thermal expansion of the insulating pattern A is measured by the following method.

The insulating pattern A is measured for elongation (displacement) while changing the temperature using a thermal mechanical analyzer/thermal expansion coefficient measuring device Discovery TMA (manufactured by TA Instruments Japan Inc.).

The temperature rising and falling conditions at the time of evaluation are set to the following (1) to (4).
(1) The temperature is raised from room temperature to 130° C. at a temperature rising rate of 5° C./min.
(2) The temperature is cooled from 130° C. to 10° C. at a cooling rate of 5° C./min.
(3) The temperature is raised from 10° C. to 220° C. at a temperature rising rate of 5° C./min.
(4) The sample is naturally cooled to room temperature.

In the above-described temperature rising and falling processes (1) to (4), the elongation (displacement) of the specimen is measured, and a calculation is carried out to determine a value obtained by dividing the elongation (displacement) of the specimen at 25° C. and 125° C. in a longitudinal direction in the process (3) by the temperature, where the value is defined as the coefficient of thermal expansion.

The details of the measurement method can be referred to the method described in Examples described later.

### [Conductive Pattern A]

A volume resistivity of the conductive pattern A at 25° C. is not particularly limited, but is preferably 1×10⁻⁵ Ω ·cm or less, more preferably 1×10⁻⁶ Ω ·cm or less, and still more preferably 1×10⁻⁷ Ω ·cm or less. The lower limit thereof is not particularly limited, but is, for example, preferably 1×10⁻¹¹ Ω ·cm or more.

As a material constituting the conductive pattern A, a metal is preferable.

The metal is not particularly limited, and an existing metal can be used, but examples thereof include copper, aluminum, nickel, vanadium, titanium, chromium, cobalt, gold, tungsten, tin, silver, and an alloy containing at least one of these metals, and copper, aluminum, or an alloy containing at least one of these metals is preferable, copper or an alloy containing copper is more preferable, and copper is still more preferable.

The conductive pattern A preferably includes a line pattern. The line pattern is included, for example, as a line-and-space pattern in which the conductive pattern A is a line portion and the insulating pattern A is a space portion.

In a case where the conductive pattern A includes a line pattern, a minimum line width of the line pattern is preferably 0.1 to 10 μm, more preferably 0.2 to 8 μm, and still more preferably 0.3 to 5 μm.

It is preferable that the conductive pattern A has a barrier layer at least in a part thereof.

It is preferable that the conductive pattern A has a barrier layer at least at one of an interface between the conductive pattern A and the insulating pattern A or an interface between the re-distribution layer A and the outside (that is, a position where the conductive pattern A is exposed in the re-distribution layer A).

By having the barrier layer, it is possible to suppress the material (metal or the like) constituting the conductive pattern from being transferred (migrated) to the other members such as the insulating pattern A and the sealing layer.

The member constituting the barrier layer is not particularly limited, and examples thereof include tungsten, titanium, and an alloy containing at least one of these metals.

In addition, the barrier layer can be formed of a metal having a lower ionization tendency than the material constituting the conductive pattern A.

### [Configuration of Re-Distribution Layer A]

The re-distribution layer A is formed to be electrically connectable to other members.

Specifically, the re-distribution layer A can have an aspect in which the conductive pattern A is exposed on the surface of the re-distribution layer A on a surface different from the surface in contact with the sealing layer, or the barrier layer in contact with the conductive pattern A is exposed.

For example, the exposed conductive pattern A or the barrier layer is connected to a connecting member A described later, whereby the re-distribution layer A is electrically connected to the other members.

In addition, the re-distribution layer A may include a conductive pad in the outermost layer (that is, the layer farthest from the sealing layer).

As a material of the conductive pad, a metal is preferable.

The metal is not particularly limited, and an existing metal can be used, but examples thereof include copper, aluminum, nickel, vanadium, titanium, chromium, cobalt, gold, tungsten, tin, silver, and an alloy containing at least one of these metals, and copper, aluminum, or an alloy containing at least one of these metals is preferable, copper or an alloy containing copper is more preferable, and copper is still more preferable.

In a case where the conductive pad is provided, the conductive pattern A is electrically connected to the other members via the conductive pad.

It is preferable that the re-distribution layer A and the re-distribution layer B are connected to each other through wiring.

Specifically, it is preferable that the conductive pattern A included in the re-distribution layer A and the conductive pattern B included in the re-distribution layer B are electrically connected to each other through wiring, and it is more preferable that the conductive pattern A included in the re-distribution layer A and the conductive pattern B included in the re-distribution layer B are connected to each other via the conductive portion included in the above-described sealing layer.

The re-distribution layer A may include two or more layers including the insulating pattern A and the conductive pattern A.

Specifically, for example, it is preferable that the re-distribution layer A includes 2 to 20 layers including the insulating pattern A and the conductive pattern A, and it is more preferable that the re-distribution layer A includes 3 to 10 layers including the insulating pattern A and the conductive pattern A.

A thickness of the re-distribution layer A is preferably 1 to 100 μm, more preferably 1 to 50 μm, and still more preferably 1 to 20 μm.

### <Re-Distribution Layer B>

The re-distribution layer B is a layer that is in contact with the other surface of the sealing layer and is not directly connected to the circuit of the member, and is a layer including the insulating pattern B and the conductive pattern B that is present between patterns of the insulating pattern B.

Here, the fact that the conductive pattern B is not directly connected to the member having a circuit in the sealing layer means that the conductive pattern B and the circuit of the member having a circuit or the above-described conductive member are not in contact with each other.

The conductive pattern B need not be directly connected to the member having a circuit, and may be electrically connected to the member having a circuit via another member. For example, it is preferable that the re-distribution layer B is electrically connected to the member having a circuit via the conductive pattern A or the like in the above-described re-distribution layer A.

For example, an aspect in which the re-distribution layer B is formed to be in contact with a surface of the member having a circuit in the above-described sealing layer on which the circuit or the conductive member connected to the circuit is not exposed, and the re-distribution layer A and the re-distribution layer B are electrically connected to each other via the above-described conductive through-via is also one of the preferred aspects of the present invention.

### [Insulating Pattern B]

A volume resistivity of the insulating pattern B at 25° C. is not particularly limited, but is preferably 1×10⁸ Ω ·cm or more, more preferably 1×10¹⁰ Ω ·cm or more, and still more preferably 1×10¹² Ω·cm or more. The upper limit thereof is not particularly limited, but is, for example, preferably 1×10¹⁸ Ω ·cm or less.

The insulating pattern B preferably contains a resin, and more preferably includes a polyimide.

In addition, the insulating pattern B is preferably a cured substance of a composition for forming an insulating pattern A, which will be described later.

### [Conductive Pattern B]

A volume resistivity of the conductive pattern B at 25° C. is not particularly limited, but is preferably 1×10⁻⁵ Ω ·cm or less, more preferably 1×10⁻⁶ Ω ·cm or less, and still more preferably 1×10⁻⁷ Ω ·cm or less. The lower limit thereof is not particularly limited, but is, for example, preferably 1×10⁻¹¹ Ω ·cm or more.

As a material constituting the conductive pattern B, a metal is preferable.

The metal is not particularly limited, and an existing metal can be used, but examples thereof include copper, aluminum, nickel, vanadium, titanium, chromium, cobalt, gold, tungsten, tin, silver, and an alloy containing at least one of these metals, and copper, aluminum, or an alloy containing at least one of these metals is preferable, copper or an alloy containing copper is more preferable, and copper is still more preferable.

The conductive pattern B preferably includes a line pattern. The line pattern is included, for example, as a line-and-space pattern in which the conductive pattern B is a line portion and the insulating pattern B is a space portion.

In a case where the conductive pattern B includes a line pattern, a minimum line width of the line pattern is preferably 0.1 to 10 μm, more preferably 0.2 to 8 μm, and still more preferably 0.3 to 5 μm.

It is preferable that the conductive pattern B has a barrier layer at least in a part thereof.

It is preferable that the conductive pattern B has a barrier layer at least at one of an interface between the conductive pattern B and the insulating pattern B or an interface between the re-distribution layer B and the outside (that is, a position where the conductive pattern B is exposed in the re-distribution layer B).

By having the barrier layer, it is possible to suppress the material (metal or the like) constituting the conductive pattern from being transferred (migrated) to the other members such as the insulating pattern B and the sealing layer.

The member constituting the barrier layer is not particularly limited, and examples thereof include tungsten, titanium, and an alloy containing at least one of these metals.

In addition, the barrier layer can be formed of a metal having a lower ionization tendency than the material constituting the conductive pattern B.

### [Configuration of Re-Distribution Layer B]

The re-distribution layer B is formed to be electrically connectable to other members.

Specifically, the re-distribution layer B can have an aspect in which the conductive pattern B is exposed on the surface of the re-distribution layer B on a surface different from the surface in contact with the sealing layer, or the barrier layer in contact with the conductive pattern B is exposed.

For example, the exposed conductive pattern B or the barrier layer is connected to a connecting member B described later, whereby the re-distribution layer B is electrically connected to the other members.

In addition, the re-distribution layer B may include a conductive pad in the outermost layer (that is, the layer farthest from the sealing layer).

As a material of the conductive pad, a metal is preferable.

The metal is not particularly limited, and an existing metal can be used, but examples thereof include copper, aluminum, nickel, vanadium, titanium, chromium, cobalt, gold, tungsten, tin, silver, and an alloy containing at least one of these metals, and copper, aluminum, or an alloy containing at least one of these metals is preferable, copper or an alloy containing copper is more preferable, and copper is still more preferable.

In a case where the conductive pad is provided, the conductive pattern B is electrically connected to the other members via the conductive pad.

The re-distribution layer B may include two or more layers including the insulating pattern B and the conductive pattern B.

Specifically, for example, it is preferable that the re-distribution layer B includes 2 to 20 layers including the insulating pattern B and the conductive pattern B, and it is more preferable that the re-distribution layer B includes 3 to 10 layers including the insulating pattern B and the conductive pattern B.

A thickness of the re-distribution layer B is preferably 1 to 100 μm, more preferably 1 to 50 μm, and still more preferably 1 to 20 μm.

### <Other Functional Dies>

The laminate may further include other functional dies that are electrically connected to the re-distribution layer A.

A preferred aspect of the other functional die is the same as the preferred aspect of the functional die included in the above-described sealing layer, except that the other functional die is not sealed in the sealing layer.

It is preferable that the other functional die is connected to a surface of the re-distribution layer A different from the surface in contact with the sealing layer.

Specifically, it is preferable that the other functional die is connected to a connecting member A described later.

In a case where the member having a circuit is the functional die, it is preferable that the laminate further comprises other functional dies that are electrically connected to the re-distribution layer A.

In such an aspect, the number of the other functional dies may be 1 or more, and is preferably 2 or more and more preferably 3 or more.

In such an aspect, in a case where two or more functional dies are included, the functional dies may be the same or different from each other.

In a case where the member having a circuit is the wiring layer, it is preferable that the laminate further comprises two or more other functional dies that are electrically connected to the re-distribution layer A.

In such an aspect, the number of the other functional dies may be 2 or more, and is preferably 5 or more and more preferably 10 or more.

In such an aspect, the functional dies may be the same or different from each other.

### <Circuit Member>

The laminate according to the embodiment of the present invention may further include a circuit member that is connected to the re-distribution layer B and includes wiring and an insulating layer.

Examples of the circuit member include a substrate on which a circuit is formed. The circuit member may further have a connection portion with another member on a surface different from a surface connected to the re-distribution layer B.

With such an aspect, it is also possible to easily manufacture a device in which a plurality of the laminates according to the embodiment of the present invention are further connected to another substrate.

### <Connecting Member A>

The laminate according to the embodiment of the present invention may further include a connecting member A on a surface of the re-distribution layer A different from the surface in contact with the sealing layer.

The connecting member A preferably has a substantially spherical cap shape, a substantially columnar shape, or a bonding pad structure having an average diameter of 5 μm or less.

In addition, the laminate according to the embodiment of the present invention may include a barrier layer between the re-distribution layer A and the connecting member A.

In a case where the connecting member A has a substantially spherical cap shape, the connecting member A is preferably a solder ball, a ball grid array (BGA) ball, or a C4 bump.

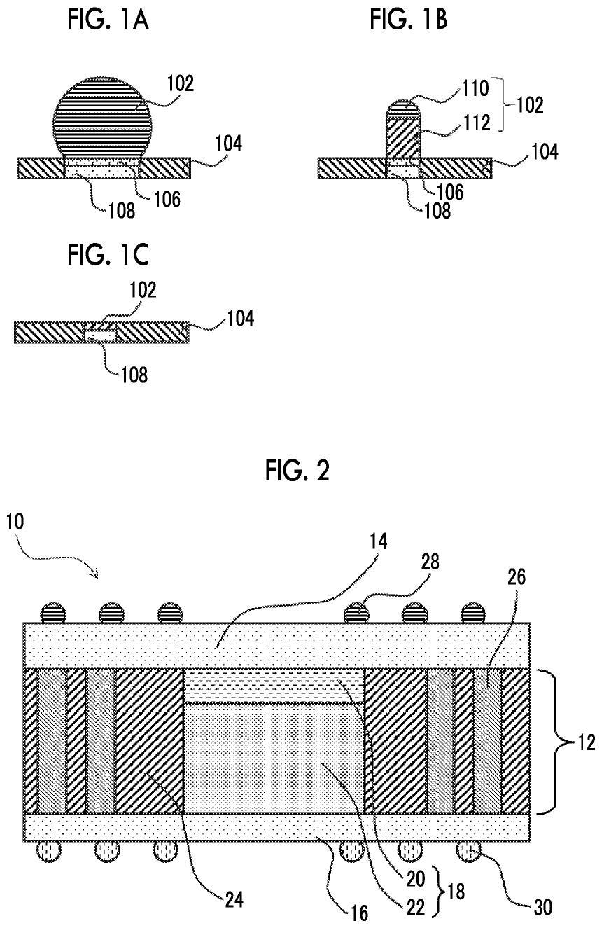

FIG. 1A is a schematic cross-sectional view in a case where the connecting member A has a substantially spherical cap shape.

In FIG. 1A, a connecting member A102 is connected to a conductive pattern A108 via a barrier layer 106, and the conductive pattern A108 is formed between insulating patterns A104.

Here, the insulating pattern A104 and the conductive pattern A108 are described in a simplified manner, but in reality, it is preferable that the insulating pattern A104 and the conductive pattern A108 are further laminated on a surface opposite to the connecting member A102. The barrier layer 106 may not be provided. This is the same in FIGS. 1B and 1C.

In a case where the connecting member A has a substantially spherical cap shape, a material constituting the connecting member A is not particularly limited, but is preferably Sn, Pb, Ag, Cu, Ni, Bi, or an alloy containing any of these.

In a case where the connecting member A has a substantially spherical cap shape, a height of the connecting member A is preferably 50 μm or less, more preferably 20 to 50 μm, and still more preferably 20 to 40 μm.

In a case where the connecting member A has a substantially columnar shape, the connecting member A is preferably a pillar having a solder member on an upper portion.

FIG. 1B is a schematic cross-sectional view in a case where the connecting member A has a substantially columnar shape.

In FIG. 1B, the connecting member A102 is a member consisting of a solder member 110 and a pillar 112.

In FIG. 1B, the solder member 110 is shown in a hemispherical shape, but the shape is not particularly limited, and the shape may be a shape having a flat upper portion, such as a cylindrical shape.

In FIG. 1B, the connecting member A102 is connected to the conductive pattern A108 via the barrier layer 106, and the conductive pattern A108 is formed between the insulating patterns A104.

In a case where the connecting member A has a substantially columnar shape, a material constituting the pillar is not particularly limited, but is preferably Sn, Pb, Ag, Cu, Ni, Bi, or an alloy containing any of these, and more preferably Cu.

In a case where the solder member is included, a material constituting the solder member is not particularly limited, but is preferably Sn, Pb, Ni, Bi, or an alloy containing any of these.

In a case where the connecting member A has a substantially columnar shape, a height of the connecting member A is preferably 20 μm or less, more preferably 10 to 20 μm, and still more preferably 10 to 15 μm.

In a case where the connecting member A has a bonding pad structure having an average diameter of 5 μm or less, it is preferable that the connecting member A is formed to have the same height as the insulating pattern A such that the connecting member A and the insulating member are substantially flat.

FIG. 1C is a schematic cross-sectional view in a case where the connecting member A has a bonding pad structure having an average diameter of 5 μm or less.

In FIG. 1C, the connecting member A102 is connected to the conductive pattern A108, and the conductive pattern A108 is formed between the insulating patterns A104.

In a case where the connecting member A has a bonding pad structure having an average diameter of 5 μm or less, a material constituting the bonding pad structure is not particularly limited, but is preferably Sn, Pb, Ag, Cu, Ni, Bi, or an alloy containing any of these, and more preferably Cu.

In a case where the connecting member A has a bonding pad structure having an average diameter of 5 μm or less, the average diameter is 5 μm or less, and is preferably 1 to 5 m and more preferably 2 to 5 μm.

The average diameter is an average diameter of an upper surface of the bonding pad structure. In a case where the upper surface of the bonding pad structure is not circular, the average diameter refers to an average value of the equivalent circle diameter.

### <Connecting Member B>

The laminate according to the embodiment of the present invention may further include a connecting member B on a surface of the re-distribution layer B different from the surface in contact with the sealing layer.

A preferred aspect of the connecting member B is the same as the preferred aspect of the connecting member A, except that the connecting member B is formed on the re-distribution layer B.

### <Specific Examples of Laminate>

Hereinafter, specific examples of the aspects of the laminate according to the embodiment of the present invention will be described with reference to the drawings, but the present invention is not limited thereto.

FIG. 2 is a schematic cross-sectional view showing an example of the laminate according to the embodiment of the present invention.

In FIG. 2, a laminate 10 includes a sealing layer 12, a re-distribution layer A14, and a re-distribution layer B16.

In FIG. 2, the thickness of each layer is changed as appropriate to facilitate checking the drawings, and in reality, for example, the thickness of the re-distribution layer A14 is, for example, several tens to several hundredths of the thickness of the sealing layer 12, and the scale may be different from the actual scale.

The sealing layer 12 includes a member 18 having a circuit, a sealing material 24, and a conductive through-via 26.

The member 18 having a circuit includes a semiconductor member 22 and a circuit 20, and the circuit 20 is connected to the re-distribution layer A.

The member 18 having a circuit is described as a functional die including the semiconductor member 22, but in a case where the member 18 having a circuit is a wiring layer, the member 18 having a circuit may be composed of only the circuit 20, and the semiconductor member 22 may not be present.

Although not shown in FIG. 2, the re-distribution layer A14 includes the insulating pattern A and the conductive pattern A that is present between the patterns of the insulating pattern A. In addition, the re-distribution layer B16 includes the insulating pattern B and the conductive pattern B that is present between the patterns of the insulating pattern B.

The conductive through-via 26 is formed as a through-via penetrating the sealing layer, and causes the conductive pattern A and the conductive pattern B to communicate with each other.

Here, the circuit 20 and the re-distribution layer A14 are directly connected to each other, but the circuit 20 and the re-distribution layer B16 are not directly connected to each other and are connected to each other via the re-distribution layer A.

In addition, in FIG. 2, a connecting member A28 is formed on the re-distribution layer A, and a connecting member B30 is formed on the re-distribution layer B. The connecting member A28 is connected to the conductive pattern A, and the connecting member B30 is connected to the conductive pattern B. In FIG. 2, the connecting member A28 and the connecting member B30 are described as substantially spherical cap shapes, but as described above, the connecting member A28 and the connecting member B30 may have other shapes such as substantially columnar shapes and bonding pads.

In addition, in FIG. 2, the connecting member A28 is described for describing the positional relationship, but the connecting member A28 may be formed immediately before bonding to other functional dies or the like.

Further, in FIG. 2, the connecting member B30 is described for describing the positional relationship, but the connecting member B30 may be formed immediately before bonding to other circuit members or the like.

According to such a laminate 10, the re-distribution layer A14 can be connected to other functional dies via the connecting member A28, and the re-distribution layer B16 can be connected to the circuit member via the connecting member B30.

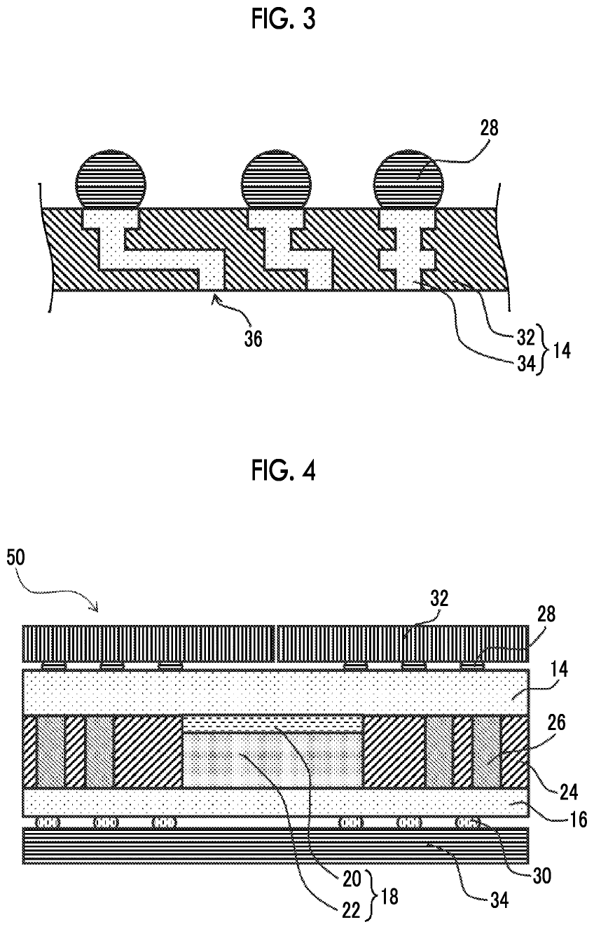

Details of the re-distribution layer A14 and the connecting member A28, which are not shown in FIG. 2, will be described with reference to FIG. 3.

FIG. 3 is a schematic cross-sectional view showing an example of the re-distribution layer A14 on which the connecting member A28 is formed.

The re-distribution layer A14 includes a conductive pattern A34 and an insulating pattern A32. Here, in FIG. 3, the re-distribution layer A14 is described as a re-distribution layer including a total of four layers consisting of the conductive pattern A and the insulating pattern A. A surface 36 on a side opposite to the connecting member A28 of the conductive pattern A is connected to the circuit 20 in FIG. 2.

FIG. 4 is a schematic cross-sectional view showing another example of the laminate according to the embodiment of the present invention.

Among the members to which reference numerals are assigned in FIG. 4, the members to which the same reference numerals as those in FIG. 2 are assigned are the same members as the members in FIG. 2.

In a laminate 50 in FIG. 4, two of other functional dies 32 are connected to the re-distribution layer A14, and a circuit member 34 is connected to the re-distribution layer B16.

In this aspect, it goes without saying that the member 18 having a circuit may be a functional die including the semiconductor member 22, and in a case where the member 18 having a circuit is a wiring layer, the member 18 having a circuit may be composed of only the circuit 20, and the semiconductor member 22 may not be present.

Here, a known underfill material may be filled in a space between the re-distribution layer A14 and the functional die 32.

In addition, a known underfill material may be filled in a space between the re-distribution layer B16 and the circuit member 34.

A known connecting member such as a solder ball may be further formed on a surface of the circuit member 34 opposite to the re-distribution layer B16.

### (Method for Manufacturing Laminate)

A manufacturing method of a laminate according to the embodiment of the present invention includes a sealing layer forming step of embedding a member having a circuit in a sealing material, and forming a sealing layer in which the circuit of the member is exposed on one surface and the circuit of the member is not exposed on the other surface; a re-distribution layer A forming step of forming a re-distribution layer A, which includes an insulating pattern A and a conductive pattern A existing between patterns of the insulating pattern A, on the surface of the sealing layer on which the circuit is exposed; and a re-distribution layer B forming step of forming a re-distribution layer B, which includes an insulating pattern B and a conductive pattern B existing between patterns of the insulating pattern B, on the surface of the sealing layer on which the circuit is not exposed, in which the insulating pattern A has a mass reduction rate of 10% or less when held at 250° C. for 1 hour.

According to the manufacturing method of a laminate according to the embodiment of the present invention, the above-described laminate according to the embodiment of the present invention can be obtained. That is, a laminate having excellent reliability over a long period of time can be obtained.

### <Sealing Layer Forming Step>

The manufacturing method of a laminate according to the embodiment of the present invention includes a sealing layer forming step.

By the sealing layer forming step, a sealing layer including a sealing material and a member having a circuit embedded in the sealing material is obtained, in which a circuit of the member is exposed on one surface and the circuit of the member is not exposed on the other surface.

In the sealing layer forming step, for example, the member having a circuit is disposed on a carrier wafer (temporary support), and the above-described curable composition is applied to embed the member having a circuit and cured, whereby the sealing layer forming step can be performed.

In addition, a known temporary adhesive layer may be formed on the carrier wafer.

The application and curing thereof can be performed with reference to known methods.

The preferred aspects of the curable composition and the member having a circuit are as described above.

An aspect in which the member having a circuit is the above-described functional die is also one of the preferred aspects of the present invention.

In addition, an aspect in which the member having a circuit is the above-described wiring layer and the manufacturing method of a laminate according to the embodiment of the present invention further includes a functional die lamination step described later is also one of the preferred aspects of the present invention.

In addition, in the sealing layer forming step, the surface of the sealing material may be polished after the curing.

Examples of the polishing include chemical mechanical polishing (CMP) and physical polishing, but the present invention is not limited thereto.

For example, by polishing the cured sealing material on a surface side of the member having a circuit on which the circuit is provided, the circuit of the member having a circuit can be exposed to the surface of the sealing layer.

In addition, as the sealing layer forming step, a known method in the present field can be used without particular limitation as long as the sealing layer is formed.

In addition, in the sealing layer forming step, the circuit of the member having a circuit may be exposed from the sealing layer by not performing polishing and simply not sealing the surface on which the circuit of the member having a circuit is disposed.

A preferred aspect of the sealing layer obtained by the sealing layer forming step is the same as the preferred aspect of the sealing layer in the above-described laminate according to the embodiment of the present invention.

However, in the sealing layer forming step, the conductive portion is not formed, and as described later, the conductive portion may be formed after at least one of the re-distribution layer A forming step or the re-distribution layer B forming step.

### <Passivation Layer Forming Step>

The manufacturing method of a laminate according to the embodiment of the present invention may further include a passivation layer forming step of forming a passivation layer after the sealing layer forming step.

The passivation layer forming step is preferably performed after the sealing layer forming step and before the re-distribution layer A forming step.

The passivation layer is formed by coating the surface of the member having a circuit with an inert film. By forming the passivation layer, the influence of the outside air on the member having a circuit, the adhesion of dust, and the contamination by water or metal may be suppressed.

A material of the passivation layer is not particularly limited, and examples thereof include SiO₂ and SiN. In addition, a resin such as polyimide may be used.

The coating method is not particularly limited, and a known method can be used. For example, in a case of coating SiN, the passivation layer forming step can be performed by chemical vapor deposition (CVD) or the like.

### <Re-Distribution Layer a Forming Step>

The manufacturing method of a laminate according to the embodiment of the present invention includes a re-distribution layer A forming step of forming a re-distribution layer A including an insulating pattern A and a conductive pattern A that is present between patterns of the insulating pattern A on a surface of the sealing layer on which the circuit is exposed.

By the re-distribution layer A forming step, the re-distribution layer A is formed on the surface of the sealing material on which the circuit is exposed. A preferred aspect of the re-distribution layer A is the same as the preferred aspect of the re-distribution layer A in the above-described laminate according to the embodiment of the present invention.

The re-distribution layer A forming step preferably includes applying a composition for forming an insulating pattern A to a sealing layer to form a film (film forming step).

In addition, the re-distribution layer A forming step more preferably includes the film forming step, an exposure step of selectively exposing the film formed by the film forming step, and a development step of developing the exposed film using a developer to form a pattern.

It is particularly preferable that the re-distribution layer A forming step includes the film forming step, the exposure step, the development step, and at least one of a heating step of heating a pattern obtained by the development step or a post-development exposure step of exposing the pattern obtained by the development step.

Hereinafter, details of each step will be described. In addition, details of the composition for forming an insulating pattern A (hereinafter, also simply referred to as a “composition”) will be described later.

### <Film Forming Step>

The re-distribution layer A forming step preferably includes a film forming step of applying the composition to the sealing layer to form a film.

As a method of applying the composition to the sealing layer, coating is preferable.

Specific examples of the means for application include a dip coating method, an air knife coating method, a curtain coating method, a wire bar coating method, a gravure coating method, an extrusion coating method, a spray coating method, a spin coating method, a slit coating method, and an ink jet method. From the viewpoint of the uniformity of the film thickness, a spin coating method, a slit coating method, a spray coating method, or an ink jet method is more preferable, and from the viewpoint of the uniformity of the film thickness and the viewpoint of productivity, a spin coating method or a slit coating method is more preferable. A film having a desired thickness can be obtained by adjusting the concentration of solid contents of the composition and application conditions according to the means to be applied. In addition, the coating method can be appropriately selected depending on the shape of the base material. In a case where a circular base material such as a wafer is used, a spin coating method, a spray coating method, an ink jet method, or the like is preferable, and in a case where a rectangular base material is used, a slit coating method, a spray coating method, an ink jet method, or the like is preferable. For example, the spin coating method can be applied at a rotation speed of 500 to 3,500 rpm for about 10 seconds to 3 minutes.

In addition, it is also possible to apply a method of transferring a coating film formed in advance on a temporary support by the above-described coating method, onto a sealing layer.

Regarding the transfer method, the production methods described in paragraphs 0023 and 0036 to 0051 of JP2006-023696A and paragraphs 0096 to 0108 of JP2006-047592A can also be suitably used.

In addition, a step of removing an excess film at an end part of the sealing layer may be performed. Examples of such a step include edge bead rinsing (EBR) and back rinsing.

A pre-wetting step of applying various solvents to the substrate before applying the composition to the sealing layer to improve wettability of the sealing layer and then applying the composition may be adopted.

### <Drying Step>

The above film may be subjected to a step (a drying step) of drying the film (or the layer) formed for removing the solvent, after the film forming step (the layer forming step).

That is, the re-distribution layer A forming step may include a drying step of drying the film formed by the film forming step.

It is preferable that the drying step is carried out after the film forming step and before the exposure step.

The drying temperature of the film in the drying step is preferably 50° C. to 150° C., more preferably 70° C. to 130° C., and still more preferably 90° C. to 110° C. In addition, the drying may be carried out by reducing the pressure. Examples of the drying time include 30 seconds to 20 minutes, and the drying time is preferably 1 minute to 10 minutes and more preferably 2 minutes to 7 minutes.

### <Exposure Step>

The film may be subjected to an exposure step of selectively exposing the film.

The re-distribution layer A forming step may include an exposure step of selectively exposing the film formed by the film forming step.

The selective exposure means that a part of the film is exposed. In addition, by selectively exposing the film, an exposed region (an exposed portion) and an unexposed region (a non-exposed portion) are formed in the film.

An exposure amount is not particularly limited as long as the film can be cured, but is, for example, preferably 50 to 10,000 mJ/cm² and more preferably 200 to 8,000 mJ/cm² in terms of exposure energy at a wavelength of 365 nm.

The exposure wavelength can be appropriately determined in a range of 190 to 1,000 nm and preferably in a range of 240 to 550 nm.

Examples of the exposure wavelength, which are mentioned in the relationship with the light source, include (1) a semiconductor laser (wavelength: 830 nm, 532 nm, 488 nm, 405 nm, 375 nm, 355 nm, or the like); (2) a metal halide lamp; (3) a high pressure mercury lamp, a g-line (wavelength: 436 nm), an h-line (wavelength: 405 nm), an i-line (wavelength: 365 nm), or broadband light (three wavelengths of the g, h, and i-line); (4) an excimer laser, a KrF excimer laser (wavelength: 248 nm), an ArF excimer laser (wavelength: 193 nm), or an F₂ excimer laser (wavelength: 157 nm); (5) an extreme ultraviolet ray: EUV (wavelength: 13.6 nm); (6) an electron beam; and (7) a second harmonic wave of 532 nm and a third harmonic wave of 355 nm of a YAG laser. Exposure with a high-pressure mercury lamp is particularly preferable, and exposure with i-rays is more preferable from the viewpoint of exposure sensitivity.

A method of the exposure is not particularly limited, and any method in which at least a part of the film is exposed may be used, but examples thereof include exposure using a photomask and exposure by a laser direct imaging method.

### <Post-Exposure Heating Step>

The film may be subjected to a step of carrying out heating after the exposure (a post-exposure heating step).

That is, the re-distribution layer A forming step may include a post-exposure baking step of heating the film exposed by the exposure step.

The post-exposure heating step can be carried out after the exposure step and before the development step.

The heating temperature in the post-exposure heating step is preferably 50° C. to 140° C. and more preferably 60° C. to 120° C.

The heating time in the post-exposure heating step is preferably 30 seconds to 300 minutes and more preferably 1 minute to 10 minutes.

In the post-exposure heating step, the temperature rising rate from the temperature at the start of heating to the maximum heating temperature is preferably 1 to 12° C./min, more preferably 2 to 10° C./min, and still more preferably 3 to 10° C./min.

In addition, the temperature rising rate may be appropriately changed during heating.

The heating means in the post-exposure heating step is not particularly limited, and a publicly known hot plate, oven, infrared heater, or the like can be used.

In addition, it is also preferable to carry out the heating in an atmosphere having a low oxygen concentration by allowing an inert gas such as nitrogen, helium, argon, or the like to flow.

### <Development Step>

The exposed film may be subjected to a development step of carrying out development using a developer to form a pattern.

That is, the re-distribution layer A forming step may include a development step of developing the film exposed by the exposure step using a developer to form a pattern.

By carrying out the development, one of the exposed portion and the non-exposed portion of the film is removed, and a pattern is formed.

Here, the development in which the non-exposed portion of the film is removed by the development step is referred to as negative-tone development, and the development in which the exposed portion of the film is removed by the development step is referred to as positive-tone development.

### [Developer]

Examples of the developer that is used in the development step include a developer containing an alkaline aqueous solution or an organic solvent.

In a case where the developer is an alkaline aqueous solution, examples of the basic compound that can be contained in the alkaline aqueous solution include inorganic alkalis, primary amines, secondary amines, tertiary amines, and a quaternary ammonium salt. The basic compound is preferably tetramethylammonium hydroxide (TMAH), potassium hydroxide, sodium carbonate, sodium hydroxide, sodium silicate, sodium metasilicate, ammonia, ethylamine, n-propylamine, diethylamine, di-n-butylamine, triethylamine, methyldiethylamine, dimethylethanolamine, triethanolamine, tetraethylammonium hydroxide, tetrapropylammonium hydroxide, tetrabutylammonium hydroxide, tetrapentylammonium hydroxide, tetrahexylammonium hydroxide, tetraoctylammonium hydroxide, ethyltrimethylammonium hydroxide, butyltrimethylammonium hydroxide, methyltriamylammonium hydroxide, dibutyldipentylammonium hydroxide, dimethylbis(2-hydroxyethyl)ammonium hydroxide, trimethylphenylammonium hydroxide, trimethylbenzylammonium hydroxide, triethylbenzylammonium hydroxide, pyrrole, or piperidine, and it is more preferably TMAH. The content of the basic compound in the developer is preferably 0.01% to 10% by mass, more preferably 0.1% to 5% by mass, and still more preferably 0.3% to 3% by mass in the total mass of the developer.

In a case where the developer contains an organic solvent, the compounds described in paragraph 0387 of WO2021/112189A can be used as the organic solvent. The content thereof is incorporated in the present specification. In addition, suitable examples of the alcohols include methanol, ethanol, propanol, isopropanol, butanol, pentanol, octanol, diethylene glycol, propylene glycol, methyl isobutyl carbinol, and triethylene glycol, and suitable examples of the amides include N-methylpyrrolidone, N-ethylpyrrolidone, and dimethylformamide.

In a case where the developer contains an organic solvent, one kind of organic solvent can be used, or two or more kinds thereof can be mixedly used. In the present invention, in particular, a developer containing at least one selected from the group consisting of cyclopentanone, γ-butyrolactone, dimethyl sulfoxide, N-methyl-2-pyrrolidone, and cyclohexanone is preferable, a developer containing at least one selected from the group consisting of cyclopentanone, γ-butyrolactone, and dimethyl sulfoxide is more preferable, and a developer containing cyclopentanone is particularly preferable.

In a case where the developer contains an organic solvent, the content of the organic solvent with respect to the total mass of the developer is preferably 50% by mass or more, more preferably 70% by mass or more, still more preferably 80% by mass or more, and particularly preferably 90% by mass or more. In addition, the above content may be 100% by mass.

In a case where the developer contains an organic solvent, the developer may further contain at least one of a basic compound or a base generator. In a case where at least one of the basic compound or the base generator in the developer permeates into the pattern, the performance such as the breaking elongation of the pattern may be improved.

The basic compound is preferably an organic base from the viewpoint of the reliability in a case of being remained in the cured film (the adhesiveness to the base material in a case where the cured substance is further heated).

The basic compound is preferably a basic compound having an amino group and preferably a primary amine, a secondary amine, a tertiary amine, an ammonium salt, a tertiary amide, or the like. However, in order to accelerate the imidization reaction, it is preferably a primary amine, a secondary amine, a tertiary amine, or an ammonium salt, more preferably a secondary amine, a tertiary amine, or an ammonium salt, still more preferably a secondary amine or a tertiary amine, and particularly preferably a tertiary amine.

From the viewpoint of mechanical characteristics (the breaking elongation) of the cured substance, it is preferable that the basic compound hardly remains in the cured film (the obtained cured substance), and from the viewpoint of accelerating cyclization, it is preferable that the residual amount of the basic compound hardly decreases due to vaporization or the like before heating.

Therefore, the boiling point of the basic compound is preferably 30° C. to 350° C., more preferably 80° C. to 270° C., and still more preferably 100° C. to 230° C. at normal pressure (101,325 Pa).

The boiling point of the basic compound is preferably higher than the temperature obtained by subtracting 20° C. from the boiling point of the organic solvent contained in the developer, and it is more preferably higher than the boiling point of the organic solvent contained in the developer.

For example, in a case where the boiling point of the organic solvent is 100° C., the basic compound to be used preferably has a boiling point of 80° C. or higher and more preferably a boiling point of 100° C. or higher.

The developer may contain only one kind of basic compound having an amide group or may contain two or more kinds thereof.

Specific examples of the basic compound include ethanolamine, diethanolamine, triethanolamine, ethylamine, diethylamine, triethylamine, hexylamine, dodecylamine, cyclohexylamine, cyclohexylmethylamine, cyclohexyldimethylamine, aniline, N-methylaniline, N,N-dimethylaniline, diphenylamine, pyridine, butylamine, isobutylamine, dibutylamine, tributylamine, dicyclohexylamine, diazabicycloundecene (DBU), 1,4-diazabicyclo[2.2.2]octane (DABCO), N,N-diisopropylethylamine, tetramethylammonium hydroxide, tetrabutylammonium hydroxide, ethylenediamine, butanediamine, 1,5-diaminopentane, N-methylhexylamine, N-methyldicyclohexylamine, trioctylamine, N-ethylethylenediamine, N,N-diethylethylenediamine, N,N,N′,N′-tetrabutyl-1,6-hexanediamine, spermidine, diaminocyclohexane, bis(2-methoxyethyl)amine, piperidine, methylpiperidine, dimethylpiperidine, piperazine, tropane, N-phenylbenzylamine, 1,2-dianilinoethane, 2-aminoethanol, toluidine, aminophenol, hexylaniline, phenylene diamine, phenylethylamine, dibenzylamine, pyrrole, N-methylpyrrole, N,N,N,N-tetramethylethylenediamine, and N,N,N,N-tetramethyl-1,3-propanediamine.

A preferred aspect of the base generator is the same as the preferred aspect of the base generator contained in the above-described composition. In particular, the base generator is preferably a thermal-base generator.

In a case where the developer contains at least one of a basic compound or a base generator, the content of the basic compound or the base generator is preferably 10% by mass or less, and more preferably 5% by mass or less with respect to the total mass of the developer. The lower limit of the content is not particularly limited; however, it is, for example, preferably 0.1% by mass or more.

In a case where the basic compound or the base generator is a solid in an environment where the developer is used, the content of the basic compound or the base generator is also preferably 70% to 100% by mass with respect to the total solid content of the developer.

The developer may contain only one kind of at least one of the basic compound or base generator or may contain two or more kinds thereof. In a case where at least one of the basic compound or the base generator is two or more kinds, the total thereof is preferably within the above-described range.

The developer may further contain another component.

Examples of the other component include a publicly known surfactant and a publicly known anti-foaming agent.

### [Method of Supplying Developer]

The method of supplying a developer is not particularly limited as long as a desired pattern can be formed, and it includes a method of immersing a base material on which a film has been formed in a developer, puddle development of supplying a developer to a film formed on a base material using a nozzle, and a method of continuously supplying a developer. The kind of nozzle is not particularly limited, and examples thereof include a straight nozzle, a shower nozzle, and a spray nozzle.

From the viewpoint of the permeability of the developer, the removability of the non-image area, and the manufacturing efficiency, a method of supplying a developer with a straight nozzle or a method of continuously supplying a developer with a spray nozzle is preferable, and from the viewpoint of the permeability of the developer into the image area, a method of supplying a developer with a spray nozzle is more preferable.

In addition, after the continuous supply by a straight nozzle, the base material is spun to remove the developer from the base material, and then the developer is continuously supplied by the straight nozzle again after the spin drying, a step of spinning the base material to remove the developer from the base material may be adopted, and this step may be repeated a plurality of times.

Examples of the method of supplying a developer in the development step include a step of continuously supplying a developer to a base material, a step of keeping a developer in a substantially stationary state on a base material, a step of vibrating a developer on a base material by ultrasonic waves or the like, and a step obtained by combining these steps.

The development time is preferably 3 seconds to 10 minutes and more preferably 5 seconds to 5 minutes. The temperature of the developer during development is not particularly determined; however, it is preferably 10° C. to 45° C. and more preferably 18° C. to 30° C.

In the development step, washing (rinsing) of the pattern with a rinsing liquid may be further carried out after the treatment with the developer. In addition, a method such as supplying a rinsing liquid before the developer which is in contact with the pattern is completely dried may be adopted.

### [Rinsing Liquid]

In a case where the developer is an alkaline aqueous solution, it is possible to use, for example, water as the rinsing liquid. In a case where the developer is a developer containing an organic solvent, it is possible to use as the rinsing liquid, for example, a solvent (for example, water, an organic solvent different from the organic solvent contained in the developer) different from the solvent contained in the developer.

Examples of the organic solvent in a case where the rinsing liquid contains an organic solvent include the same organic solvents as the organic solvents exemplified in the above-described case where the developer contains an organic solvent.

The organic solvent contained in the rinsing liquid is preferably an organic solvent different from the organic solvent contained in the developer, and it is more preferably an organic solvent having a solubility of the pattern, which is lower than that of the organic solvent contained in the developer.

In a case where the rinsing liquid contains an organic solvent, one kind of organic solvent can be used, or two or more kinds thereof can be mixedly used. The organic solvent is preferably cyclopentanone, γ-butyrolactone, dimethyl sulfoxide, N-methylpyrrolidone, cyclohexanone, PGMEA, or PGME, more preferably cyclopentanone, γ-butyrolactone, dimethyl sulfoxide, PGMEA, or PGME, and still more preferably cyclohexanone or PGMEA.

In a case where the rinsing liquid contains an organic solvent, the organic solvent is preferably 50% by mass or more, more preferably 70% by mass or more, and still more preferably 90% by mass or more with respect to the total mass of the rinsing liquid. In addition, the organic solvent may be 100% by mass with respect to the total mass of the rinsing liquid.

The rinsing liquid may contain at least one of a basic compound or a base generator.

Although not particularly limited, in a case where the developer contains an organic solvent, an aspect in which the rinsing liquid contains at least one of an organic solvent, a basic compound, or a base generator is also one of the preferred aspects of the present invention.

Examples of the basic compound and the base generator which are contained in the rinsing liquid include the compounds exemplified as the basic compound and the base generator which may be contained in a case where the developer contains an organic solvent, and the same applies to the preferred aspects thereof.

The basic compound and the base generator, which are contained in the rinsing liquid, may be selected in consideration of the solubility in the solvent in the rinsing liquid.

In a case where the rinsing liquid contains at least one of a basic compound or a base generator, the content of the basic compound or the base generator is preferably 10% by mass or less, and more preferably 5% by mass or less with respect to the total mass of the rinsing liquid. The lower limit of the content is not particularly limited; however, it is, for example, preferably 0.1% by mass or more.

In a case where the basic compound or the base generator is a solid in an environment where the rinsing liquid is used, the content of the basic compound or the base generator is also preferably 70% to 100% by mass with respect to the total solid content of the rinsing liquid.

In a case where the rinsing liquid contains at least one of a basic compound or a base generator, the rinsing liquid may contain only one kind of at least one of the basic compound or base generator or may contain two or more kinds thereof. In a case where at least one of the basic compound or the base generator is two or more kinds, the total thereof is preferably within the above-described range.

The rinsing liquid may further contain another component.

Examples of the other component include a publicly known surfactant and a publicly known anti-foaming agent.

### [Method of Supplying Rinsing Liquid]

The method of supplying a rinsing liquid is not particularly limited as long as a desired pattern can be formed and includes a method of immersing a base material in a rinsing liquid, a method of supplying a rinsing liquid to a base material by liquid filling, a method of supplying a rinsing liquid to a base material with a shower, and a method of continuously supplying a rinsing liquid to a base material by means such as a straight nozzle.

From the viewpoint of the permeability of the rinsing liquid, the removability of non-image area, and the manufacturing efficiency, there is a method of supplying a rinsing liquid with a shower nozzle, a straight nozzle, a spray nozzle, or the like, and a method of continuously supplying a rinsing liquid with a spray nozzle is preferable. From the viewpoint of the permeability of the rinsing liquid into the image area, a method of supplying a rinsing liquid with a spray nozzle is more preferable. The kind of nozzle is not particularly limited, and examples thereof include a straight nozzle, a shower nozzle, and a spray nozzle.

That is, the rinsing step is preferably a step of supplying, with a straight nozzle, or continuously supplying a rinsing liquid to the exposed film, and it is more preferably a step of supplying a rinsing liquid with a spray nozzle.

In the method of supplying a rinsing liquid in the rinsing step, a step of continuously supplying a rinsing liquid to a base material, a step of keeping a rinsing liquid in a substantially stationary state on a base material, a step of vibrating a rinsing liquid on the base material by ultrasonic waves or the like, and a step obtained by combining these steps can be adopted.

The rinsing time is preferably 10 seconds to 10 minutes and more preferably 20 seconds to 5 minutes. The temperature of the rinsing liquid during rinsing is not particularly determined; however, it is preferably 10° C. to 45° C. and more preferably 18° C. to 30° C.

The development step may include a step of bringing the treatment liquid into contact with the pattern after the treatment using the developer or after the pattern is washed with the rinsing liquid. In addition, such a method of supplying a treatment liquid before the developer or rinsing liquid which is in contact with the pattern is completely dried may be adopted.

Examples of the treatment liquid include a treatment liquid containing at least one of water or an organic solvent and at least one of a basic compound or a base generator.

Preferred aspects of the organic solvent and at least one of the basic compound or the base generator are the same as the preferred aspects of the organic solvent and at least one of the basic compound or the base generator, which are used in the above-described rinsing liquid.

As a method of supplying the treatment liquid to the pattern, the same method as the above-described method of supplying the rinsing liquid can be used, and the same applies to the preferred aspect thereof.

The content of the basic compound or the base generator in the treatment liquid is preferably 10% by mass or less and more preferably 5% by mass or less with respect to the total mass of the treatment liquid. The lower limit of the content is not particularly limited; however, it is, for example, preferably 0.1% by mass or more.

In addition, in a case where the basic compound or the base generator is a solid in an environment where the treatment liquid is used, the content of the basic compound or the base generator is also preferably 70% to 100% by mass with respect to the total solid content of the treatment liquid.

In a case where the treatment liquid contains at least one of a basic compound or a base generator, the treatment liquid may contain only one kind of at least one of the basic compound or the base generator, or may contain two or more kinds thereof. In a case where at least one of the basic compound or the base generator is two or more kinds, the total thereof is preferably within the above-described range.

### <Heating Step>

The pattern obtained by the development step (a pattern after the rinsing in a case where the rinsing step is carried out) may be subjected to a heating step of heating the pattern obtained by the development.

That is, the re-distribution layer A forming step may include a heating step of heating the pattern obtained by the development step.

In the heating step, the resin such as the polyimide precursor is cyclized to be a resin such as polyimide.

In addition, the crosslinking of unreacted crosslinkable groups in the specific resin or a crosslinking agent other than the specific resin also proceeds.

The heating temperature (the maximum heating temperature) in the heating step is preferably 50° C. to 450° C., more preferably 150° C. to 350° C., still more preferably 150° C. to 250° C., even still more preferably 160° C. to 250° C., and particularly preferably 160° C. to 230° C.

The heating step is preferably a step of accelerating the cyclization reaction of the polyimide precursor in the pattern under the action of the base or the like generated from the base generator by heating.

The heating in the heating step is preferably carried out at a temperature rising rate of 1 to 12° C./min from the temperature at the start of heating to the maximum heating temperature.

The temperature rising rate is more preferably 2 to 10° C./min and still more preferably 3 to 10° C./min. In a case where the above temperature rising rate is set to 1° C./min or higher, the excessive volatilization of the acid or solvent can be prevented while securing productivity, and in a case where the above temperature rising rate is set to 12° C./min or lower, the residual stress of the cured substance can be relaxed.

In addition, in a case of an oven that enables rapid heating, the heating is preferably carried out at a temperature rising rate of 1 to 8° C./see from the temperature at the start of heating to the maximum heating temperature, more preferably 2 to 7° C./see, and still more preferably 3 to 6° C./sec.

The temperature at the start of heating is preferably 20° C. to 150° C., more preferably 20° C. to 130° C., and still more preferably 25° C. to 120° C. The temperature at the start of heating refers to a temperature at which the step of heating to the maximum heating temperature is started. For example, in a case where the composition is applied on a base material and then dried, the temperature at the start of heating is the temperature of the film (the layer) after drying, and for example, it is preferable to raise the temperature from a temperature lower by 30° C. to 200° C. than the boiling point of the solvent contained in the composition.

The heating time (the heating time at the maximum heating temperature) is preferably 5 to 360 minutes, more preferably 10 to 300 minutes, and still more preferably 15 to 240 minutes.

In particular, in a case of forming a multilayered laminate, the heating temperature is preferably 30° C. or higher, more preferably 80° C. or higher, still more preferably 100° C. or higher, and particularly preferably 120° C. or higher, from the viewpoint of adhesiveness between layers.

The upper limit of the heating temperature is preferably 350° C. or lower, more preferably 250° C. or lower, and still more preferably 240° C. or lower.

The heating may be carried out stepwise. For example, a step in which the temperature is raised from 25° C. to 120° C. at 3° C./min, held at 120° C. for 60 minutes, raised from 120° C. to 180° C. at 2° C./min, and held at 180° C. for 120 minutes, may be carried out. In addition, it is also preferable to carry out the treatment while carrying out irradiation with ultraviolet rays as described in U.S. Pat. No. 9,159,547B. By such a pretreatment step, it is possible to improve the properties of the film. The pretreatment step may be carried out for a short time of about 10 seconds to 2 hours and more preferably 15 seconds to 30 minutes. The pretreatment step may be carried out as a step of two or more stages, for example, a first stage pretreatment step may be carried out in a range of 100° C. to 150° C., and then a second stage pretreatment step may be carried out in a range of 150° C. to 200° C.

Further, cooling may be carried out after heating, and the cooling rate, in this case, is preferably 1 to 5° C./min.

From the viewpoint of preventing the decomposition of the specific resin, it is preferable that the heating step is carried out in an atmosphere of a low oxygen concentration, for example, by allowing an inert gas such as nitrogen, helium, argon, or the like to flow, or carrying out heating under reduced pressure. The oxygen concentration is preferably 50 ppm (volume ratio) or lower, and more preferably 20 ppm (volume ratio) or lower.

The heating means in the heating step is not particularly limited; however, examples thereof include a hot plate, an infrared furnace, an electric heating oven, a hot air oven, and an infrared oven.

### <Post-Development Exposure Step>

The pattern obtained by the development step (a pattern after the rinsing in a case where the rinsing step is carried out) may be subjected to a post-development exposure step of exposing the pattern after the development step, instead of the heating step or in addition to the heating step.

That is, the re-distribution layer A forming step may include an after-development exposure step of exposing the pattern obtained by the development step. The re-distribution layer A forming step may include the heating step and the after-development exposure step, or may include only one of the heating step or the after-development exposure step.

In the post-development exposure step, it is possible to accelerate, for example, a reaction in which the cyclization of a polyimide precursor or the like proceeds by photosensitization of a photobase generator, a reaction in which the elimination of an acid-decomposable group proceeds by photosensitization of a photoacid generator.

In the post-development exposure step, it is sufficient that at least a part of the pattern obtained in the development step is exposed; however, it is preferable that the whole of the above pattern is exposed.

The exposure amount in the post-development exposure step is preferably 50 to 20,000 mJ/cm² and more preferably 100 to 15,000 mJ/cm² in terms of conversion of exposure energy at the wavelength at which the photosensitive compound has a sensitivity.

The post-development exposure step can be carried out using, for example, the light source in the above-described exposure step, and it is preferable to use broadband light.

### <Metal Layer Forming Step>

The pattern (preferably a pattern that has been subjected to at least one of the heating step or the post-development exposure step) obtained by the development step may be subjected to a metal layer forming step of forming a metal layer on the pattern.

The metal layer formed by the metal layer forming step corresponds to the conductive pattern A in the insulating pattern A of the pattern obtained by the development step.

That is, it is preferable that the re-distribution layer A forming step includes a metal layer forming step of forming a metal layer on the pattern (preferably the pattern supplied to at least one of the heating step or the after-development exposure step) obtained by the development step.

For the metal layer, existing metal kinds can be used without particular limitations. Examples thereof include copper, aluminum, nickel, vanadium, titanium, chromium, cobalt, gold, tungsten, tin, silver, and an alloy including these metals, where copper or aluminum is more preferable, and copper is still more preferable.

The forming method for the metal layer is not particularly limited, and the existing method can be applied. For example, the methods described in JP2007-157879A, JP2001-521288A, JP2004-214501A, JP2004-101850A, U.S. Pat. No. 7,888,181B2, and U.S. Pat. No. 9,177,926B2 can be used. For example, photolithography, physical vapor deposition method (PVD), chemical vapor phase growth method (CVD), lift-off, electrolytic plating, electroless plating, etching, printing, and a method obtained by combining these may be conceivable. More specific examples of the forming method for the metal layer include a patterning method obtained by combining sputtering, photolithography, and etching, and a patterning method combining photolithography and electrolytic plating. Examples of the preferred aspect of the plating include electrolytic plating using a copper sulfate plating liquid or a copper cyanide plating liquid.

In addition, it is also preferable that the metal layer forming step includes forming a barrier layer on the formed metal layer after the metal layer is formed. As a method of forming the barrier layer, a known method in the related art can be used without particular limitation.

The thickness of the metal layer at the thickest portion is preferably 0.01 to 50 μm and more preferably 1 to 10 μm.

### <Resist Layer Forming Step, Resist Layer Peeling Step>

Here, the re-distribution layer A forming step may include a resist layer forming step before the metal layer forming step.

Furthermore, the re-distribution layer A forming step may include a resist layer peeling step after the metal layer forming step.

These steps can be performed by a known method.

By performing these steps, a line-and-space pattern or the like can also be formed as the conductive pattern A.

### <Polishing Step>

The re-distribution layer A forming step may further include a polishing step of polishing the surface of the re-distribution layer A after the metal layer forming step.

Examples of the polishing method include chemical mechanical polishing (CMP) and physical polishing, but the present invention is not limited thereto, and a known method can be used without particular limitation.

### <Laminating Step>

The re-distribution layer A forming step according to the embodiment of the present invention preferably includes a laminating step.

The laminating step is a series of steps including carrying out again, in the following order on the surface of the pattern (the resin layer) or the metal layer, at least one of (a) the film forming step (the layer forming step), (b) the exposure step, (c) the development step, or (d) the heating step and the post-development exposure step. However, the aspect thereof may be such that at least one of (a) the film forming step or (d) the heating step and the post-development exposure step is repeated. In addition, (e) the metal layer forming step may be included after at least one of the heating step or the post-development exposure step of (d). It is needless to say that the laminating step may further include appropriately the above-described drying step or the like.

In a case where another laminating step is further carried out after the laminating step, a surface activation treatment step may be further carried out after the exposure step, the heating step, or the metal layer forming step. Examples of the surface activation treatment include plasma treatment. Details of the surface activation treatment will be described later.

The laminating step is preferably carried out 2 to 20 times and more preferably 2 to 9 times.

For example, a configuration having resin layers of 2 or more layers and 20 or fewer layers, such as a resin layer/a metal layer/a resin layer/a metal layer/a resin layer/a metal layer, is preferable, and a configuration having resin layers of 2 or more layers and 9 or fewer layers is still more preferable.

In the above layers, the compositions, shapes, film thicknesses, and the like may be the same or may be different from each other.

In the re-distribution layer A forming step, it is particularly preferable to form the cured substance (resin layer) of the composition to cover the metal layer after the metal layer is provided. Specific examples thereof include an aspect in which (a) the film forming step, (b) the exposure step, (c) the development step, (d) at least one of the heating step or the post-development exposure step, (e) the metal layer forming step are repeated in this order, and an aspect in which (a) the film forming step, (d) at least one of the heating step or the post-development exposure step, and (e) the metal layer forming step are repeated in order. By alternately carrying out the laminating step of laminating the composition layer (the resin layer) and the metal layer forming step, the composition layer (the resin layer) according to the embodiment of the present invention and the metal layer can be alternately laminated.

### <Step of Surface Activation Treatment>

The re-distribution layer A forming step preferably includes a surface activation treatment step of performing a surface activation treatment on at least a part of the metal layer and the composition layer.

The surface activation treatment step is usually carried out after the metal layer forming step (preferably, after at least one of the heating step or the post-development exposure step). However, after the development step, the metal layer forming step may be carried out after the composition layer is subjected to the surface activation treatment step.

Only at least a part of the metal layer may be subjected to the surface activation treatment, only at least a part of the composition layer after the exposure may be subjected to the surface activation treatment, or both at least a part of the metal layer and at least a part of the composition layer after the exposure may be subjected to the surface activation treatment. It is preferable to carry out the surface activation treatment on at least a part of the metal layer, and it is preferable to carry out the surface activation treatment on a part or whole of the region of the metal layer having a surface on which the composition layer is formed. In a case where a surface of the metal layer is subjected to the surface activation treatment in this manner, it is possible to improve the adhesiveness to the composition layer (film) to be provided on the surface thereof.

It is preferable that the surface activation treatment is carried out on a part or whole of the composition layer (the resin layer) after the exposure. In a case where a surface of the composition layer is subjected to the surface activation treatment in this manner, it is possible to improve the adhesiveness to a metal layer or a resin layer to be provided on the surface that has been subjected to the surface activation treatment. In particular, in a case where the composition layer is cured, such as in a case where negative-tone development is carried out, it is less likely to be damaged by the surface treatment, and thus the adhesiveness is likely to be improved.

The surface activation treatment can be carried out, for example, according to the method described in paragraph 0415 of WO2021/112189A. The content thereof is incorporated in the present specification.

### <Connection Pad Forming Step>

The re-distribution layer A forming step may further include a connection pad forming step after the laminating step. A preferred aspect of the connection pad to be formed is as described above.

In the connection pad forming step, a known method in the present field can be used without particular limitation, and examples thereof include a method of forming a resist layer as necessary, forming a connection pad by plating or the like, and peeling off the resist layer.

Here, an aspect in which the re-distribution layer A forming step includes a step of applying the composition for forming an insulating pattern A to the sealing layer to form a coating film, a step of drying, exposing, and developing the coating film to form a precursor pattern A, and a step of heating the precursor pattern A to obtain the insulating pattern A, and a film thickness change rate of the insulating pattern A with respect to the precursor pattern A is less than 20% is also one of the preferred aspects of the present invention.

Here, the above-described coating, drying, exposure, development, and heating are performed by the above-described film forming step, drying step, exposure step, development step, and heating step.

The film thickness change rate is calculated by (thickness of precursor pattern A−thickness of insulating pattern A)/thickness of precursor pattern A×100.

The above-described film thickness change rate is preferably 15% or less and more preferably 10% or less. In addition, the lower limit of the film thickness change rate is not particularly limited, and may be 0% or more.

### <Re-Distribution Layer B Forming Step>

The manufacturing method of a laminate according to the embodiment of the present invention includes a re-distribution layer B forming step of forming a re-distribution layer B including an insulating pattern B and a conductive pattern B that is present between patterns of the insulating pattern B on a surface of the sealing layer on which the circuit is not exposed.

By the re-distribution layer B forming step, the re-distribution layer B is formed on the surface of the sealing material on which the circuit is not exposed. A preferred aspect of the re-distribution layer B is the same as the preferred aspect of the re-distribution layer B in the above-described laminate according to the embodiment of the present invention.

The re-distribution layer B forming step can be performed by the same method as the re-distribution layer A forming step in terms of points other than the point that the re-distribution layer B is formed on the surface of the sealing material on which the circuit is not exposed.

In the re-distribution layer B forming step, the re-distribution layer B can be formed in the same manner as the re-distribution layer A is formed by using the composition for forming an insulating pattern A.

Here, the composition for forming an insulating pattern A used for forming the re-distribution layer A and the composition for forming an insulating pattern A used for forming the re-distribution layer B may have the same composition or different compositions.

In addition, the re-distribution layer B forming step and the re-distribution layer A forming step may be performed in any order.

### <Carrier Wafer Bonding Step, Carrier Wafer Peeling Step>

The manufacturing method of a laminate according to the embodiment of the present invention can include a carrier wafer bonding step of bonding a carrier wafer to the laminate during the manufacturing, and a carrier wafer peeling step of peeling off the bonded carrier wafer.

For example, in a case where the sealing layer is formed on the carrier wafer by bonding the carrier wafer to the member having a circuit in the sealing layer forming step, and the re-distribution layer A is formed on the sealing layer by the re-distribution layer A forming step, in order to form the re-distribution layer B, the carrier wafer is peeled off from the sealing layer, and a new carrier wafer is bonded to the surface of the re-distribution layer A as necessary, whereby the surface on which the carrier wafer is present can be reversed.

The carrier wafer peeling step and the carrier wafer bonding step can be performed by a known method.

In addition, a known carrier wafer can be used without particular limitation.

### <Conductive Portion Forming Step>

The manufacturing method of a laminate according to the embodiment of the present invention may further include a conductive portion forming step of forming the above-described conductive portion.

The conductive portion forming step may be performed, for example, between the sealing layer forming step and the re-distribution layer A forming step and the re-distribution layer B forming step, or after at least one of the re-distribution layer A forming step or the re-distribution layer B forming step.

The conductive portion forming step is performed, for example, by forming a hole in the sealing layer by a laser or the like and filling the hole with a conductor by plating or the like.

The above-described hole may be a through-hole or a non-through-hole.

In addition, in the formation of the above-described hole, residues of the sealing layer or the like generated during the processing may be removed by a known desmear treatment or the like.

As a method of the conductive portion forming step, a known method in the present field can be used without particular limitation.

### <Inspection Step>

After at least one of the re-distribution layer A forming step or the re-distribution layer B forming step, an inspection step of inspecting the formed re-distribution layer A and the re-distribution layer B at least one surface, conduction, insulating properties, the presence or absence of voids, and the like may be further included.

As a method of the inspection step, a known method in the present field can be used without particular limitation.

### <Connecting Member a Forming Step>

The manufacturing method of a laminate according to the embodiment of the present invention may further include a step of forming the connecting member A on a surface of the re-distribution layer A different from the surface in contact with the sealing layer.

A preferred aspect of the connecting member A is the same as the preferred aspect of the connecting member A of the laminate according to the embodiment of the present invention.

As a method of forming the connecting member A, a known method in the present field can be used without particular limitation.

### <Other Functional Die Bonding Step>

The manufacturing method of a laminate according to the embodiment of the present invention may further include a step of bonding the other functional die to a surface of the re-distribution layer A different from the surface in contact with the sealing layer.

It is preferable that the other functional die is connected to the re-distribution layer A via the above-described connecting member A.

A preferred aspect of the other functional die is the same as the preferred aspect of the other functional die of the laminate according to the embodiment of the present invention.

In a case of bonding the other functional die, at least one of heating or pressurization may be performed. As a bonding method of the other functional die, a known method in the present field can be used without particular limitation.

In the manufacturing method of a laminate according to the embodiment of the present invention, an aspect in which the member having a circuit is a wiring layer and the manufacturing method includes a step of bonding two or more other functional dies to the re-distribution layer A is also one of the preferred aspects of the present invention.

The bonding of the two or more other functional dies may be performed by the above-described other functional die bonding step. These may be bonded at the same time or may be bonded separately.

### <Connecting Member B Forming Step>

The manufacturing method of a laminate according to the embodiment of the present invention may further include a step of forming the connecting member B on a surface of the re-distribution layer B different from the surface in contact with the sealing layer.

A preferred aspect of the connecting member B is the same as the preferred aspect of the connecting member B of the laminate according to the embodiment of the present invention.

As a method of forming the connecting member B, a known method in the present field can be used without particular limitation.

### <Circuit Member Bonding Step>

The manufacturing method of a laminate according to the embodiment of the present invention may further include a step of bonding the circuit member to a surface of the re-distribution layer B different from the surface in contact with the sealing layer.

It is preferable that the circuit member is connected to the re-distribution layer B via the above-described connecting member B.

A preferred aspect of the circuit member is the same as the preferred aspect of the circuit member of the laminate according to the embodiment of the present invention.

In a case of bonding the circuit member, at least one of heating or pressurization may be performed. As a bonding method of the circuit member, a known method in the present field can be used without particular limitation.

### <Other Steps>

The manufacturing method of a laminate according to the embodiment of the present invention may further include other steps.

Examples of the other steps include a step of washing the member as necessary after each step.

### <Specific Examples of Manufacturing Method of Laminate>

Hereinafter, specific examples of the aspects of the manufacturing method of a laminate according to the embodiment of the present invention will be described with reference to the drawings, but the present invention is not limited thereto.

In each drawing, reference numerals described above may be omitted.

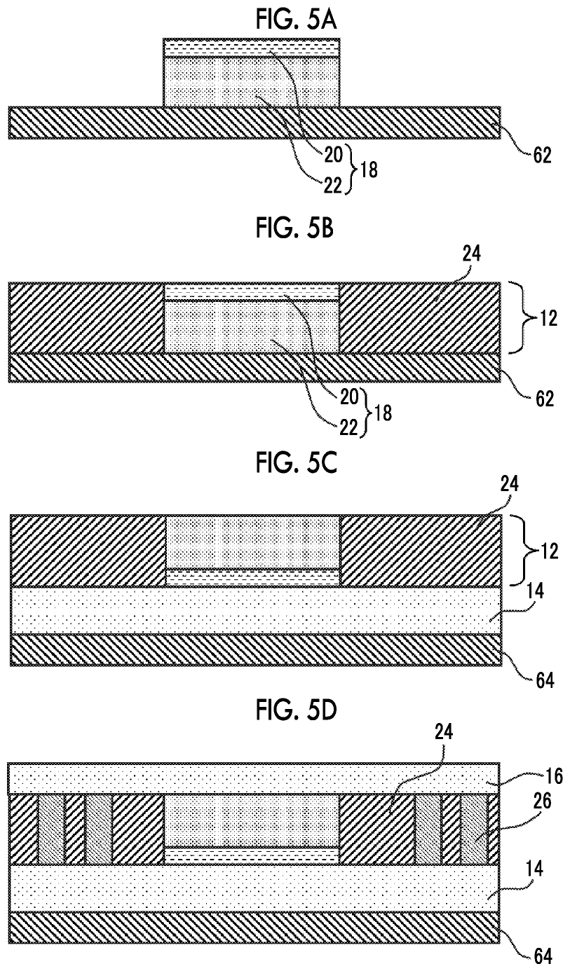

FIGS. 5A to 5D are schematic cross-sectional views showing an example of the manufacturing method of a laminate according to the embodiment of the present invention.

FIG. 5A is a schematic cross-sectional view showing a state in which the member 18 having a circuit is bonded to a carrier wafer 62.

Although not shown in FIG. 5A, a temporary adhesive layer may be formed on a side of the carrier wafer 62 on which the member 18 having a circuit is provided.

The member 18 having a circuit includes the semiconductor member 22 and the circuit 20, and the circuit 20 is disposed on a side opposite to the carrier wafer 62 across the semiconductor member 22. The member 18 having a circuit is described as a functional die including the semiconductor member 22, but in a case where the member 18 having a circuit is a wiring layer, the member 18 having a circuit may be composed of only the circuit 20, and the semiconductor member 22 may not be present.

FIG. 5B is a schematic cross-sectional view showing a state in which the sealing layer 12 including the member 18 having a circuit and the sealing material 24 is formed on the carrier wafer 62 by the sealing layer forming step.

The sealing layer 12 is obtained by forming a sealing material by a method of applying a curable composition to the carrier wafer 62 and the member 18 having a circuit shown in FIG. 5A and curing the composition.

Before the subsequent re-distribution layer A forming step, the surface of the sealing layer 12 may be polished by the above-described method to expose the circuit 20, or the above-described passivation layer forming step may be performed on the surface having the circuit 20.

FIG. 5C is a schematic cross-sectional view showing a state in which the second carrier wafer 64 is bonded and the carrier wafer 62 is peeled off after the re-distribution layer A14 is formed by the re-distribution layer A forming step.

The re-distribution layer A is formed on the surface of the sealing layer 12 shown in FIG. 5B on which the circuit 20 is provided, by performing the re-distribution layer A forming step.

Here, after the re-distribution layer A forming step, the second carrier wafer 64 different from the carrier wafer 62 is bonded to the re-distribution layer A, and the carrier wafer 62 is peeled off, whereby a surface of the sealing layer 12 different from the surface on which the re-distribution layer A is formed is exposed (reversal step).

FIG. 5D is a schematic cross-sectional view showing a state in which the conductive through-via 26 is formed by the conductive portion forming step and the re-distribution layer B16 is formed by the re-distribution layer B forming step.

The conductive through-via 26 is formed on the sealing material 24 of the sealing layer 12 shown in FIG. 5C by performing the conductive portion forming step.

In addition, the re-distribution layer B is formed on the surface of the sealing layer 12 shown in FIG. 5C on which the circuit 20 is not provided, by performing the re-distribution layer B forming step.

Thereafter, the second carrier wafer 64 is peeled off to obtain a laminate according to the embodiment of the present invention.

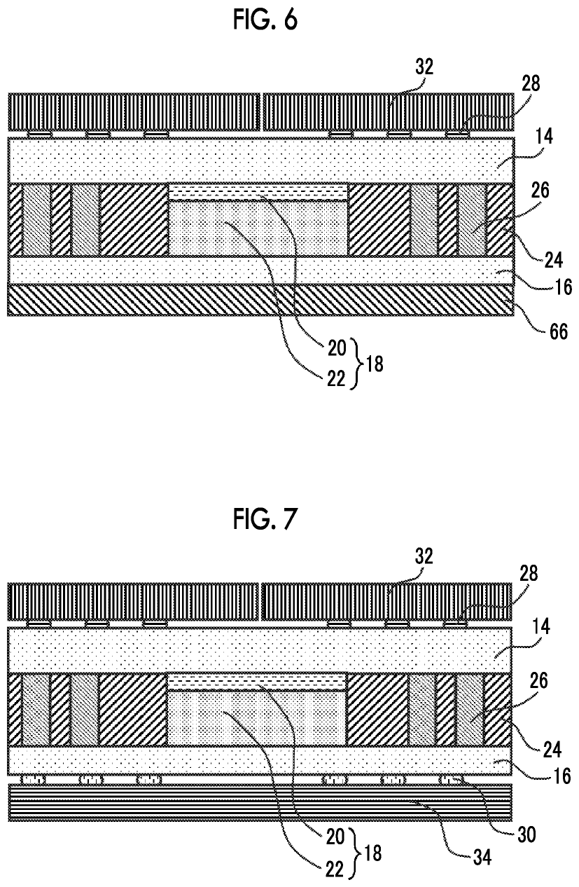

FIG. 6 is a schematic cross-sectional view showing an example of an aspect in which other functional dies are further bonded to the laminate shown in FIG. 5D.

In FIG. 6, the third carrier wafer 66 is bonded to the re-distribution layer B16 in the laminate shown in FIG. 5D, and the second carrier wafer 64 is peeled off.

After the second carrier wafer 64 is peeled off, the connecting member A forming step is performed to form the connecting member A28 on the re-distribution layer A14, and the other functional die bonding step is performed to bond two other functional dies 32, whereby the laminate shown in FIG. 6 is obtained.

Here, an underfill material may be further filled between the re-distribution layer A14 and the other functional die 32.

Thereafter, the laminate obtained by peeling off the third carrier wafer 66 can be used as a semiconductor package.

FIG. 7 is a schematic cross-sectional view showing an example of an aspect in which a circuit member is further bonded to the laminate shown in FIG. 6.

In FIG. 7, the third carrier wafer 66 in the laminate shown in FIG. 6 is peeled off.

After the third carrier wafer 66 is peeled off, the connecting member B forming step is performed to form the connecting member B30 on the re-distribution layer B16, and the circuit member bonding step is performed to bond the circuit member 34, whereby the laminate is obtained.

Hereinafter, details of the composition for forming an insulating pattern A (composition) will be described.

As the composition, a known composition used for forming an insulating pattern can be used without particular limitation, but the composition preferably includes at least one resin selected from the group consisting of a heterocyclic ring-containing polymer and a precursor thereof (hereinafter, also referred to as a “specific resin”), and more preferably includes a polyimide or a polyimide precursor.

An imidization rate of the polyimide precursor is preferably less than 50%.

An imidization rate of the polyimide is preferably 50% or more.

Details of the imidization rate will be described later.

### <Specific Resin>

The heterocyclic ring-containing polymer is preferably a resin including an imide ring structure or an oxazole ring structure in a main chain structure.

In the present invention, the term “main chain” represents the relatively longest bonding chain in a resin molecule, and the term “side chain” refers to other bonding chains other than the main chain.

Examples of the heterocyclic ring-containing polymer include polyimide, polybenzoxazole, and polyamideimide.

The precursor of the heterocyclic ring-containing polymer refers to a resin in which a change in a chemical structure occurs due to an external stimulus to form a heterocyclic ring-containing polymer, and a resin in which a change in a chemical structure occurs due to heat to form a heterocyclic ring-containing polymer is preferable, and a resin in which a ring structure is formed by a ring closure reaction due to heat to form a heterocyclic ring-containing polymer is more preferable.

Examples of the precursor of the heterocyclic ring-containing polymer include a polyimide precursor, a polybenzoxazole precursor, and a polyamideimide precursor.

That is, the composition preferably contains, as the specific resin, at least one resin selected from the group consisting of a polyimide, a polyimide precursor, a polybenzoxazole, a polybenzoxazole precursor, a polyamideimide, and a polyamideimide precursor.

The composition preferably includes a polyimide or a polyimide precursor as the specific resin.

In addition, the specific resin is preferably a resin having at least one repeating unit selected from the group consisting of a repeating unit represented by Formula (2) described later and a repeating unit represented by Formula (4) described later.

The specific resin preferably has a polymerizable group and more preferably contains a radically polymerizable group.

In a case where the specific resin has a radically polymerizable group, the resin composition preferably contains a radical polymerization initiator, and it more preferably contains a radical polymerization initiator and a radical crosslinking agent. Further, a sensitizing agent can be contained as necessary. From such a composition, for example, a negative type photosensitive film is formed.

In addition, the specific resin may have a polarity converting group such as an acid-decomposable group.

In a case where the specific resin has an acid-decomposable group, it is preferable that the composition contains a photoacid generator. From such a composition, for example, a positive-tone photosensitive film or a negative-tone photosensitive film, which is a chemical amplification type photosensitive film, is formed.

### [Polyimide Precursor]

The kind and the like of the polyimide precursor used in the present invention are not particularly limited, but it is preferable that the polyimide precursor contains a repeating unit represented by Formula (2).

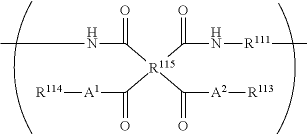

In Formula (2), A¹ and A² each independently represent an oxygen atom or —NR^{z}—, R¹¹¹ represents a divalent organic group, R¹¹⁵ represents a tetravalent organic group, R¹¹³ and R¹¹⁴ each independently represent a hydrogen atom or a monovalent organic group, and R^{z} represents a hydrogen atom or a monovalent organic group.

A¹ and A² in Formula (2) each independently represent an oxygen atom or —NR^{z}—, and an oxygen atom is preferable.

R^{z} represents a hydrogen atom or a monovalent organic group, and a hydrogen atom is preferable.

R¹¹¹ in Formula (2) represents a divalent organic group. Examples of the divalent organic group include a group having a linear or branched aliphatic group, a cyclic aliphatic group, or an aromatic group. A linear or branched aliphatic group having 2 to 20 carbon atoms, a cyclic aliphatic group having 3 to 20 carbon atoms, an aromatic group having 3 to 20 carbon atoms, or a group consisting of a combination of these groups is preferable, and a group containing an aromatic group having 6 to 20 carbon atoms is more preferable. In the linear or branched aliphatic group, the hydrocarbon group in the chain may be substituted with a group containing a heteroatom, and in the cyclic aliphatic group and the aromatic group, the hydrocarbon group of the ring member may be substituted with a group containing a heteroatom. Examples of R¹¹¹ in Formula (2) include groups represented by —Ar— and —Ar-L-Ar—, respectively, and a group represented by —Ar-L-Ar— is preferable. However, Ar's are each independently an aromatic group, and L is a single bond or an aliphatic hydrocarbon group having 1 to 10 carbon atoms, which may be substituted with a fluorine atom, —O—, —CO—, —S—, —SO₂—, or —NHCO—, or a group consisting of a combination of two or more of the above. The preferred ranges thereof are as described above.

R¹¹¹ is preferably derived from a diamine. Examples of the diamine that is used for producing the polyimide precursor include a linear aliphatic or branched aliphatic diamine, a cyclic aliphatic diamine, or an aromatic diamine. One kind of diamine may be used alone, or two or more kinds thereof may be used.

Specifically, R¹¹¹ is preferably a diamine containing a linear or branched aliphatic group having 2 to 20 carbon atoms, a cyclic aliphatic group having 3 to 20 carbon atoms, an aromatic group having 3 to 20 carbon atoms, or a group consisting of a combination thereof, and more preferably a diamine containing an aromatic group having 6 to 20 carbon atoms. In the linear or branched aliphatic group, the hydrocarbon group in the chain may be substituted with a group containing a heteroatom, and in the cyclic aliphatic group and the aromatic group, the hydrocarbon group of the ring member may be substituted with a group containing a heteroatom. Examples of the group containing an aromatic group include the following groups.

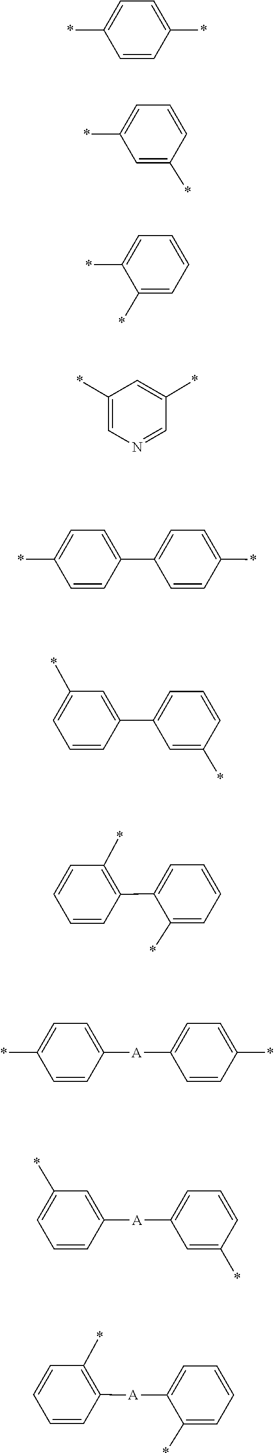

In the formulae, A represents a single bond or a divalent linking group. It is preferably a single bond, or an aliphatic hydrocarbon group having 1 to 10 carbon atoms, which may be substituted with a fluorine atom, —O—, —C(═O)—, —S—, —SO₂—, —NHCO—, or a group selected from combinations thereof, more preferably a single bond or a group selected from an alkylene group having 1 to 3 carbon atoms, which may be substituted with a fluorine atom, —O—, —C(═O)—, —S—, or —SO₂—, and still more preferably —CH₂—, —O—, —S—, —SO₂—, —C(CF₃)₂—, or —C(CH₃)₂—.

In Formulae, * represents a bonding site to another structure.

Specific examples of diamine include at least one diamine selected from 1,2-diaminoethane, 1,2-diaminopropane, 1,3-diaminopropane, 1,4-diaminobutane, or 1,6-diaminohexane;
1,2- or 1,3-diaminocyclopentane, 1,2-, 1,3-, or 1,4-diaminocyclohexane, 1,2-, 1,3-, or 1,4-bis(aminomethyl)cyclohexane, bis-(4-aminocyclohexyl)methane, bis-(3-aminocyclohexyl)methane, 4,4′-diamino-3,3′-dimethylcyclohexylmethane, and isophoronediamine;
m- or p-phenylenediamine, diaminotoluene, 4,4′- or 3,3′-diaminobiphenyl, 4,4′-diaminodiphenyl ether, 3,3′-diaminodiphenyl ether, 4,4′- or 3,3′-diaminodiphenylmethane, 4,4′- or 3,3′-diaminodiphenyl sulfone, 4,4′- or 3,3′-diaminodiphenyl sulfide, 4,4′- or 3,3′-diaminobenzophenone, 3,3′-dimethyl-4,4′-diaminobiphenyl, 2,2′-dimethyl-4,4′-diaminobiphenyl, 3,3′-dimethoxy-4,4′-diaminobiphenyl, 2,2-bis(4-aminophenyl)propane, 2,2-bis(4-aminophenyl)hexafluoropropane, 2,2-bis(3-hydroxy-4-aminophenyl)propane, 2,2-bis(3-hydroxy-4-aminophenyl)hexafluoropropane, 2,2-bis(3-amino-4-hydroxyphenyl)propane, 2,2-bis(3-amino-4-hydroxyphenyl)hexafluoropropane, bis(3-amino-4-hydroxyphenyl)sulfone, bis(4-amino-3-hydroxyphenyl)sulfone, 4,4′-diaminoparaterphenyl, 4,4′-bis(4-aminophenoxy)biphenyl, bis[4-(4-aminophenoxy)phenyl]sulfone, bis[4-(3-aminophenoxy)phenyl]sulfone, bis[4-(2-aminophenoxy)phenyl]sulfone, 1,4-bis(4-aminophenoxy)benzene, 9,10-bis(4-aminophenyl)anthracene, 3,3′-dimethyl-4,4′-diaminodiphenyl sulfone, 1,3-bis(4-aminophenoxy)benzene, 1,3-bis(3-aminophenoxy)benzene, 1,3-bis(4-aminophenyl)benzene, 3,3′-diethyl-4,4′-diaminodiphenylmethane, 3,3′-dimethyl-4,4′-diaminodiphenylmethane, 4,4′-diaminooctafluorobiphenyl, 2,2-bis[4-(4-aminophenoxy)phenyl]propane, 2,2-bis[4-(4-aminophenoxy)phenyl]hexafluoropropane, 9,9-bis(4-aminophenyl)-10-hydroanthracene, 3,3′,4,4′-tetraaminobiphenyl, 3,3′,4,4′-tetraaminodiphenyl ether, 1,4-diaminoanthraquinone, 1,5-diaminoanthraquinone, 3,3-dihydroxy-4,4′-diaminobiphenyl, 9,9′-bis(4-aminophenyl)fluorene, 4,4′-dimethyl-3,3′-diaminodiphenyl sulfone, 3,3′,5,5′-tetramethyl-4,4′-diaminodiphenylmethane, 2,4- and 2,5-diaminocumen, 2,5-dimethyl-p-phenylenediamine, acetoguanamine, 2,3,5,6-tetramethyl-p-phenylenediamine, 2,4,6-trimethyl-m-phenylenediamine, bis(3-aminopropyl)tetramethyldisiloxane, bis(p-aminophenyl)octamethylpentasiloxane, 2,7-diaminofluorene, 2,5-diaminopyridine, 1,2-bis(4-aminophenyl)ethane, diaminobenzanilide, an ester of diaminobenzoic acid, 1,5-diaminonaphthalene, diaminobenzotrifluoride, 1,3-bis(4-aminophenyl)hexafluoropropane, 1,4-bis(4-aminophenyl)octafluorobutane, 1,5-bis(4-aminophenyl)decafluoropentane, 1,7-bis(4-aminophenyl)tetradecafluoroheptane, 2,2-bis[4-(3-aminophenoxy)phenyl]hexafluoropropane, 2,2-bis[4-(2-aminophenoxy)phenyl]hexafluoropropane, 2,2-bis[4-(4-aminophenoxy)-3,5-dimethylphenyl]hexafluoropropane, 2,2-bis[4-(4-aminophenoxy)-3,5-bis(trifluoromethyl)phenyl]hexafluoropropane, p-bis(4-amino-2-trifluoromethylphenoxy)benzene, 4,4′-bis(4-amino-2-trifluoromethylphenoxy)biphenyl, 4,4′-bis(4-amino-3-trifluoromethylphenoxy)biphenyl, 4,4′-bis(4-amino-2-trifluoromethylphenoxy)diphenyl sulfone, 4,4′-bis(3-amino-5-trifluoromethylphenoxy)diphenyl sulfone, 2,2-bis[4-(4-amino-3-trifluoromethylphenoxy)phenyl]hexafluoropropane, 3,3′,5,5′-tetramethyl-4,4′-diaminobiphenyl, 4,4′-diamino-2,2′-bis(trifluoromethyl)biphenyl, 2,2′,5,5′,6,6′-hexafluorotolidine, and 4,4′-diaminoquaterphenyl.

Further, the diamines (DA-1) to (DA-18) described in paragraphs 0030 to 0031 of WO2017/038598A are also preferable.

Further, the diamine having two or more alkylene glycol units in the main chain, described in paragraphs 0032 to 0034 of WO2017/038598A, is also preferably used.

R¹¹¹ is preferably represented by —Ar-L-Ar— from the viewpoint of the flexibility of the organic film to be obtained. However, Ar's are each independently an aromatic group, and L is an aliphatic hydrocarbon group having 1 to 10 carbon atoms, which may be substituted with a fluorine atom, —O—, —CO—, —S—, —SO₂—, or —NHCO—, or a group consisting of a combination of two or more of the above. Ar is preferably a phenylene group, and L is preferably an aliphatic hydrocarbon group having 1 or 2 carbon atoms, which may be substituted with a fluorine atom, —O—, —CO—, —S—, or —SO₂—. The aliphatic hydrocarbon group here is preferably an alkylene group.

In addition, from the viewpoint of the i-line transmittance, R¹¹¹ is preferably a divalent organic group represented by Formula (51) or Formula (61) below. In particular, from the viewpoint of the i-line transmittance and ease of availability, a divalent organic group represented by Formula (61) is more preferable.

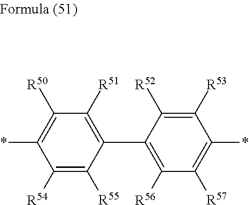

In Formula (51), R⁵⁰ to R⁵⁷ each independently represent a hydrogen atom, a fluorine atom, or a monovalent organic group, and at least one of R⁵⁰, . . . , or R⁵⁷ represents a fluorine atom, a methyl group, or a trifluoromethyl group, and *'s each independently represent a bonding site to the nitrogen atom in Formula (2).

Examples of the monovalent organic group as R⁵⁰ to R⁵⁷ include an unsubstituted alkyl group having 1 to 10 (preferably 1 to 6 carbon atoms) carbon atoms and a fluorinated alkyl group having 1 to 10 (preferably 1 to 6 carbon atoms) carbon atoms.

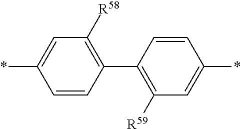

In Formula (61), R⁵⁸ and R⁵⁹ each independently represent a fluorine atom, a methyl group, or a trifluoromethyl group, and *'s each independently represent a bonding site to the nitrogen atom in Formula (2).

Examples of the diamine that provides a structure of Formula (51) or Formula (61), 2,2′-dimethylbenzidine, 2,2′-bis(trifluoromethyl)-4,4′-diaminobiphenyl, 2,2′-bis(fluoro)-4,4′-diaminobiphenyl, and 4,4′-diaminooctafluorobiphenyl. These may be used alone, or two or more kinds thereof may be used in combination.

In addition, R¹¹¹ is also preferably a group represented by Formula (71). In the above-described aspect, R¹¹¹ is more preferably a group represented by Formula (72).

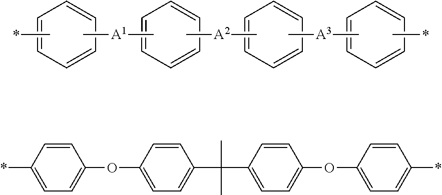

In Formula (71), A¹ to A³ each independently represent a single bond or a divalent linking group, * represents a bonding site to a nitrogen atom in Formula (2), and four benzene rings described in Formula (71) each have a hydrogen atom which may be substituted with a substituent.

In the present specification, a bond that intersects with a side of a ring structure means that any hydrogen atom in the ring structure is substituted.

In Formula (72), * represents a bonding site to the nitrogen atom in Formula (2).

In Formula (71), A¹ to A³ are each preferably an aliphatic hydrocarbon group having 1 to 10 carbon atoms, which may be substituted with a fluorine atom, —O—, —C(═O)—, —S—, —S(═O)₂—, —NHC(═O)—, or a group consisting of a combination of two or more of these, more preferably an aliphatic hydrocarbon group having 1 to 10 carbon atoms, which may be substituted with a fluorine atom, —O—, —C(═O)—, or a group consisting of a combination of two or more of these, and still more preferably an aliphatic hydrocarbon group having 1 to 10 carbon atoms, which may be substituted with a fluorine atom, or —O—.

In particular, A¹ and A³ are preferably —O—.

In particular, A² is preferably an aliphatic hydrocarbon group having 1 to 10 carbon atoms, which may be substituted with a fluorine atom.

Among these, an aspect in which A¹ and A³ are —O— and A² is —C(CH₃)₂— is also one of the preferred aspects of the present invention.

The number of carbon atoms in the aliphatic hydrocarbon group having 1 to 10 carbon atoms, which may be substituted with a fluorine atom, is not particularly limited, but is preferably 1 to 6 and more preferably 1 to 4.

Specific examples of the aliphatic hydrocarbon group having 1 to 10 carbon atoms, which may be substituted with a fluorine atom, include —CH₂—, —C(CH₃)₂—, and —C(CF₃)₂—, and among these, —C(CH₃)₂— is preferable.

Examples of the substituent in the four benzene rings described in Formula (71) include a fluorine atom and a hydrocarbon group having 1 to 10 carbon atoms, in which a hydrogen atom may be substituted with a fluorine atom.

In addition, an aspect in which all four benzene rings described in Formula (71) are unsubstituted is also one of the preferred aspects of the present invention.

In addition, R¹¹¹ is also preferably a group represented by Formula (81). In the above-described aspect, R¹¹¹ is more preferably a group represented by Formula (82).

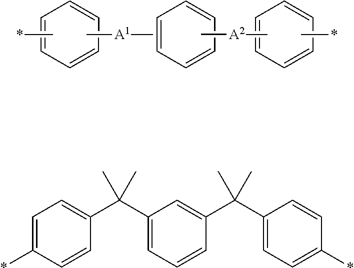

In Formula (81), A¹ and A² each independently represent a single bond or a divalent linking group, * represents a bonding site to a nitrogen atom in Formula (2), and three benzene rings described in Formula (81) each have a hydrogen atom which may be substituted with a substituent.

In Formula (82), * represents a bonding site to the nitrogen atom in Formula (2).

In Formula (81), A¹ and A² each independently represent preferably an aliphatic hydrocarbon group having 1 to 10 carbon atoms, which may be substituted with a fluorine atom, —O—, —C(═O)—, —S—, —S(═O)₂—, —NHC(═O)—, or a group consisting of a combination of two or more of these, more preferably an aliphatic hydrocarbon group having 1 to 10 carbon atoms, which may be substituted with a fluorine atom, —O—, —C(═O)—, or a group consisting of a combination of two or more of these, still more preferably an aliphatic hydrocarbon group having 1 to 10 carbon atoms, which may be substituted with a fluorine atom, or —O—, and particularly preferably —C(CH₃)₂—.

R¹¹⁵ in Formula (2) represents a tetravalent organic group. The tetravalent organic group is preferably a tetravalent organic group containing an aromatic ring and more preferably a group represented by Formula (5) or Formula (6).

In Formula (5) or Formula (6), *'s each independently represent a bonding site to another structure.

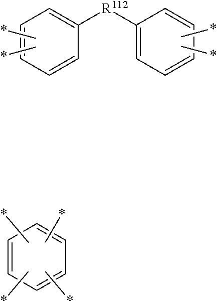

In Formula (5), R¹¹² is a single bond or a divalent linking group. It is preferably a single bond or a group selected from an aliphatic hydrocarbon group having 1 to 10 carbon atoms, which may be substituted with a fluorine atom, —O—, —CO—, —S—, —SO₂—, —NHCO—, or a combination thereof, more preferably a single bond or a group selected from an alkylene group having 1 to 3 carbon atoms, which may be substituted with a fluorine atom, —O—, —CO—, —S—, or —SO₂—, and still more preferably a divalent group selected from the group consisting of —CH₂—, —C(CF₃)₂—, —C(CH₃)₂—, —O—, —CO—, —S—, and —SO₂—.

In addition, R¹¹⁵ is also preferably a group represented by Formula (7). In the above-described aspect, R¹¹⁵ is more preferably a group represented by Formula (7-2).

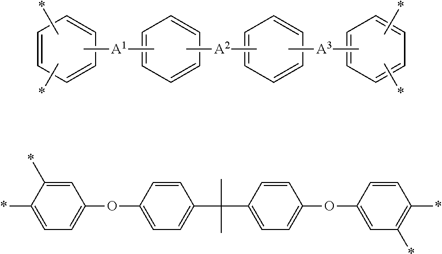

In Formula (7), A¹ to A³ each independently represent a single bond or a divalent linking group, * represents a bonding site to a carbonyl group in Formula (2), and four benzene rings described in Formula (7) each have a hydrogen atom which may be substituted with a substituent.

In Formula (7-2), * represents a bonding site to the carbonyl group in Formula (2).

In Formula (7), the preferred aspects of A¹ to A³ and the substituent in the benzene ring are the same as the preferred aspects of A¹ to A³ in Formula (7-1) and the substituent in the benzene ring.

Specific examples of R¹¹⁵ include a tetracarboxylic acid residue that remains after the removal of the anhydride group from the tetracarboxylic acid dianhydride. The polyimide precursor may contain only one kind of tetracarboxylic acid dianhydride residue or may contain two or more kinds thereof, as a structure corresponding to R ¹¹⁵.

The tetracarboxylic acid dianhydride is preferably represented by Formula (0).

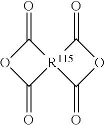

In Formula (0), R¹¹⁵ represents a tetravalent organic group. R¹¹⁵ is the same as R¹¹⁵ in Formula (2), and the same applies to the preferred range thereof.

Specific examples of the tetracarboxylic acid dianhydride include pyromellitic acid dianhydride (PMDA), 3,3′,4,4′-biphenyltetracarboxylic acid dianhydride, 3,3′,4,4′-diphenylsulfide tetracarboxylic acid dianhydride, 3,3′,4,4′-diphenylsulfone tetracarboxylic acid dianhydride, 3,3′,4,4′-benzophenone tetracarboxylic acid dianhydride, 3,3′,4,4′-diphenylmethane tetracarboxylic acid dianhydride, 2,2′,3,3′-diphenylmethane tetracarboxylic acid dianhydride, 2,3,3′,4′-biphenyltetracarboxylic acid dianhydride, 2,3,3′,4′-benzophenone tetracarboxylic acid dianhydride, 4,4′-oxydiphthalic acid dianhydride, 2,3,6,7-naphthalene tetracarboxylic acid dianhydride, 1,4,5,7-naphthalene tetracarboxylic acid dianhydride, 2,2-bis(3,4-dicarboxyphenyl)propane dianhydride, 2,2-bis(2,3-dicarboxyphenyl)propane dianhydride, 2,2-bis(3,4-dicarboxyphenyl) hexafluoropropane dianhydride, 1,3-diphenylhexafluoropropane-3,3,4,4-tetracarboxylic acid dianhydride, 1,4,5,6-naphthalene tetracarboxylic acid dianhydride, 2,2′,3,3′-diphenyl tetracarboxylic acid dianhydride, 3,4,9,10-perylene tetracarboxylic acid dianhydride, 1,2,4,5-naphthalene tetracarboxylic acid dianhydride, 1,4,5,8-naphthalene tetracarboxylic acid dianhydride, 1,8,9,10-phenanthrene tetracarboxylic acid dianhydride, 1,1-bis(2,3-dicarboxyphenyl)ethane dianhydride, 1,1-bis(3,4-dicarboxyphenyl)ethane dianhydride, 1,2,3,4-benzene tetracarboxylic acid dianhydride, and alkyl derivatives having 1 to 6 carbon atoms thereof as well as alkoxy derivatives having 1 to 6 carbon atoms thereof.

In addition, preferred examples thereof include the tetracarboxylic acid dianhydrides (DAA-1) to (DAA-5) described in paragraph 0038 of WO2017/038598A.

In Formula (2), it is also possible that at least one of R¹¹¹ or R¹¹⁵ has an OH group. More specifically, examples of R¹¹¹ include a residue of a bisaminophenol derivative.

R¹¹³ and R¹¹⁴ in Formula (2) each independently represent a hydrogen atom or a monovalent organic group. The monovalent organic group preferably includes a linear or branched alkyl group, a cyclic alkyl group, an aromatic group, or a polyalkyleneoxy group. In addition, at least one of R¹¹³ or R¹¹⁴ preferably contains a polymerizable group, and more preferably both of them contain a polymerizable group. It is also preferable that at least one of R¹¹³ or R¹¹⁴ contains two or more polymerizable groups. The polymerizable group is preferably a group capable of undergoing a crosslinking reaction under the action of heat, a radical, or the like, where the group is a radically polymerizable group. Specific examples of the polymerizable group include a group having an ethylenically unsaturated bond, an alkoxymethyl group, a hydroxymethyl group, an acyloxymethyl group, an epoxy group, an oxetanyl group, a benzoxazolyl group, a blocked isocyanate group, and an amino group. The radically polymerizable group contained in the polyimide precursor is preferably a group having an ethylenically unsaturated bond.

Examples of the group having an ethylenically unsaturated bond include a vinyl group, an allyl group, an isoallyl group, a 2-methylallyl group, a group (for example, a vinylphenyl group) having an aromatic ring that is directly bonded to a vinyl group, a (meth)acrylamide group, a (meth)acryloyloxy group, and a group represented by Formula (III), where a group represented by Formula (III) is preferable.

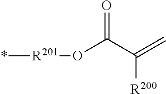

In Formula (III), R²⁰⁰ represents a hydrogen atom, a methyl group, an ethyl group, or a methylol group, where a hydrogen atom or a methyl group is preferable.

In Formula (III), * represents a bonding site to another structure.

In Formula (III), R²⁰¹ represents an alkylene group having 2 to 12 carbon atoms, —CH₂CH(OH)CH₂—, a cycloalkylene group, or a polyalkyleneoxy group.

Suitable examples of R²⁰¹ include an alkylene group such as an ethylene group, a propylene group, a trimethylene group, a tetramethylene group, a pentamethylene group, a hexamethylene group, an octamethylene group, or a dodecamethylene group, a 1,2-butanediyl group, a 1,3-butanediyl group, —CH₂CH(OH)CH₂—, and a polyalkyleneoxy group, where an alkylene group such as an ethylene group or a propylene group, —CH₂CH(OH)CH₂—, a cyclohexyl group, or a polyalkyleneoxy group is more preferable, and an alkylene group such as an ethylene group or a propylene group, or a polyalkyleneoxy group is still more preferable.

In the present invention, the polyalkyleneoxy group refers to a group to which two or more alkyleneoxy groups are directly bonded. The alkylene group in the plurality of alkyleneoxy groups contained in the polyalkyleneoxy group may be the same or different from each other.

In a case where the polyalkyleneoxy group contains a plurality of kinds of alkyleneoxy groups having different alkylene groups, the sequence of the alkyleneoxy groups in the polyalkyleneoxy group may be a randomly arranged sequence, may be a sequence arranged to have a block, or may be a sequence arranged to have an alternating pattern or the like.

The number of carbon atoms of the alkylene group (including the number of carbon atoms of the substituent in a case where the alkylene group has a substituent) is preferably 2 or more, more preferably 2 to 10, still more preferably 2 to 6, even more preferably 2 to 5, even still more preferably 2 to 4, even further still more preferably 2 or 3, and particularly preferably 2.

In addition, the alkylene group may have a substituent. Examples of the preferred substituent include an alkyl group, an aryl group, and a halogen atom.

In addition, the number of alkyleneoxy groups contained in the polyalkyleneoxy group (the number of repetitions of the polyalkyleneoxy group) is preferably 2 to 20, more preferably 2 to 10, and still more preferably 2 to 6.

The polyalkyleneoxy group is preferably a polyethyleneoxy group, a polypropyleneoxy group, a polytrimethyleneoxy group, a polytetramethyleneoxy group, or a group obtained by bonding a plurality of ethyleneoxy groups with a plurality of propyleneoxy groups, more preferably a polyethyleneoxy group or a polypropyleneoxy group, and still more preferably a polyethyleneoxy group, from the viewpoint of solubility in a solvent and solvent resistance. In the group obtained by bonding a plurality of ethyleneoxy groups with a plurality of propyleneoxy groups, the ethyleneoxy groups and the propyleneoxy groups may be randomly arranged, may be arranged by forming a block, or may be arranged in an alternately patterned manner or the like. The preferred aspect of the number of repetitions of the ethyleneoxy group and the like in these groups is as described above.

In Formula (2), in a case where R¹¹³ is a hydrogen atom, or in a case where R¹¹⁴ is a hydrogen atom, the polyimide precursor may form a conjugate salt together with a tertiary amine compound having an ethylenically unsaturated bond. Examples of the tertiary amine compound having such an ethylenically unsaturated bond include N,N-dimethylaminopropyl methacrylate.

In Formula (2), at least one of R¹¹³ or R¹¹⁴ may be a polarity converting group such as an acid-decomposable group. The acid-decomposable group is not particularly limited as long as it decomposes by the action of the acid to generate an alkali-soluble group such as a phenolic hydroxy group or a carboxy group; however, it is preferably an acetal group, a ketal group, a silyl group, or a silyl ether group, a tertiary alkyl ester group, or the like, and from the viewpoint of exposure sensitivity, it is more preferably an acetal group or a ketal group.

Specific examples of the acid-decomposable group include a tert-butoxycarbonyl group, an isopropoxycarbonyl group, a tetrahydropyranyl group, a tetrahydrofuranyl group, an ethoxyethyl group, a methoxyethyl group, an ethoxymethyl group, a trimethylsilyl group, a tert-butoxycarbonylmethyl group, and a trimethylsilyl ether group. From the viewpoint of exposure sensitivity, an ethoxyethyl group or a tetrahydrofuranyl group is preferable.

The polyimide precursor preferably has a fluorine atom in the structure thereof. The content of fluorine atoms in the polyimide precursor is preferably 10% by mass or more, and it is preferably 20% by mass or less.

In addition, for the purpose of improving adhesiveness to a substrate, the polyimide precursor may be copolymerized with an aliphatic group having a siloxane structure. Specifically, an aspect in which bis(3-aminopropyl)tetramethyldisiloxane, bis(p-aminophenyl)octamethylpentasiloxane, or the like is used as the diamine can be mentioned.

The repeating unit represented by Formula (2) is preferably a repeating unit represented by Formula (2-A). That is, at least one polyimide precursor that is used in the present invention is preferably a precursor having a repeating unit represented by Formula (2-A). In a case where the polyimide precursor contains a repeating unit represented by Formula (2-A), it is possible to further widen the width of the exposure latitude.

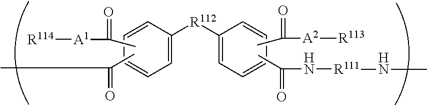

In Formula (2-A), A¹ and A² represent an oxygen atom, R¹¹¹ and R¹¹² each independently represent a divalent organic group, R¹¹³ and R¹¹⁴ each independently represent a hydrogen atom or a monovalent organic group, and at least one of R¹¹³ or R¹¹⁴ is a group containing a polymerizable group, where both of them are preferably a group containing a polymerizable group.

A¹, A², R¹¹¹, R¹¹³, and R¹¹⁴ each independently have the same meaning as A¹, A², R¹¹, R¹¹³, and R¹¹⁴ in Formula (2), respectively, and the same applies to the preferred ranges thereof. R¹¹² has the same meaning as R¹¹² in Formula (5), and the same applies to the preferred range thereof.

The polyimide precursor may contain one kind of repeating unit represented by Formula (2) or may contain two or more kinds thereof. In addition, the polyimide precursor may contain structural isomers of the repeating unit represented by Formula (2). The polyimide precursor may also contain another kind of repeating unit in addition to the above repeating unit represented by Formula (2).

One embodiment of the polyimide precursor in the present invention includes an aspect in which the content of the repeating unit represented by Formula (2) is 50% by mole or more of all the repeating units. The above-described total content is more preferably 70% by mole or more, still more preferably 90% by mole or more, and particularly preferably more than 90% by mole. The upper limit of the total content is not particularly limited, and all the repeating units in the polyimide precursor excluding the terminal may be the repeating unit represented by Formula (2).

### —Cyclization Rate (Imidization Rate)—

From the viewpoint of film strength, insulating properties, and the like of the organic film to be obtained, the cyclization rate (imidization rate) of the polyimide precursor is preferably less than 50%, more preferably 40% or less, still more preferably 30% or less, and even more preferably 20% or less.

The lower limit of the cyclization rate is not particularly limited, and may be 0%.

The cyclization rate is measured by, for example, the following method.

The infrared absorption spectrum of polyimide precursor is measured, and a peak intensity P1 in the vicinity of 1,377 cm⁻¹, which is the absorption peak derived from the imide structure, is obtained. Next, the polyimide precursor is subjected to a heat treatment at 350° C. for 1 hour, and then the infrared absorption spectrum is measured again to obtain a peak intensity P2 in the vicinity of 1,377 cm⁻¹. Using the obtained peak intensities P1 and P2, the cyclization rate of the polyimide precursor can be determined based on the following expression.

Cyclization rate (%)=(peak intensity P1/peak intensity P2)×100

The weight-average molecular weight (Mw) of the polyimide precursor is preferably 5,000 to 100,000, more preferably 10,000 to 50,000, and still more preferably 15,000 to 40,000. The number-average molecular weight (Mn) of the polyimide precursor is preferably 2,000 to 40,000, more preferably 3,000 to 30,000, and still more preferably 4,000 to 20,000.

The dispersivity of the molecular weight of the polyimide precursor is preferably 1.5 or more, more preferably 1.8 or more, and still more preferably 2.0 or more. The upper limit value of the dispersivity of the molecular weight of the polyimide precursor is not particularly limited; however, it is, for example, preferably 7.0 or less, more preferably 6.5 or less, and still more preferably 6.0 or less.

In the present specification, the dispersity of the molecular weight is a value obtained by calculating “weight-average molecular weight/number-average molecular weight”.

In a case where the composition contains a plurality of kinds of polyimide precursors as the specific resin, it is preferable that the weight-average molecular weight, the number-average molecular weight, and the dispersity of at least one kind of polyimide precursor are in the above ranges. Further, it is also preferable that the weight-average molecular weight, the number-average molecular weight, and the dispersity, calculated by using the plurality of kinds of polyimide precursors as one resin, are within the above ranges.

### [Polyimide]

The polyimide that is used in the present invention may be an alkali-soluble polyimide or may be a polyimide soluble in a developer containing an organic solvent as a main component.

In the present specification, the alkali-soluble polyimide refers to a polyimide, 0.1 g or more of which is dissolved in 100 g of an aqueous solution of 2.38% by mass of tetramethylammonium at 23° C., and from the viewpoint of pattern formation properties, it is preferably a polyimide, 0.5 g or more of which is dissolved therein and still more preferably a polyimide, 1.0 g or more of which is dissolved therein. The upper limit of the dissolution amount is not particularly limited; however, it is preferably 100 g or less.

The polyimide is preferably a polyimide having a plurality of imide structures in the main chain from the viewpoint of the film hardness and the insulating properties of the organic film to be obtained.

### —Fluorine Atom—

From the viewpoint of the film hardness of the organic film to be obtained, the polyimide preferably has a fluorine atom.

The fluorine atom is preferably contained in, for example, R¹³² in a repeating unit represented by Formula (4) described later or R¹³¹ in a repeating unit represented by Formula (4) described later, and it is more preferably contained, as a fluorinated alkyl group, in R¹³² in a repeating unit represented by Formula (4) described later or R¹³¹ in a repeating unit represented by Formula (4) described later.

The amount of fluorine atoms with respect to the total mass of the polyimide is preferably 5% by mass or more, and it is preferably 20% by mass or less.

### —Silicon Atom—

From the viewpoint of the film hardness of the organic film to be obtained, it is also preferable that the polyimide has a silicon atom.

The silicon atom is preferably contained in, for example, R¹³¹ in a repeating unit represented by Formula (4) described later, and more preferably contained in R¹³¹ in a repeating unit represented by Formula (4) described later as an organically modified (poly)siloxane structure.

The silicon atom or the organically modified (poly)siloxane structure may be contained in the side chain of the polyimide; however, it is preferably contained in the main chain of the polyimide.

The amount of silicon atoms with respect to the total mass of the polyimide is preferably 1% by mass or more, and it is preferably 20% by mass or less.

### —Ethylenically Unsaturated Bond—

From the viewpoint of the film hardness of the organic film to be obtained, the polyimide preferably has an ethylenically unsaturated bond.

The polyimide may have an ethylenically unsaturated bond at the terminal of the main chain or the side chain; however, it preferably has an ethylenically unsaturated bond at the side chain.

The ethylenically unsaturated bond preferably has radical polymerizability.

The ethylenically unsaturated bond is preferably included in R¹³² or R¹³¹ in the repeating unit represented by Formula (4) described later, and more preferably included in R¹³² or R¹³¹ as a group having an ethylenically unsaturated bond.

Among these, the ethylenically unsaturated bond is preferably included in R¹³¹ in the repeating unit represented by Formula (4) described later, and more preferably included in R¹³¹ as a group having an ethylenically unsaturated bond.

Examples of the group having an ethylenically unsaturated bond include a group having a vinyl group which may be substituted, which is directly bonded to an aromatic ring such as a vinyl group, an allyl group, or a vinylphenyl group, a (meth)acrylamide group, a (meth)acryloyloxy group, and a group represented by Formula (IV).

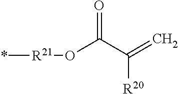

In Formula (IV), R²⁰ represents a hydrogen atom, a methyl group, an ethyl group, or a methylol group, where a hydrogen atom or a methyl group is preferable.

In Formula (IV), R²¹ represents an alkylene group having 2 to 12 carbon atoms, —O—CH₂CH(OH)CH₂—, —C(═O)O—, —O(C═O)NH—, a (poly)alkyleneoxy group having 2 to 30 carbon atoms (the alkylene group preferably has 2 to 12 carbon atoms, more preferably 2 to 6 carbon atoms, and particularly preferably 2 or 3 carbon atoms, and the number of repetitions of alkyleneoxy group is preferably 1 to 12, more preferably 1 to 6, and particularly preferably 1 to 3), or a group obtained by combining two or more of these.

The alkylene group having 2 to 12 carbon atoms may be a linear one, a branched one, or a cyclic one, or may be any alkylene group represented by a combination of these.

The alkylene group having 2 to 12 carbon atoms is preferably an alkylene group having 2 to 8 carbon atoms and more preferably an alkylene group having 2 to 4 carbon atoms.

Among the above, R²¹ is preferably a group represented by any one of Formulae (R1) to (R3) and more preferably a group represented by Formula (R1).

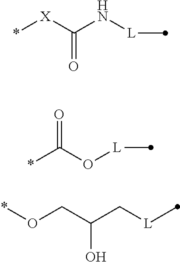

In Formulae (R1) to (R3), L represents a single bond, an alkylene group having 2 to 12 carbon atoms, a (poly)alkyleneoxy group having 2 to 30 carbon atoms, or a group obtained by bonding two or more of these, X represents an oxygen atom or a sulfur atom, * represents a bonding site to another structure, and * represents a bonding site to an oxygen atom to which R²¹ in Formula (IV) is bonded.

In Formulae (R1) to (R3), the preferred aspect of the alkylene group having 2 to 12 carbon atoms as L or the (poly)alkyleneoxy group having 2 to 30 carbon atoms is the same as the preferred aspect of the alkylene group having 2 to 12 carbon atoms as R²¹ in Formula (IV) or the (poly)alkyleneoxy group having 2 to 30 carbon atoms.

In Formula (R1), X is preferably an oxygen atom.

In Formulae (R1) to (R3), * has the same meaning as * in Formula (IV), and the same applies to the preferred aspect thereof.

The structure represented by Formula (R1) is obtained, for example, by reacting a polyimide having a hydroxy group such as a phenolic hydroxy group with a compound (for example, 2-isocyanatoethyl methacrylate) having an isocyanato group and an ethylenically unsaturated bond.

The structure represented by Formula (R2) is obtained, for example, by reacting a polyimide having a carboxy group with a compound (for example, 2-hydroxyethyl methacrylate) having a hydroxy group and an ethylenically unsaturated bond.

The structure represented by Formula (R3) is obtained, for example, by reacting a polyimide having a hydroxy group such as a phenolic hydroxy group with a compound (for example, glycidyl methacrylate) having a glycidyl group and an ethylenically unsaturated bond.

In Formula (IV), * represents a bonding site to another structure, and it is preferably a bonding site to the main chain of the polyimide.

The amount of the ethylenically unsaturated bond with respect to the total mass of the polyimide is preferably 0.0001 to 0.1 mol/g and more preferably 0.0005 to 0.05 mol/g.

—Polymerizable Group Other than Group Having Ethylenically Unsaturated Bond—

The polyimide may have a polymerizable group other than the group having an ethylenically unsaturated bond.

Examples of the polymerizable group other than the group having an ethylenically unsaturated bond include a cyclic ether group such as an epoxy group or an oxetanyl group, an alkoxymethyl group such as a methoxymethyl group, and a methylol group.

The polymerizable group other than the group having an ethylenically unsaturated bond is preferably contained in, for example, R¹³¹ in a repeating unit represented by Formula (4) described later.

The amount of the polymerizable group other than the group having an ethylenically unsaturated bond with respect to the total mass of the polyimide is preferably 0.0001 to 0.1 mol/g and more preferably 0.001 to 0.05 mol/g.

### —Polarity Converting Group—

The polyimide may have a polarity converting group such as an acid-decomposable group. The acid-decomposable group in the polyimide is the same as the acid-decomposable group described in R¹¹³ and R¹¹⁴ in Formula (2) described above, and the same applies to the preferred aspect thereof.

The polarity converting group is contained, for example, in R¹³¹ or R¹³² in the repeating unit represented by Formula (4) described later, or a terminal of the polyimide.

### —Acid Value—

In a case where the polyimide is subjected to alkaline development, the acid value of the polyimide is preferably 30 mgKOH/g or more, more preferably 50 mgKOH/g or more, and still more preferably 70 mgKOH/g or more, from the viewpoint of improving developability.

The acid value thereof is preferably 500 mgKOH/g or less, more preferably 400 mgKOH/g or less, and still more preferably 200 mgKOH/g or less.

In a case where the polyimide is subjected to the development (for example, the “solvent development”) using a developer containing an organic solvent as a main component, the acid value of the polyimide is preferably 1 to 35 mgKOH/g, more preferably 2 to 30 mgKOH/g, and still more preferably 5 to 20 mgKOH/g.

The acid value is measured by a known method, for example, by the method described in JIS K0070: 1992.

The acid group contained in the polyimide is preferably an acid group having a pKa of 0 to 10 and more preferably an acid group having a pKa of 3 to 8 from the viewpoint of achieving both storage stability and developability.

The “pKa” is represented by the negative common logarithm pKa of the equilibrium constant Ka of a dissociation reaction, in a case of assuming that hydrogen ions are released from the acid in the dissociation reaction. In the present specification, unless otherwise specified, pKa is defined as a calculated value according to ACD/ChemSketch (registered trademark). pKa may refer to the values published in “Handbook of Chemistry, Pure Chemistry, 5th Edition” edited by the Chemical Society of Japan.

In a case where the acid group is a polyvalent acid such as phosphoric acid, the pKa is the first dissociation constant.

As such an acid group, the polyimide preferably contains at least one selected from the group consisting of a carboxy group and a phenolic hydroxy group and more preferably contains a phenolic hydroxy group.

### —Phenolic Hydroxy Group—

From the viewpoint of allowing the speed of development with an alkaline developer to be proper, the polyimide preferably has a phenolic hydroxy group.

The polyimide may have a phenolic hydroxy group at the terminal of the main chain or the side chain.

The phenolic hydroxy group is preferably contained in, for example, R¹³² or R¹³¹ in a repeating unit represented by Formula (4) described later.

The amount of the phenolic hydroxy group with respect to the total mass of the polyimide is preferably 0.1 to 30 mol/g and more preferably 1 to 20 mol/g.

The polyimide that is used in the present invention is not particularly limited as long as it is a polymer compound having an imide structure; however, it is preferable that the polyimide contains a repeating unit represented by Formula (4).

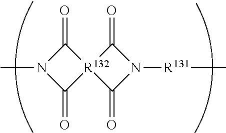

In Formula (4), R¹³¹ represents a divalent organic group, and R¹³² represents a tetravalent organic group.

In a case where a polymerizable group is contained, the polymerizable group may be located at at least one of R¹³¹ or R¹³² or may be located at the terminal of the polyimide as shown in Formula (4-1) or Formula (4-2).

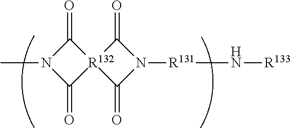

In Formula (4-1), R¹³³ is a polymerizable group, and the other groups respectively have the same meanings as those in Formula (4).

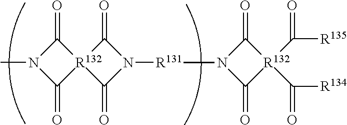

In Formula (4-2), at least one of R¹³⁴ or R¹³⁵ is a polymerizable group, where it is an organic group in a case of not being a polymerizable group, and the other groups respectively have the same meanings as those in Formula (4).

Examples of the polymerizable group include the above-described group having an ethylenically unsaturated bond or a crosslinkable group other than the above-described group having an ethylenically unsaturated bond.

R¹³¹ represents a divalent organic group. Examples of the divalent organic group include the same one as R¹¹¹ in Formula (2), and the same applies to the preferred range thereof.

Examples of R¹³¹ include a diamine residue that remains after the removal of an amino group of a diamine. Examples of the diamine include an aliphatic, a cyclic aliphatic, and an aromatic diamine. Specific examples thereof include the example of R¹¹¹ in Formula (2) which is contained in the polyimide precursor.

It is preferable that R¹³¹ is a diamine residue having at least two alkylene glycol units in the main chain from the viewpoint of more effectively suppressing the occurrence of warping during baking. It is more preferably a diamine residue containing, in one molecule, a total of two or more chains of any one or both of the ethylene glycol chain and the propylene glycol chain, and it is still more preferably the above-described diamine which is a diamine residue containing no aromatic ring.

Examples of the diamine containing, in one molecule, a total of two or more chains of any one or both of the ethylene glycol chain and the propylene glycol chain include JEFFAMINE (registered trade name) KH-511, ED-600, ED-900, ED-2003, EDR-148, EDR-176, D-200, D-400, D-2000, D-4000 (all product names, manufactured by HUNTSMAN Corporation), 1-(2-(2-(2-aminopropoxy)ethoxy)propoxy)propane-2-amine, and 1-(1-(1-(2-aminopropoxy)propan-2-yl)oxy)propane-2-amine, which are not limited thereto.

In addition, R¹³¹ is preferably a group including a group represented by Formula (2-1), and more preferably a group represented by Formula (2-1).

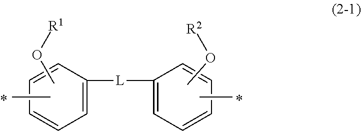

In Formula (2-1), R¹ and R² each independently represent a group having an ethylenically unsaturated bond, L represents a single bond or a divalent linking group which does not have an imide bond, and *'s each represent a bonding site to another structure.

In Formula (2-1), R¹ and R² are each independently preferably a group represented by Formula (R1-1).

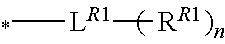

In Formula (R1-1), L^{R1} represents an (n+1)-valent linking group, R^{R1}'s each independently represent an aromatic group directly bonded to a vinyl group, a maleimide group, a (meth)acryloxy group, or a (meth)acrylamide group, n represents an integer of 1 to 10, and * represents a bonding site to an oxygen atom in Formula (2-1).

R^{R1}'s each independently represent an aromatic group directly bonded to a vinyl group or a maleimide group, and a vinylphenyl group is more preferable.

L^{R1} is preferably a hydrocarbon group or a group represented by a bond between a hydrocarbon group and at least one group selected from the group consisting of —O—, —C(═O)—, —S—, —S(═O)₂—, and —NR^{N}—, and more preferably a hydrocarbon group, a group represented by *¹—C(═O)-L^{R2}-*², or a group represented by *¹—C(═O)NR^{N}-L^{R2}-*².

The hydrocarbon group in L^{R1} is preferably an alkylene group, more preferably an alkylene group having 1 to 10 carbon atoms, and still more preferably an alkylene group having 1 to 4 carbon atoms.

L^{R2} represents a hydrocarbon group, and is preferably an alkylene group, more preferably an alkylene group having 2 to 10 carbon atoms, and still more preferably an alkylene group having 2 to 6 carbon atoms.

The preferred aspect of R^{N} is as described above.

*¹ has the same definition as * in Formula (R1-1), and *² represents a bonding site to R^{R1} in Formula (R1-1).

In addition, in a case where R^{R1} is a vinylphenyl group, L^{R1} is preferably an alkylene group having 1 to 4 carbon atoms, and more preferably a methylene group.

In a case where R^{R1} is a maleimide group, L^{R1} is preferably an alkylene group having 1 to 4 carbon atoms or a group represented by * ¹—C(═O)-L^{R2}-*².

In a case where R^{R1} is a (meth)acryloxy group or a (meth)acrylamide group, L^{R1} is preferably a group represented by *¹—C(═O)NR^{N}-L^{R2}*².

n is preferably an integer of 1 to 4, more preferably 1 or 2, and still more preferably 1.

In Formula (2-1), L is preferably a single bond, —C(CH₃)₂—, —C(CF₃)₂—, —S(═O)₂—, or a 9,9-fluorenyl group. In addition, an aspect in which L is a single bond, —C(CH₃)₂—, or —C(CF₃)₂— is also one of the preferred aspects of the present invention.

R¹³² represents a tetravalent organic group. Examples of the tetravalent organic group include the same one as R¹¹⁵ in Formula (2), and the same applies to the preferred range thereof.

For example, four bonding partners of the tetravalent organic group exemplified as R¹¹⁵ are bonded to four —C(═O)— moieties in Formula (4) to form a fused ring.

Examples of R¹³² include a tetracarboxylic acid residue that remains after the removal of the anhydride group from the tetracarboxylic acid dianhydride. Specific examples thereof include the example of R¹¹⁵ in Formula (2) which is contained in the polyimide precursor. From the viewpoint of the hardness of the organic film, R¹³² is preferably an aromatic diamine residue having 1 to 4 aromatic rings.

It is also preferable that an OH group is contained in at least one of R¹³¹ or R¹³² More specifically, preferred examples of R¹³¹ include 2,2-bis(3-hydroxy-4-aminophenyl)propane, 2,2-bis(3-hydroxy-4-aminophenyl)hexafluoropropane, 2,2-bis(3-amino-4-hydroxyphenyl)propane, 2,2-bis(3-amino-4-hydroxyphenyl)hexafluoropropane, and the above (DA-1) to (DA-18), and more preferred examples of R¹³² include the above (DAA-1) to (DAA-5).

It is also preferable that the polyimide has a fluorine atom in the structure. The content of fluorine atoms in the polyimide is preferably 10% by mass or more, and it is more preferably 20% by mass or less.

For the intended purpose of improving adhesiveness to a substrate, an aliphatic group having a siloxane structure may be copolymerized with the polyimide. Specific examples of the diamine component include bis(3-aminopropyl)tetramethyldisiloxane, and bis(p-aminophenyl)octamethyl pentasiloxane.

In order to improve the storage stability of the composition, the terminal of the main chain of the polyimide is preferably blocked with a terminal blocking agent such as a monoamine, an acid anhydride, a monocarboxylic acid, a monoacid chloride compound, or a monoactive ester compound. Among these, it is more preferable to use monoamine. Examples of the preferred monoamine compound include aniline, 2-ethynyl aniline, 3-ethynyl aniline, 4-ethynyl aniline, 5-amino-8-hydroxyquinoline, 1-hydroxy-7-aminonaphthalene, 1-hydroxy-6-aminonaphthalene, 1-hydroxy-5-aminonaphthalene, 1-hydroxy-4-aminonaphthalene, 2-hydroxy-7-aminonaphthalene, 2-hydroxy-6-aminonaphthalene, 2-hydroxy-5-aminonaphthalene, 1-carboxy-7-aminonaphthalene, 1-carboxy-6-aminonaphthalene, 1-carboxy-5-aminonaphthalene, 2-carboxy-7-aminonaphthalene, 2-carboxy-6-aminonaphthalene, 2-carboxy-5-aminonaphthalene, 2-aminobenzoic acid, 3-aminobenzoic acid, 4-aminobenzoic acid, 4-aminosalicylic acid, 5-aminosalicylic acid, 6-aminosalicylic acid, 2-aminobenzenesulfonic acid, 3-aminobenzenesulfonic acid, 4-aminobenzenesulfonic acid, 3-amino-4,6-dihydroxypyrimidine, 2-aminophenol, 3-aminophenol, 4-aminophenol, 2-aminothiophenol, 3-aminothiophenol, and 4-aminothiophenol. Two or more of these may be used, and a plurality of different terminal groups may be introduced by reacting a plurality of terminal blocking agents.

### —Imidization Rate (Ring Closure Rate)—

The imidization rate (also referred to as the “ring closure rate”) of the polyimide is preferably 50% or more, more preferably 70% or more, and still more preferably 90% or more, from the viewpoint of the film hardness, the insulating properties, or the like of the organic film to be obtained.

The upper limit of the imidization rate is not particularly limited, and it may be any imidization rate of 100% or less.

The imidization rate is measured according to the method described above.

The polyimide may include the repeating unit represented by Formula (4) in which the combinations of R¹³¹ and R¹³² in all the repeating units are the same, or may include the repeating unit represented by Formula (4) including two or more different combinations of R¹³¹ and R¹³². The polyimide may contain another kind of repeating unit in addition to the above repeating unit represented by Formula (4). Examples of the other kind of repeating unit include the repeating unit represented by Formula (2) described above.

The polyimide can be synthesized by utilizing, for example, a method in which a tetracarboxylic acid dianhydride is reacted with a diamine (a part thereof is substituted with a terminal blocking agent which is a monoamine) at a low temperature, a method in which a tetracarboxylic acid dianhydride (a part thereof is substituted with a terminal blocking agent which is an acid anhydride, a monoacid chloride compound, or a monoactive ester compound) is reacted with a diamine at a low temperature, a method in which a diester is obtained from a tetracarboxylic acid dianhydride and alcohol and then reacted with a diamine (a part thereof is substituted with a terminal blocking agent which is a monoamine) in the presence of a condensing agent, a method in which a polyimide precursor is obtained, for example, by using a method in which a diester is obtained from a tetracarboxylic acid dianhydride and an alcohol, the remaining dicarboxylic acid is subjected to acid chloride modification and reacted with a diamine (a part thereof is substituted with a terminal blocking agent which is a monoamine), and the polyimide precursor is subjected to full imidization using a known imidization reaction method, or, a method in which the imidization reaction is stopped in the middle of the reaction and the imide structure is partially introduced, or furthermore a method in which a fully imidized polymer is blended with the polyimide precursor, whereby the imide structure is partially introduced. In addition, another known method for synthesizing polyimide can also be applied.

The weight-average molecular weight (Mw) of the polyimide is preferably 5,000 to 100,000, more preferably 10,000 to 50,000, and still more preferably 15,000 to 40,000. In a case where the weight-average molecular weight is set to 5,000 or more, it is possible to improve the breakage resistance of the film after curing. In order to obtain an organic film having excellent mechanical properties (for example, breaking elongation), the weight-average molecular weight is particularly preferably 15,000 or more.

The number-average molecular weight (Mn) of the polyimide is preferably 2,000 to 40,000, more preferably 3,000 to 30,000, and still more preferably 4,000 to 20,000.

The dispersivity of the molecular weight of the polyimide is preferably 1.5 or more, more preferably 1.8 or more, and still more preferably 2.0 or more. The upper limit value of the dispersivity of the molecular weight of the polyimide is not particularly limited; however, it is, for example, preferably 7.0 or less, more preferably 6.5 or less, and still more preferably 6.0 or less.

In a case where the composition contains a plurality of kinds of polyimides as the specific resin, it is preferable that the weight-average molecular weight, the number-average molecular weight, and the dispersity of at least one kind of polyimide are in the above ranges. It is also preferable that the weight-average molecular weight, the number-average molecular weight, and the dispersity, calculated by using the plurality of kinds of polyimides as one resin, are within the above ranges.

### [Polybenzoxazole Precursor]

Examples of the polybenzoxazole precursor include the compounds described in paragraphs 0073 to 0095 of WO2022/145355A. The above description is incorporated in the present specification.

### [Polybenzoxazole]

Examples of the polybenzoxazole include the compounds described in paragraphs 0101 to 0108 of WO2022/145355A. The above description is incorporated in the present specification.

### [Polyamideimide Precursor]

Examples of the polyamideimide precursor include the compounds described in paragraphs 0104 to 0119 of WO2022/145355A. The above description is incorporated in the present specification.

### [Polyamideimide]

Examples of the polyamideimide include compounds described in paragraphs 0125 to 0138 of WO2022/145355A. The above description is incorporated in the present specification.

### [Production Method for Polyimide Precursor and Like]

The polyimide precursor and the like are produced, for example, by the method described in paragraphs 0134 to 0136 of WO2022/145355A. The above description is incorporated in the present specification.

### [Content]

The content of the specific resin in the composition is preferably 20% by mass or more, more preferably 30% by mass or more, still more preferably 40% by mass or more, and even still more preferably 50% by mass or more, with respect to the total solid content of the composition. In addition, the content of the resin in the composition is preferably 99.5% by mass or less, more preferably 99% by mass or less, still more preferably 98% by mass or less, still more preferably 97% by mass or less, and even still more preferably 95% by mass or less, with respect to the total solid content of the composition.

The composition may include only one kind of the specific resin or may include two or more kinds thereof. In a case where two or more kinds thereof are contained, the total amount thereof is preferably within the above range.

The composition preferably includes at least two kinds of resins.

Specifically, the composition may contain in total two or more kinds of the specific resins and other resins described later or may contain two or more kinds of the specific resins; however, it is preferable to include two or more kinds of the specific resins.

In a case where the composition contains two or more kinds of the specific resins, it is preferable to contain, for example, two or more kinds of polyimide precursors which are polyimide precursors in which the structure (R¹¹⁵ in Formula (2) described above) derived from the dianhydride is different.

### <Another Resin>

The composition may include the above-described specific resin and another resin different from the specific resin (hereinafter, also simply referred to as “another resin”).

Examples of the other resin include a phenol resin, polyamide, an epoxy resin, polysiloxane, a resin containing a siloxane structure, a (meth)acrylic resin, a (meth)acrylamide resin, a urethane resin, a butyral resin, a styryl resin, a polyether resin, and a polyester resin.

For example, in a case where a (meth)acrylic resin is further added, it is possible to obtain a composition having excellent coatability, and it is possible to obtain a pattern (a cured substance) having excellent solvent resistance.

For example, in a case where a (meth)acrylic resin having a high polymerizable group value and having a weight-average molecular weight of 20,000 or less (for example, a molar content amount of a polymerizable group in 1 g of a resin is 1×10⁻³ mol/g or more) is added to the composition instead of a polymerizable compound described later or in addition to a polymerizable compound described later, it is possible to improve the coatability of the composition, the solvent resistance of the pattern (the cured substance).

In a case where the composition contains the other resin, the content of the other resin is preferably 0.01% by mass or more, more preferably 0.05% by mass or more, still more preferably 1% by mass or more, even still more preferably 2% by mass or more, even still more preferably 5% by mass or more, and even further still more preferably 10% by mass or more, with respect to the total solid content of the composition.

In a case where the composition contains the other resin, the content of the other resin is preferably 80% by mass or less, more preferably 75% by mass or less, still more preferably 70% by mass or less, even still more preferably 60% by mass or less, and even further still more preferably 50% by mass or less, with respect to the total solid content of the composition.

As a preferred aspect of the composition, an aspect in which the content of the other resin is a low content can also be adopted. In the above aspect, the content of the other resin is preferably 20% by mass or less, more preferably 15% by mass or less, still more preferably 10% by mass or less, even still more preferably 5% by mass or less, and even further still more preferably 1% by mass or less, with respect to the total solid content of the composition. The lower limit of the content is not particularly limited, and it may be any content of 0% by mass or more.

The composition may include only one kind of the other resin or may include two or more kinds thereof. In a case where two or more kinds thereof are contained, the total amount thereof is preferably within the above range.

### <Polymerizable Compound>

It is preferable that the composition further contains a polymerizable compound.

Examples of the polymerizable compound include a radical crosslinking agent and another crosslinking agent.

### [Radical Crosslinking Agent]

The composition preferably includes a radical crosslinking agent.

The radical crosslinking agent is a compound having a radically polymerizable group.

The radically polymerizable group is preferably a group containing an ethylenically unsaturated bond. Examples of the group containing an ethylenically unsaturated bond include a vinyl group, an allyl group, a vinylphenyl group, a (meth)acryloyl group, a maleimide group, and a (meth)acrylamide group.

Among these, a (meth)acryloyl group, a (meth)acrylamide group, or a vinylphenyl group is preferable, and from the viewpoint of reactivity, a (meth)acryloyl group is more preferable.

The radical crosslinking agent is preferably a compound having one or more ethylenically unsaturated bonds; however, a compound having two or more ethylenically unsaturated bonds is more preferably contained. The radical crosslinking agent may have three or more ethylenically unsaturated bonds.

The compound having 2 or more ethylenically unsaturated bonds is preferably a compound having 2 to 15 ethylenically unsaturated bonds, more preferably a compound having 2 to 10 ethylenically unsaturated bonds, and still more preferably a compound having 2 to 6 ethylenically unsaturated bonds.

From the viewpoint of the film hardness of the pattern (cured substance) to be obtained, the composition preferably contains a compound having two ethylenically unsaturated bonds and a compound having three or more ethylenically unsaturated bonds.

The molecular weight of the radical crosslinking agent is preferably 2,000 or less, more preferably 1,500 or less, and still more preferably 900 or less. The lower limit of the molecular weight of the radical crosslinking agent is preferably 100 or more.

Specific examples of the radical crosslinking agent include unsaturated carboxylic acids (for example, acrylic acid, methacrylic acid, itaconic acid, crotonic acid, isocrotonic acid, and maleic acid), and esters and amides thereof, where esters between unsaturated carboxylic acids and polyhydric alcohol compounds or amides between unsaturated carboxylic acids and polyvalent amine compounds are preferable. In addition, addition reaction products produced by reacting unsaturated carboxylic acid esters or amides, having a nucleophilic substituent such as a hydroxy group, an amino group, or a sulfanyl group, with monofunctional or polyfunctional isocyanates or epoxies, dehydration condensation reaction products produced by reacting the above esters or amides with a monofunctional or polyfunctional carboxylic acid, or the like are also suitably used. In addition, an addition reaction product produced by reacting unsaturated carboxylic acid esters or amides, having an electrophilic substituent such as an isocyanate group or an epoxy group, with monofunctional or polyfunctional alcohols, amines, or thiols, and further, a substitution reaction product produced by reacting unsaturated carboxylic acid esters or amides, having an eliminable substituent such as a halogeno group or a tosyloxy group, with monofunctional or polyfunctional alcohols, amines, or thiols is also suitable. In addition, as other examples, it is also possible to use a group of compounds in which the unsaturated carboxylic acid described above is replaced with an unsaturated phosphonic acid, a vinylbenzene derivative such as styrene, a vinyl ether, an allyl ether, or the like. Regarding the specific examples thereof, reference can be made to the description of paragraphs 0113 to 0122 of JP2016-027357A, the content of which is incorporated in the present specification.

The radical crosslinking agent is also preferably a compound having a boiling point of 100° C. or higher under normal pressure. Examples of the compound having a boiling point of 100° C. or higher under normal pressure include the compounds described in paragraph 0203 of WO2021/112189A. The content thereof is incorporated in the present specification.

Examples of the preferred radical crosslinking agent other than those described above include the radically polymerizable compounds described in paragraphs 0204 to 0208 of WO2021/112189A. The content thereof is incorporated in the present specification.

As the radical crosslinking agent, dipentaerythritol triacrylate (as a commercially available product, KAYARAD D-330 (manufactured by Nippon Kayaku Co., Ltd.), dipentaerythritol tetraacrylate (as a commercially available product, KAYARAD D-320 (manufactured by Nippon Kayaku Co., Ltd.), A-TMMT (manufactured by Shin-Nakamura Chemical Co., Ltd.), dipentaerythritol penta(meth)acrylate (as a commercially available product, KAYARAD D-310 (manufactured by Nippon Kayaku Co., Ltd.), dipentaerythritol hexa(meth)acrylate (as a commercially available product, KAYARAD DPHA (manufactured by Nippon Kayaku Co., Ltd.), A-DPH (manufactured by Shin-Nakamura Chemical Co., Ltd.), or a structure in which a (meth)acryloyl group thereof is bonded through an ethylene glycol residue or a propylene glycol residue is preferable. Oligomer types thereof can also be used.

Examples of the commercially available product of the radical crosslinking agent include SR-494 which is a tetrafunctional acrylate having four ethyleneoxy chains, SR-209, 231, and 239 which are a difunctional methacrylate having four ethyleneoxy chains (all of which are manufactured by Sartomer Company Inc.), DPCA-60 which is a hexafunctional acrylate having six pentyleneoxy chains and TPA-330 which is a trifunctional acrylate having three isobutylene oxy chains (all of which are manufactured by Nippon Kayaku Co., Ltd.), UAS-10 and UAB-140 which are a urethane oligomer (all of which are manufactured by Nippon Paper Industries Co., Ltd.), NK Ester M-40Q NK Ester 4Q NK Ester M-9300, NK Ester A-9300, and UA-7200 (all of which are manufactured by Shin-Nakamura Chemical Co., Ltd.), DPHA-40H (manufactured by Nippon Kayaku Co., Ltd.), UA-306H, UA-306T, UA-306I, AH-600, T-600, and AI-600 (all of which are manufactured by KYOEISHA CHEMICAL Co., Ltd.), and Brenmer PME400 (manufactured by NOF Corporation).

As the radical crosslinking agent, the urethane acrylates as described in JP1973-041708B (JP-S48-041708B), JP1976-037193A (JP-S51-037193A), JP1990-032293B (JP-H02-032293B), and JP1990-016765B (JP-H02-016765B), and the urethane compounds having an ethylene oxide-based skeleton described in JP1983-049860B (JP-S58-049860B), JP1981-017654B (JP-S56-017654B), JP1987-039417B (JP-S62-039417B), and JP1987-039418B (JP-S62-039418B) are also suitable. As the radical crosslinking agent, the compounds having an amino structure or a sulfide structure in the molecule as described in JP1988-277653A (JP-S63-277653A), JP1988-260909A (JP-S63-260909A), and JP1989-105238A (JP-H01-105238A) can also be used.

The radical crosslinking agent may be a radical crosslinking agent having an acid group such as a carboxy group or a phosphoric acid group. The radical crosslinking agent having an acid group is preferably an ester between an aliphatic polyhydroxy compound and an unsaturated carboxylic acid and more preferably a radical crosslinking agent obtained by reacting an unreacted hydroxy group of an aliphatic polyhydroxy compound with a non-aromatic carboxylic acid anhydride to have an acid group. The radical crosslinking agent is particularly preferably a compound in which an aliphatic polyhydroxy compound is pentaerythritol or dipentaerythritol in a radical crosslinking agent having an acid group obtained by reacting an unreacted hydroxy group of the aliphatic polyhydroxy compound with a non-aromatic carboxylic acid anhydride. Examples of the commercially available product thereof include M-510 and M-520 as polybasic acid-modified acrylic oligomers which are manufactured by Toagosei Co., Ltd.

An acid value of the radical crosslinking agent having an acid group is preferably 0.1 to 300 mgKOH/g and more preferably 1 to 100 mgKOH/g. In a case where the acid value of the radical crosslinking agent is within the above-described range, excellent manufacturing handleability is exhibited, and excellent developability is exhibited. In addition, good polymerization properties are exhibited. The acid value is measured in accordance with the description of JIS K 0070: 1992.

The radical crosslinking agent is also preferably a radical crosslinking agent having at least one selected from the group consisting of a urea bond and a urethane bond (hereinafter, also referred to as a “crosslinking agent U”).

In the present invention, the urea bond is a bond represented by *—NR^{N}—C(═O)—NR^{N}*, where R^{N}'s each independently represent a hydrogen atom or a monovalent organic group, and *'s each represent a bonding site to a carbon atom.

In the present invention, the urethane bond is a bond represented by *—O—C(═O)—NR^{N}—*, where R^{N} represents a hydrogen atom or a monovalent organic group, and *'s each represent a bonding site to a carbon atom.

In a case where the composition contains a crosslinking agent U, chemical resistance, resolution, and the like may be improved.

The crosslinking agent U may have only one urea bond or urethane bond, may have one or more urea bonds and one or more urethane bonds, may have two or more urea bonds without having a urethane bond, or may have two or more urethane bonds without having a urea bond.

The total number of urea bonds and urethane bonds in the crosslinking agent U is 1 or more, and it is preferably 1 to 10, more preferably 1 to 4, and still more preferably 1 or 2.

in a case where the crosslinking agent U does not have a urethane bond, the number of urea bonds in the crosslinking agent U is 1 or more, and it is preferably 1 to 10, more preferably 1 to 4, and still more preferably 1 or 2.

in a case where the crosslinking agent U does not have a urea bond, the number of urethane bonds in the crosslinking agent U is 1 or more, and it is preferably 1 to 10, more preferably 1 to 4, and still more preferably 1 or 2.

The radically polymerizable group in the crosslinking agent U is not particularly limited; however, examples thereof include a vinyl group, an allyl group, a (meth)acryloyl group, a (meth)acryloxy group, a (meth)acrylamide group, a vinylphenyl group, and a maleimide group, where a (meth)acryloxy group, a (meth)acrylamide group, a vinylphenyl group, or a maleimide group is preferable, and a (meth)acryloxy group is more preferable.

In a case where the crosslinking agent U has two or more radically polymerizable groups, the structures of the respective radically polymerizable groups may be the same or different from each other.

The number of radically polymerizable groups in the crosslinking agent U may be only one or may be two or more, and it is preferably 1 to 10, more preferably 1 to 6, and particularly preferably 1 to 4.

The radically polymerizable group value (the mass of the compound per 1 mol of the radically polymerizable group) in the crosslinking agent U is preferably 150 to 400 g/mol.

From the viewpoint of the chemical resistance of the cured substance, the lower limit of the above-described radically polymerizable group value is more preferably 200 g/mol or more, still more preferably 210 g/mol or more, even more preferably 220 g/mol or more, even still more preferably 230 g/mol or more, even still more preferably 240 g/mol or more, and particularly preferably 250 g/mol or more.

From the viewpoint of developability, the upper limit of the above-described radically polymerizable group value is more preferably 350 g/mol or less, still more preferably 330 g/mol or less, and particularly preferably 300 g/mol or less.

Among the above, the polymerizable group value of the crosslinking agent U is preferably 210 to 400 g/mol and more preferably 220 to 400 g/mol.

The crosslinking agent U has preferably, for example, a structure represented by Formula (U-1).

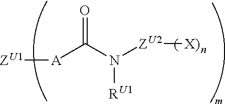

In Formula (U-1), R^{U1} is a hydrogen atom or a monovalent organic group, A is —O—, or —NR^{N}—, R^{N} is a hydrogen atom or a monovalent organic group, Z^{U1} is an m-valent organic group, Z^{U2} is an (n+1)-valent organic group, X is a radically polymerizable group, n is an integer of 1 or more, and m is an integer of 1 or more.

R^{U1} is preferably a hydrogen atom, an alkyl group, or an aromatic hydrocarbon group, and more preferably a hydrogen atom.

R^{N} is preferably a hydrogen atom, an alkyl group, or an aromatic hydrocarbon group, and more preferably a hydrogen atom.

Z^{U1} is preferably a hydrocarbon group, —O—, —C(═O)—, —S—, —S(═O)₂—, —NR^{N}—, or a group in which two or more of these are bonded, and more preferably a hydrocarbon group or a group in which a hydrocarbon group is bonded to at least one group selected from the group consisting of —O—, —C(═O)—, —S—, —S(═O)₂—, and —NR^{N}—.

As the above-described hydrocarbon group, a hydrocarbon group having 20 or less carbon atoms is preferable, a hydrocarbon group having 18 or less carbon atoms is more preferable, and a hydrocarbon group having 16 or less carbon atoms is still more preferable. Examples of the above-described hydrocarbon group include a saturated aliphatic hydrocarbon group, an aromatic hydrocarbon group, and a group represented by bonding of these groups. R^{N} represents a hydrogen atom or a monovalent organic group, and it is preferably a hydrogen atom or a hydrocarbon group, more preferably a hydrogen atom or an alkyl group, and still more preferably a hydrogen atom or a methyl group.

Z^{U2} is preferably a hydrocarbon group, —O—, —C(═O)—, —S—, —S(═O)₂—, —NR^{N}—, or a group in which two or more of these are bonded, and more preferably a hydrocarbon group or a group in which a hydrocarbon group is bonded to at least one group selected from the group consisting of —O—, —C(═O)—, —S—, —S(═O)₂—, and —NR^{N}—.

Examples of the hydrocarbon group include the same ones as those exemplified as Z^{U1}, and the same applies to the preferred aspect thereof.

X is not particularly limited; however, examples thereof include a vinyl group, an allyl group, a (meth)acryloyl group, a (meth)acryloxy group, a (meth)acrylamide group, a vinylphenyl group, and a maleimide group, where a (meth)acryloxy group, a (meth)acrylamide group, a vinylphenyl group, or a maleimide group is preferable, and a (meth)acryloxy group is more preferable.

n is preferably an integer of 1 to 10, more preferably an integer of 1 to 4, still more preferably 1 or 2, and particularly preferably 1.

m is preferably an integer of 1 to 10, more preferably an integer of 1 to 4, and still more preferably 1 or 2.

It is also preferable that the crosslinking agent U has at least one of a hydroxy group, an alkyleneoxy group, an amide group, or a cyano group.

From the viewpoint of the chemical resistance of the cured film to be obtained, the hydroxy group may be an alcoholic hydroxy group or a phenolic hydroxy group; however, it is preferably an alcoholic hydroxy group.

From the viewpoint of the chemical resistance of the cured film to be obtained, the alkyleneoxy group is preferably an alkyleneoxy group having 2 to 20 carbon atoms, more preferably an alkyleneoxy group having 2 to 10 carbon atoms, still more preferably an alkyleneoxy group having 2 to 4 carbon atoms, even still more preferably an ethyleneoxy group or a propyleneoxy group, and particularly preferably an ethylene group.

The alkyleneoxy group may be contained in the crosslinking agent U as a polyalkyleneoxy group. The number of repetitions of the alkyleneoxy group in this case is preferably 2 to 10 and more preferably 2 to 6.

The amide group refers to a bond represented by —C(═O)—NR^{N}—. R^{N} is as described above. In a case where the crosslinking agent U has an amide group, the crosslinking agent U can include, for example, a group represented by R—C(═O)—NR^{N}—* or a group represented by *—C(═O)—NR^{N}—R. R represents a hydrogen atom or a monovalent substituent, and it is preferably a hydrogen atom or a hydrocarbon group and more preferably a hydrogen atom, an alkyl group, or an aromatic hydrocarbon group.

The crosslinking agent U may have, in the molecule, two or more structures selected from the group consisting of a hydroxy group, an alkyleneoxy group (however, a polyalkyleneoxy group in a case of constituting a polyalkyleneoxy group), an amide group, and a cyano group; however, an aspect in which only one structure is contained in the molecule is also preferable.

The hydroxy group, the alkyleneoxy group, the amide group, and the cyano group may be present at any position of the crosslinking agent U. However, from the viewpoint of chemical resistance, it is also preferable that the crosslinking agent U is such that at least one selected from the group consisting of the hydroxy group, the alkyleneoxy group, the amide group, and the cyano group, and at least one radically polymerizable group contained in the crosslinking agent U are linked by a linking group (hereinafter, also referred to as a “linking group L2-1”) containing a urea bond or a urethane bond.

In particular, in a case where the crosslinking agent U contains only one radically polymerizable group, it is preferable that the radically polymerizable group contained in the crosslinking agent U and at least one selected from the group consisting of a hydroxy group, an alkyleneoxy group, an amide group, and a cyano group are linked by a linking group including a urea bond or a urethane bond (hereinafter, also referred to as a “linking group L2-2”).

In a case where the crosslinking agent U contains an alkyleneoxy group (however, a polyalkyleneoxy group in a case of constituting a polyalkyleneoxy group) and has the above-described linking group L2-1 or the above-described linking group L2-2, a structure that is bonded to a side of the alkyleneoxy group (however, a polyalkyleneoxy group in a case of constituting a polyalkyleneoxy group) opposite to the linking group L2-1 or the linking group L2-2 is not particularly limited; however, it is preferably a hydrocarbon group, a radically polymerizable group, or a group represented by a combination thereof. As the above-described hydrocarbon group, a hydrocarbon group having 20 or less carbon atoms is preferable, a hydrocarbon group having 18 or less carbon atoms is more preferable, and a hydrocarbon group having 16 or less carbon atoms is still more preferable. Examples of the above-described hydrocarbon group include a saturated aliphatic hydrocarbon group, an aromatic hydrocarbon group, and a group represented by bonding of these groups. In addition, the preferred aspect of the radically polymerizable group is the same as the preferred aspect of the radically polymerizable group in the above-described crosslinking agent U.

In a case where the crosslinking agent U contains an amide group and has the linking group L2-1 or the linking group L2-2, a structure that is bonded to a side of the amide group opposite to the linking group L2-1 or the linking group L2-2 is not particularly limited; however, it is preferably a hydrocarbon group, a radically polymerizable group, or a group represented by a combination thereof. As the above-described hydrocarbon group, a hydrocarbon group having 20 or less carbon atoms is preferable, a hydrocarbon group having 18 or less carbon atoms is more preferable, and a hydrocarbon group having 16 or less carbon atoms is still more preferable. In addition, examples of the above-described hydrocarbon group include a saturated aliphatic hydrocarbon group, an aromatic hydrocarbon group, and a group represented by bonding of these groups. The preferred aspect of the radically polymerizable group is the same as the preferred aspect of the radically polymerizable group in the above-described crosslinking agent U. In addition, in the above aspect, a carbon atom side of the amide group may be bonded to the linking group L2-1 or the linking group L2-2, or a nitrogen atom side of the amide group may be bonded to the linking group L2-1 or the linking group L2-2.

Among these, from the viewpoint of the adhesiveness to the base material, the chemical resistance, and the Cu void suppression, the crosslinking agent U preferably has a hydroxy group.

From the viewpoint of compatibility with the heterocyclic ring-containing polymer and the like, the crosslinking agent U preferably includes an aromatic group.

The aromatic group is preferably directly bonded to a urea bond or a urethane bond contained in the crosslinking agent U. In a case where the crosslinking agent U contains two or more urea bonds or two or more urethane bonds, it is preferable that one of the urea bonds or urethane bonds is directly bonded to the aromatic group.

The aromatic group may be an aromatic hydrocarbon group or an aromatic heterocyclic group and may have a structure in which these groups form a fused ring; however, an aromatic hydrocarbon group is preferable.

The aromatic hydrocarbon group is preferably an aromatic hydrocarbon group having 6 to 30 carbon atoms, more preferably an aromatic hydrocarbon group having 6 to 20 carbon atoms, and still more preferably a group obtained by removing two or more hydrogen atoms from a benzene ring structure.

The aromatic heterocyclic group is preferably a 5-membered or 6-membered aromatic heterocyclic group. Examples of the aromatic heterocyclic ring in such an aromatic heterocyclic group include pyrrole, imidazole, triazole, tetrazole, pyrazole, furan, thiophene, oxazole, isoxazole, thiazole, pyridine, pyrazine, pyrimidine, pyridazine, and triazine. These rings may be further fused with another ring, for example, as in the case of indole or benzimidazole.

The heteroatom contained in the aromatic heterocyclic group is preferably a nitrogen atom, an oxygen atom, or a sulfur atom.

It is preferable that the aromatic group is included in, for example, a linking group that links two or more radically polymerizable groups and links a linking group having a urea bond or a urethane bond, or at least one selected from the group consisting of a hydroxy group, an alkyleneoxy group, an amide group, and a cyano group, to at least one radically polymerizable group contained in the crosslinking agent U.

The number of atoms (linking chain length) between the urea bond or urethane bond and the radically polymerizable group in the crosslinking agent U is not particularly limited; however, it is preferably 30 or less, more preferably 2 to 20, and still more preferably 2 to 10.

In a case where the crosslinking agent U contains two or more urea bonds or urethane bonds in total, the minimum number of atoms (linking chain length) between the urea bond or urethane bond and the radically polymerizable group is sufficient to be within the above-described range in a case where the crosslinking agent U contains two or more radically polymerizable groups, or in a case where the crosslinking agent U contains two or more urea bonds or two or more urethane bonds and two or more radically polymerizable groups.

In the present specification, the phrase “number of atoms (linking chain length) between the urea bond or urethane bond and the polymerizable group” refers to the smallest number of atoms (minimum number of atoms) for linking targets among the number of atoms for atomic chains on a path that links two atoms or atomic groups between the linking targets. For example, in a structure represented by the following Formula, the number of atoms (linking chain length) between the urea bond and the radically polymerizable group (methacryloyloxy group) is 2.

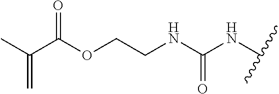 [SMILES: *NC(=O)NCCOC(=O)C(=C)C]

### [Symmetry Axis]

It is also preferable that the crosslinking agent U is a compound having a structure which does not have a symmetry axis.

The fact that the crosslinking agent U does not have a symmetry axis refers to that the crosslinking agent U is a left-right asymmetric compound which does not have an axis that generates the same molecule as the original molecule in a case where the entire compound is rotated. In addition, in a case where the structural formula of the crosslinking agent U is shown on the paper surface, the fact that the crosslinking agent U does not have a symmetry axis refers to that the structural formula of the crosslinking agent U cannot be shown in a form having a symmetry axis.

It is considered that the aggregation of the crosslinking agents U is suppressed in the composition film in a case where the crosslinking agent U does not have a symmetry axis.

### [Molecular Weight]

The molecular weight of the crosslinking agent U is preferably 100 to 2,000, more preferably 150 to 1,500, and still more preferably 200 to 900.

A manufacturing method for the crosslinking agent U is not particularly limited; however, the crosslinking agent U can be obtained, for example, by reacting a radically polymerizable compound with a compound having an isocyanate group and a compound having at least one of a hydroxy group or an amino group.

Specific examples of the crosslinking agent U are shown below; however, the crosslinking agent U is not limited thereto.

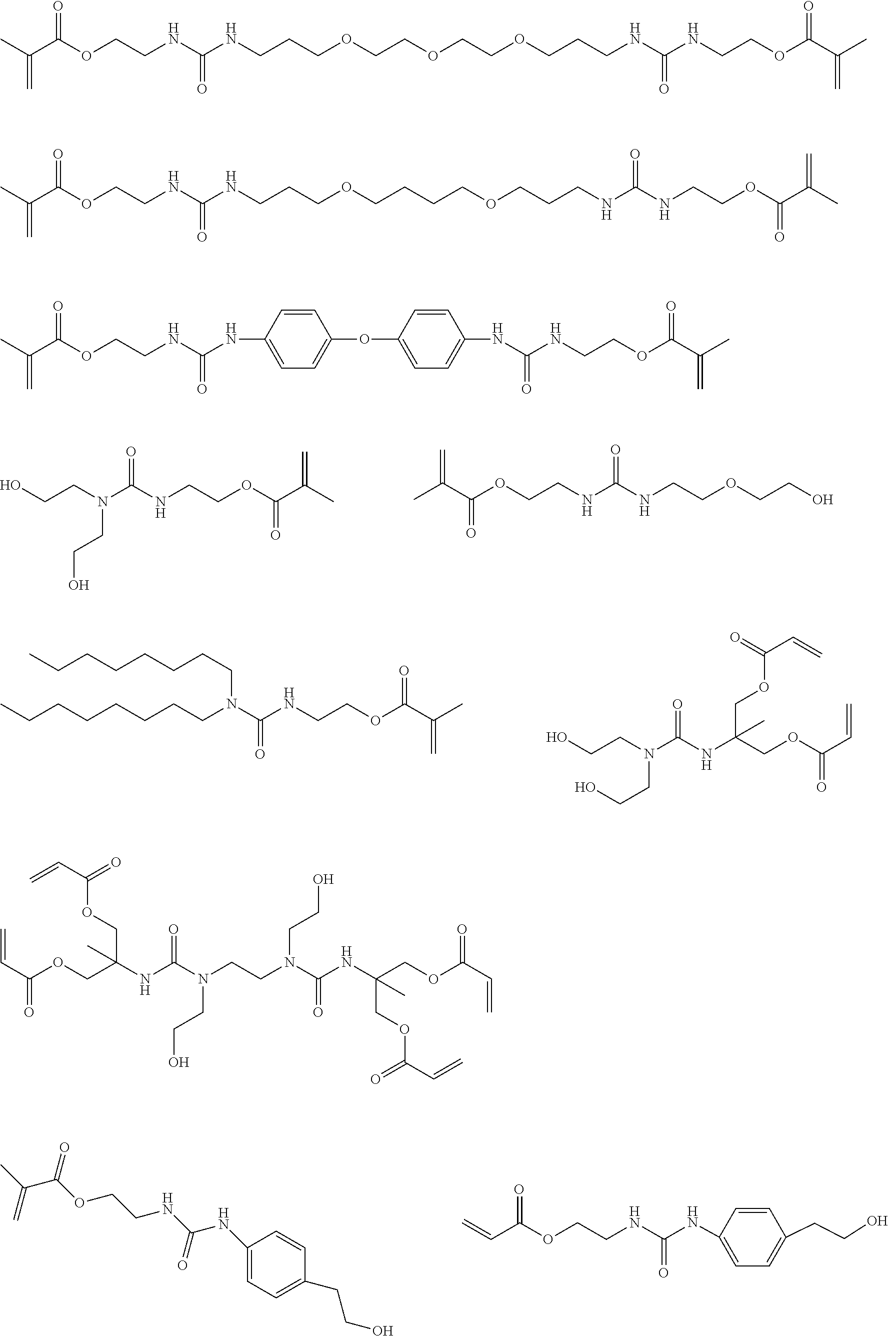

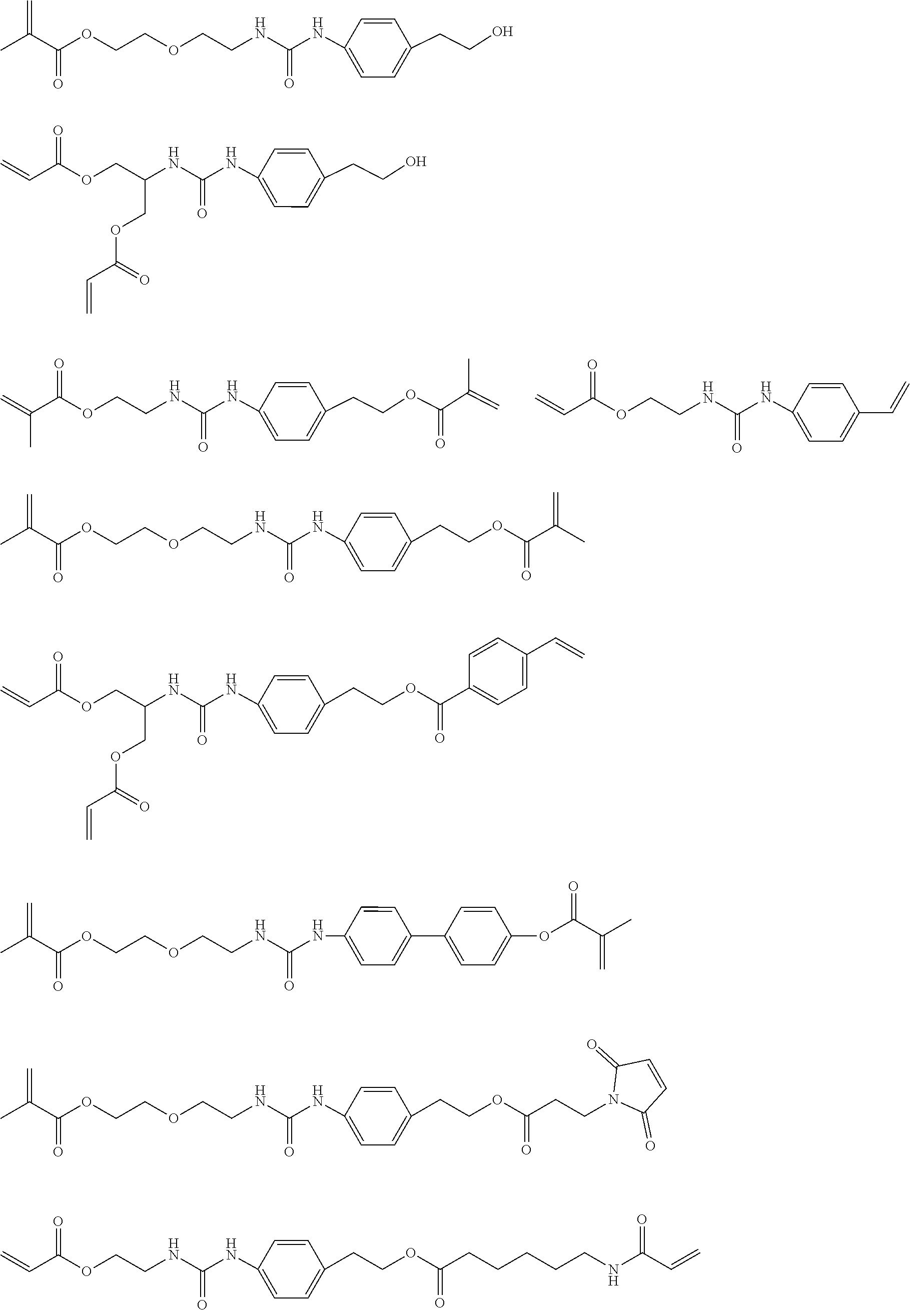

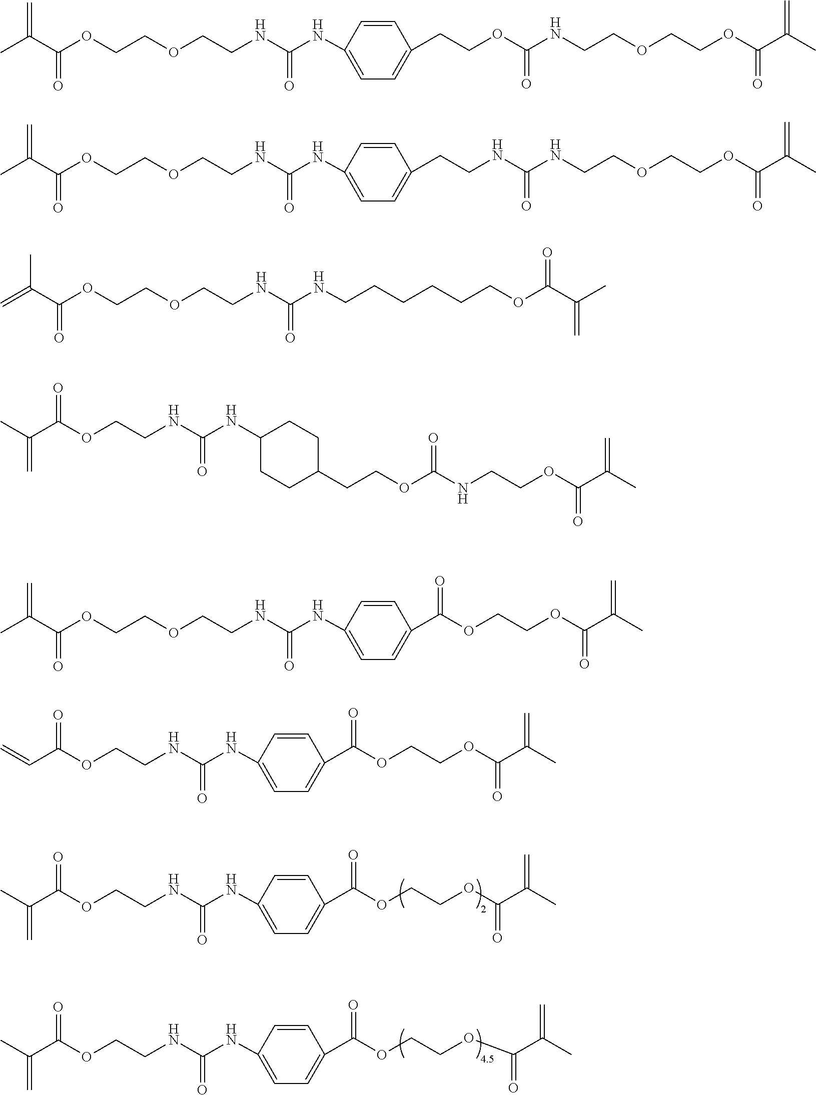

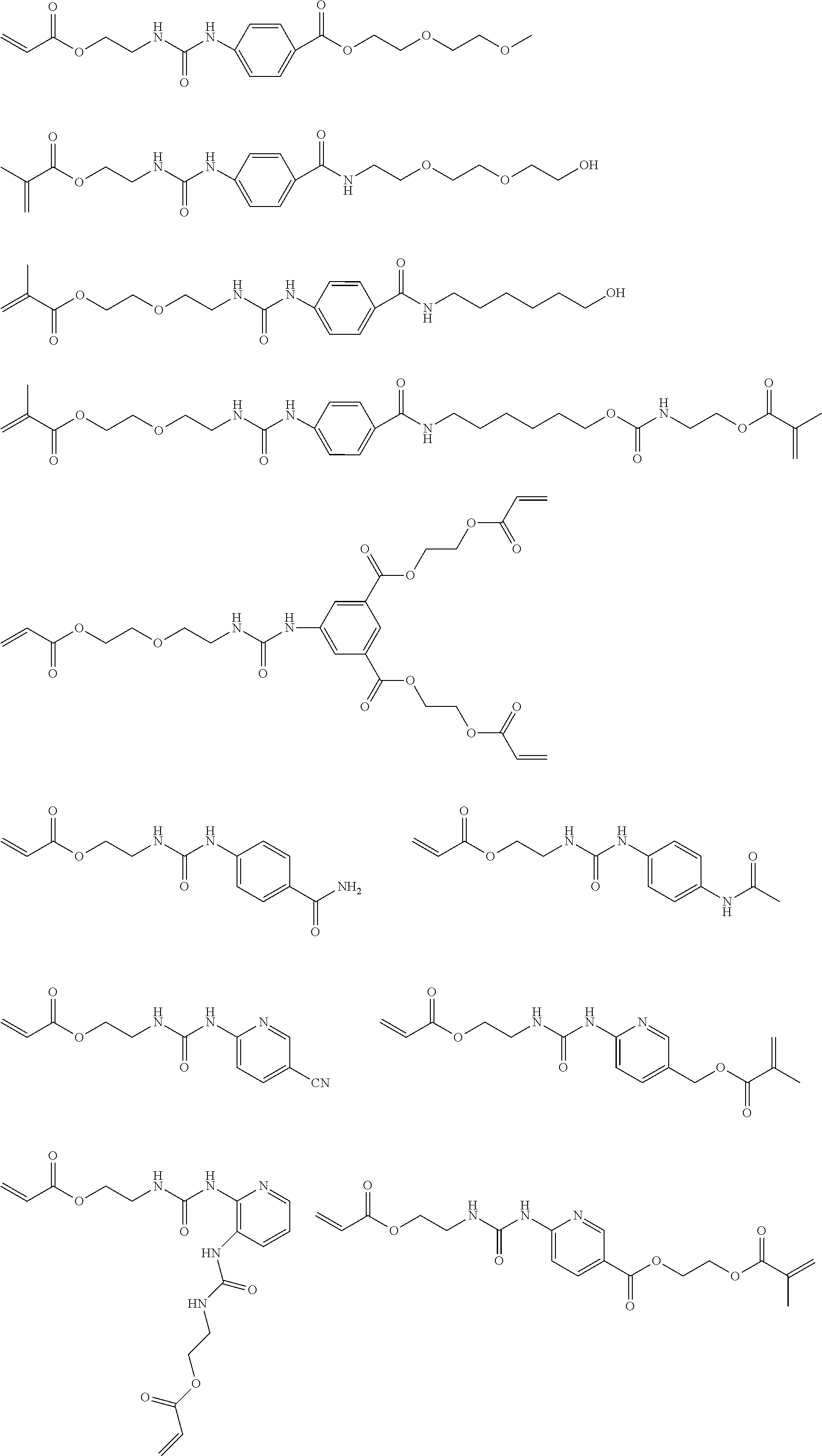

In the composition, it is preferable to use difunctional methacrylate or acrylate from the viewpoint of pattern resolution and film elasticity.

As the specific compound, the following compound can be used; triethylene glycol diacrylate, triethylene glycol dimethacrylate, tetraethylene glycol dimethacrylate, tetraethylene glycol diacrylate, polyethylene glycol (PEG) 200 diacrylate, PEG 200 dimethacrylate, PEG 600 diacrylate, PEG 600 dimethacrylate, polytetraethylene glycol diacrylate, polytetraethylene glycol dimethacrylate, dipropylene glycol diacrylate, tripropylene glycol diacrylate, neopentyl glycol diacrylate, neopentyl glycol dimethacrylate, 3-methyl-1, 5-pentanediol diacrylate, 1,6-hexanediol diacrylate, 1,6-hexanediol dimethacrylate, dimethylol-tricyclodecanediacrylate, dimethylol-tricyclodecanedimethacrylate, a diacrylate of an ethylene oxide (EO) adduct of bisphenol A, a dimethacrylate of an EO adduct of bisphenol A, a diacrylate of a propylene oxide (PO) adduct of bisphenol A, a dimethacrylate of a PO adduct of bisphenol A, 2-hydroxy-3-acryloyloxypropyl methacrylate, isocyanuric acid EO-modified diacrylate, isocyanuric acid EO-modified dimethacrylate, another difunctional acrylate having a urethane bond, and difunctional methacrylate having a urethane bond. As necessary, two or more of these can be mixedly used.

It is noted that, for example, the PEG 200 diacrylate refers to a polyethylene glycol diacrylate having a polyethylene glycol chain Formula weight of about 200.

From the viewpoint of suppressing warping of the pattern (cured substance), the composition can preferably use a monofunctional radical crosslinking agent as the radical crosslinking agent. As the monofunctional radical crosslinking agent, (meth)acrylic acid derivatives such as n-butyl (meth)acrylate, 2-ethylhexyl (meth)acrylate, 2-hydroxyethyl (meth)acrylate; butoxyethyl (meth)acrylate, carbitol (meth)acrylate, cyclohexyl (meth)acrylate, benzyl (meth)acrylate, phenoxyethyl (meth)acrylate, N-methylol (meth)acrylamide, glycidyl (meth)acrylate, polyethylene glycol mono(meth)acrylate, and polypropylene glycol mono(meth)acrylate, N-vinyl compounds such as N-vinylpyrrolidone and N-vinylcaprolactam, allyl glycidyl ethers, and the like are preferably used. As the monofunctional radical crosslinking agent, a compound having a boiling point of 100° C. or higher under normal pressure is also preferable in order to suppress volatilization before exposure.

In addition, examples of the bi- or higher functional radical crosslinking agent include allyl compounds such as diallyl phthalate and triallyl trimellitate.

In a case where a radical crosslinking agent is contained, the content of the radical crosslinking agent is preferably more than 0% by mass and 60% by mass or less with respect to the total solid content of the composition. The lower limit thereof is more preferably 5% by mass or more. The upper limit thereof is more preferably 50% by mass or less and still more preferably 30% by mass or less.

One kind of radical crosslinking agent may be used alone, or two or more kinds thereof may be mixedly used. In a case where two or more kinds thereof are used in combination, the total amount thereof is preferably in the above range.

### [Another Crosslinking Agent]

The composition preferably includes a crosslinking agent different from the above-described radical crosslinking agent.

The other crosslinking agent refers to a crosslinking agent other than the above-described radical crosslinking agent, where it is preferably a compound having a plurality of groups, in the molecule, which accelerates a reaction of forming a covalent bond between other compounds in the composition or reaction products thereof, by the photosensitization of the above-described photoacid generator or photobase generator, and more preferably a compound having a plurality of groups, in the molecule, which accelerates a reaction of forming a covalent bond between other compounds in the composition or reaction products thereof, by the action of the acid or the base.

The acid or the base is preferably an acid or a base, which is generated from a photoacid generator or a photobase generator in the exposure step.

Examples of the other crosslinking agent include the compounds described in paragraphs 0179 to 0207 of WO2022/145355A. The above description is incorporated in the present specification.

### [Polymerization Initiator]

The composition preferably contains a polymerization initiator.

The polymerization initiator may be a thermal polymerization initiator or a photopolymerization initiator; however, it is particularly preferable to contain a photopolymerization initiator.

The photopolymerization initiator is preferably a photoradical polymerization initiator. The photoradical polymerization initiator is not particularly limited and can be appropriately selected from publicly known photoradical polymerization initiators. For example, a photoradical polymerization initiator having photosensitivity to rays ranging from the ultraviolet ray range to the visible light range is preferable. In addition, it may be an activator that acts with a sensitizing agent to generate an active radical.

The photoradical polymerization initiator preferably contains at least one compound having a molar absorption coefficient of at least about 50 L·mol⁻¹·cm⁻¹ within a range of a wavelength of about 240 to 800 nm (preferably 330 to 500 nm). The molar absorption coefficient of a compound can be measured using a well-publicly known method. For example, it is preferable to carry out a measurement at a concentration of 0.01 g/L using an ethyl acetate solvent with an ultraviolet-visible spectrophotometer (Cary-5 spectrophotometer manufactured by Varian Medical Systems, Inc.).

As a photoradical polymerization initiator, well-known compounds can be optionally used. Examples thereof include a halogenated hydrocarbon derivative (for example, a compound having a triazine skeleton, a compound having an oxadiazole skeleton, or a compound having a trihalomethyl group), an acylphosphine compound such as an acylphosphine oxide, hexaarylbiimidazole, an oxime compound such as an oxime derivative, an organic peroxide, a thio compound, a ketone compound, an aromatic onium salt, a keto oxime ether, an a-amino ketone compound such as aminoacetophenone, an a-hydroxy ketone compound such as hydroxyacetophenone, an azo-based compound, an azide compound, a metallocene compound, an organic boron compound, and an iron arene complex. With regard to details thereof, reference can be made to the description of paragraphs 0165 to 0182 of JP2016-027357A and paragraphs 0138 to 0151 of WO2015/199219A, the contents of which are incorporated in the present specification. In addition, examples thereof include the compounds described in paragraphs 0065 to 0111 of JP2014-130173A and JP6301489B, the peroxide-based photopolymerization initiator described in MATERIAL STAGE 37 to 60 p, vol. 19, No. 3, 2019, the photopolymerization initiator described in WO2018/221177A, the photopolymerization initiator described in WO2018/110179A, the photopolymerization initiator described in JP2019-043864A, the photopolymerization initiator described in JP2019-044030A, and the peroxide-based initiator described in JP2019-167313A, the contents of which are incorporated in the present specification.

Examples of the ketone compound include compounds described in paragraph 0087 of JP2015-087611A, the content of which is incorporated in the present specification. As a commercially available product thereof, KAYACURE DETX-S (manufactured by Nippon Kayaku Co., Ltd.) is also suitably used.

In one embodiment of the present invention, a hydroxyacetophenone compound, an aminoacetophenone compound, and an acylphosphine compound can be suitably used as the photoradical polymerization initiator. More specifically, for example, the aminoacetophenone-based initiator described in JP1998-291969A (JP-H10-291969A) and the acylphosphine oxide-based initiator described in JP4225898B can be used, the contents of which are incorporated in the present specification.

As the α-hydroxy ketone-based initiator, Omnirad 184, Omnirad 1173, Omnirad 2959, Omnirad 127 (all of which are manufactured by IGM Resins B.V), IRGACURE 184 (IRGACURE is a registered trademark), DAROCUR 1173, IRGACURE 500, IRGACURE-2959, and IRGACURE 127 (all of which are manufactured by BASF SE) can be used.

As the α-amino ketone-based initiator, Omnirad 907, Omnirad 369, Omnirad 369E, Omnirad 379EG (all of which are manufactured by IGM Resins B.V.), IRGACURE 907, IRGACURE 369, and IRGACURE 379 (all of which are manufactured by BASF SE) can be used.

As the aminoacetophenone-based initiator, the acylphosphine oxide-based initiator, and the metallocene compound, it is also possible to suitably use, for example, the compounds described in paragraphs 0161 to 0163 of WO2021/112189A. The content thereof is incorporated in the present specification.

Examples of the more preferred photoradical polymerization initiator include an oxime compound. In a case where an oxime compound is used, exposure latitude can be more effectively improved. The oxime compound is particularly preferable since the oxime compound has a wide exposure latitude (a wide exposure margin) and also works as a photocuring accelerator.

Specific examples of the oxime compound include the compounds described in JP2001-233842A, the compounds described in JP2000-080068A, the compounds described in JP2006-342166A, the compounds described in J.C.S. Perkin II (1979, pp. 1653-1660), the compounds described in J.C.S. Perkin II (1979, pp. 156-162), the compounds described in Journal of Photopolymer Science and Technology (1995, pp. 202-232), the compounds described in JP2000-066385A, the compounds described in JP2004-534797A, the compounds described in JP2017-019766A, the compounds described in JP6065596B, the compounds described in WO2015/152153A, the compounds described in WO2017/051680A, the compounds described in JP2017-198865A, the compounds described in paragraph Nos. 0025 to 0038 of WO2017/164127A, and the compounds described in WO2013/167515A, the content of which is incorporated in the present specification.

Examples of the preferred oxime compound include compounds having the following structures, 3-(benzoyloxy(imino))butan-2-one, 3-(acetoxy(imino))butan-2-one, 3-(propionyloxy(imino))butan-2-one, 2-(acetoxy(imino))pentan-3-one, 2-(acetoxy(imino))-1-phenylpropan-1-one, 2-(benzoyloxy(imino))-1-phenylpropan-1-one, 3-((4-toluenesulfonyloxy)imino)butan-2-one, and 2-(ethoxycarbonyloxy(imino))-1-phenylpropan-1-one. In the composition, it is preferable to use an oxime compound, particularly as a photoradical polymerization initiator. The oxime compound as a photoradical polymerization initiator has a linking group of >C═N—O—C(═O)— in the molecule.

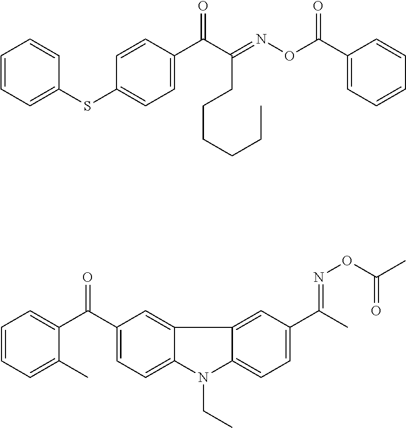 [SMILES: CCCCCC/C(=N\OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21]

Examples of the commercially available product of the oxime compound include IRGACURE OXE 01, IRGACURE OXE 02, IRGACURE OXE 03, and IRGACURE OXE 04 (all of which are manufactured by BASF SE), ADEKA OPTOMER N-1919 (manufactured by ADEKA Corporation, the photoradical polymerization initiator 2 described in JP2012-014052A), TR-PBG-304 and TR-PBG-305 (all of which are manufactured by Changzhou Tronly New Electronic Materials Co., Ltd.), ADEKA ARKLS NCI-730, NCI-831, and ADEKA ARKLS NCI-930 (all of which are manufactured by ADEKA Corporation), DFI-091 (manufactured by DAITO CHEMIX Co., Ltd.), and SpeedCure PDO (manufactured by SARTOMER ARKEMA). In addition, oxime compounds having the following structures can also be used.

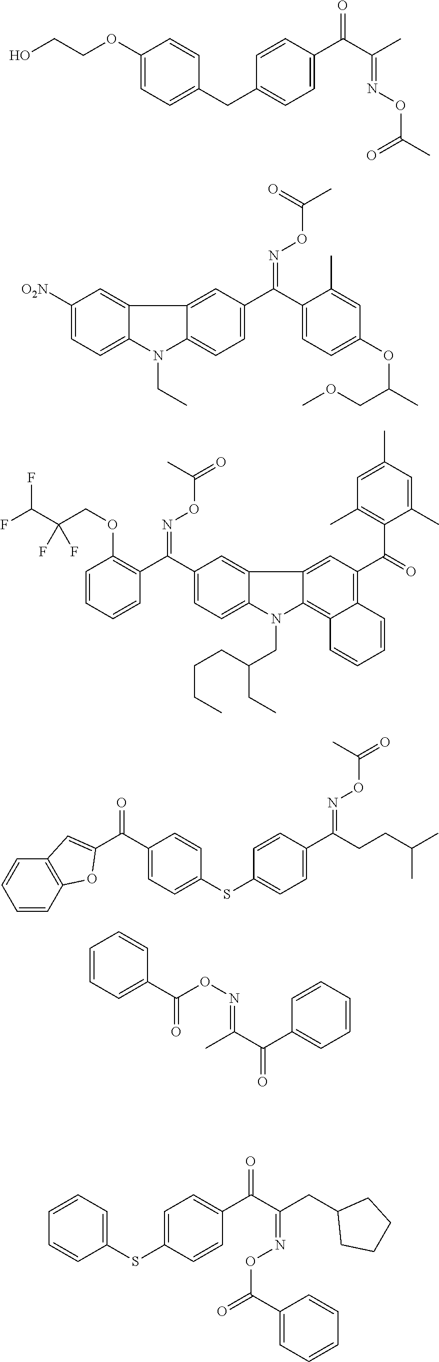

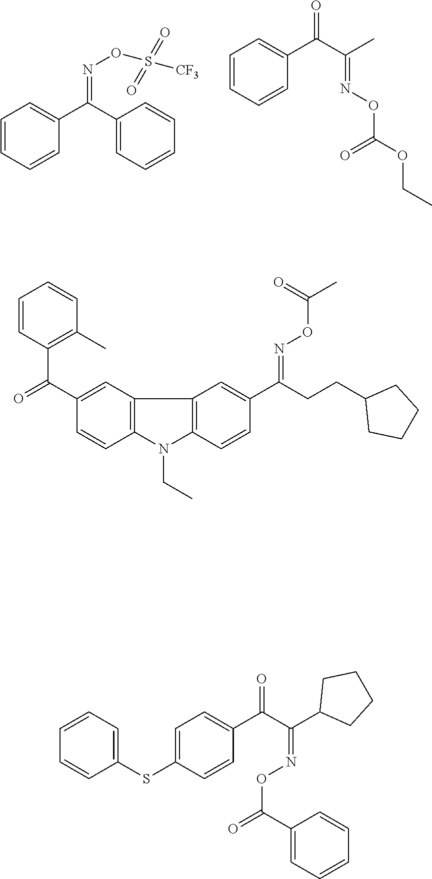 [SMILES: O=S(=O)(ON=C(c1ccccc1)c1ccccc1)C(F)(F)F ; CCOC(=O)O/N=C(\C)C(=O)c1ccccc1 ; CCn1c2ccc(C(=O)c3ccccc3C)cc2c2cc(/C(CCC3CCCC3)=N/OC(C)=O)ccc21 ; O=C(O/N=C(\C(=O)c1ccc(Sc2ccccc2)cc1)C1CCCC1)c1ccccc1]

As the photoradical polymerization initiator, it is also possible to use, for example, the oxime compounds having a fluorene ring, which are described in paragraphs 0169 to 0171 of WO2021/112189A, an oxime compound having a skeleton in which at least one benzene ring of a carbazole ring is a naphthalene ring, or an oxime compound having a fluorine atom.

In addition, it is also possible to use the oxime compounds having a nitro group, which are described in paragraphs 0208 to 0210 of WO2021/020359A, an oxime compound having a benzofuran skeleton, or an oxime compound in which a substituent having a hydroxy group is bonded to a carbazole skeleton. The content thereof is incorporated in the present specification.

In addition, as the photopolymerization initiator, compounds described in paragraphs 0113 to 0117 of JP2023-058585A can also be used. This description is incorporated in the present specification.

In a case where the composition contains a photopolymerization initiator, the content thereof is preferably 0.1% to 30% by mass, more preferably 0.1% to 20% by mass, still more preferably 0.5% to 15% by mass, and even still more preferably 1.0% to 10% by mass with respect to the total solid content of the composition. Only one kind of photopolymerization initiator may be contained, or two or more kinds thereof may be contained. In a case where two or more kinds of photopolymerization initiators are contained, the total amount thereof is preferably within the above-described range.

It is noted that since the photopolymerization initiator may also function as a thermal polymerization initiator, crosslinking with the photopolymerization initiator may be further allowed to proceed by heating an oven, a hot plate, or the like.

### [Sensitizing Agent]

The composition may include a sensitizer. The sensitizing agent absorbs a specific radioactive ray to be in an electronically excited state. The sensitizing agent in the electronically excited state is brought into contact with a thermal radical polymerization initiator, a photoradical polymerization initiator, or the like, to cause actions such as electron migration, energy transfer, and heat generation. As a result, the thermal radical polymerization and the photoradical polymerization initiator undergo a chemical change and decomposes to generate a radical, an acid, or a base.

In addition, as a usable sensitizing agent, a benzophenone-based, a Michler's ketone-based, a coumarin-based, a pyrazole azo-based, an anilino azo-based, a triphenylmethane-based, an anthraquinone-based, an anthracene-based, an anthrapylidene-based, a benzylidene-based, an oxonol-based, a pyrazolotriazole azo-based, a pyridone azo-based, a cyanine-based, a phenothiazine-based, a pyrrolopyrazole azomethine-based, a xanthene-based, a phthalocyanine-based, a benzopyran-based, and an indigo-based compound can be used.

Examples of the sensitizing agent include, Michler's ketone, 4,4′-bis(diethylamino)benzophenone, 2,5-bis(4′-diethylaminobenzal)cyclopentane, 2,6-bis(4′-diethylaminobenzal)cyclohexanone, 2,6-bis(4′-diethylaminobenzal)-4-methylcyclohexanone, 4,4′-bis(dimethylamino)chalcone, 4,4′-bis(diethylamino)chalcone, p-dimethylaminocinnamylidene indanone, p-dimethylamino benzylidene indanone, 2-(p-dimethylaminophenylbiphenylene)-benzothiazole, 2-(p-dimethylaminophenylvinylene)benzothiazole, 2-(p-dimethylaminophenylvinylene)isonaphtothiazole, 1,3-bis(4′-dimethylaminobenzal)acetone, 1,3-bis(4′-diethylaminobenzal)acetone, 3,3′-carbonyl-bis(7-diethylaminocoumarin), 3-acetyl-7-dimethylaminocoumarin, 3-ethoxycarbonyl-7-dimethylaminocoumarin, 3-benzyloxycarbonyl-7-dimethylaminocoumarin, 3-methoxycarbonyl-7-diethylaminocoumarin, 3-ethoxycarbonyl-7-diethylaminocoumarin (ethyl 7-(diethylamino)coumarin-3-carboxylate), N-phenyl-N′-ethylethanolamine, N-phenyldiethanolamine, N-p-tolyldiethanolamine, N-phenylethanolamine, 4-morpholinobenzophenone, isoamyl dimethylaminobenzoate, isoamyl diethylaminobenzoate, 2-mercaptobenzimidazole, 1-phenyl-5-mercaptotetrazole, 2-mercaptobenzothiazole, 2-(p-dimethylaminostyryl)benzoxazole, 2-(p-dimethylaminostyryl)benzothiazole, 2-(p-dimethylaminostyryl)naphtho (1,2-d)thiazole, 2-(p-dimethylaminobenzoyl)styrene, diphenylacetamide, benzanilide, N-methylacetanilide, and 3′,4′-dimethylacetanilide.

In addition, other sensitizing dyes may be used.

For details of the sensitizing dye, reference can be made to the description in paragraphs 0161 to 0163 of JP2016-027357A, the content of which is incorporated in the present specification.

In a case where the composition contains a sensitizing agent, the content of the sensitizing agent is preferably 0.01% to 20% by mass, more preferably 0.1% to 15% by mass, and still more preferably 0.5% to 10% by mass with respect to the total solid content of the composition. One kind of sensitizing agent may be used alone, or two or more kinds thereof may be used in combination.

### [Chain Transfer Agent]

The composition may contain a chain transfer agent. The chain transfer agent is defined, for example, in Polymer Dictionary, 3rd Edition, pp. 683 to 684 (edited by The Society of Polymer Science, 2005). As the chain transfer agent, for example, the following compound is used; a group of compounds having —S—S—, —SO₂—S—, —N—O—, SH, PH, SiH, or GeH in the molecule, or a dithiobenzoate compound, a trithiocarbonate compound, dithiocarbamate, or a xanthate compound, which has a thiocarbonylthio group that is used for the reversible addition fragmentation chain transfer (RAFT) polymerization. These can donate hydrogen to a low active radical to generate a radical or can be oxidized and then deprotonated to generate a radical. In particular, a thiol compound can be preferably used.

In addition, as the chain transfer agent, the compounds described in paragraphs 0152 and 0153 of WO2015/199219A can also be used, the content of which is incorporated in the present specification.

In a case where the composition has a chain transfer agent, the content of the chain transfer agent is preferably 0.01 to 20 parts by mass, more preferably 0.1 to 10 parts by mass, and still more preferably 0.5 to 5 parts by mass, with respect to 100 parts by mass of the total solid content of the composition. Only one kind of chain transfer agent may be used alone, or two or more kinds thereof may be used. In a case where two or more kinds of chain transfer agents are used, the total thereof is preferably within the above-described range.

In addition, an aspect in which the composition includes two or more polymerization initiators as the polymerization initiator is also one of the preferred aspects of the present invention.

Specifically, the composition preferably includes a photopolymerization initiator and a thermal polymerization initiator described later, or includes the above-described photoradical polymerization initiator and the above-described photo-acid generator.

By containing the photopolymerization initiator and the thermal polymerization initiator described later, pattern formation by exposure is possible, and radical polymerization is also likely to proceed during curing in the heating step described later, and thus the performance such as chemical resistance may be improved.

In the content ratio in a case where the photopolymerization initiator and the thermal polymerization initiator described later are contained, the content of the thermal polymerization initiator is preferably 20% to 70% by mass and more preferably 30% to 60% by mass with respect to the total content of the photopolymerization initiator and the thermal polymerization initiator.

The performance such as resolution may be improved by containing a photoradical polymerization initiator and a photoacid generator.

In the content ratio in a case where the photopolymerization initiator and the photoacid generator are contained, the content of the photoacid generator is preferably 20% to 70% by mass, and more preferably 30% to 60% by mass with respect to the total content of the photopolymerization initiator and the photoacid generator.

### [Thermal Polymerization Initiator]

Examples of the thermal polymerization initiator include a thermal radical polymerization initiator. The thermal radical polymerization initiator is a compound that generates a radical by heat energy and initiates or accelerates a polymerization reaction of a compound having polymerization properties. In a case where a thermal radical polymerization initiator is added, the polymerization reaction of the resin and the polymerizable compound can be allowed to proceed, and thus the solvent resistance can be further improved.

Specific examples of thermal radical polymerization initiator include compounds described in paragraphs 0074 to 0118 of JP2008-063554A, the content of which is incorporated in the present specification.

In a case where a thermal polymerization initiator is contained, the content thereof is preferably 0.1% to 30% by mass, more preferably 0.1% to 20% by mass, and still more preferably 0.5% to 15% by mass with respect to the total solid content of the composition. The composition may contain only one kind of thermal polymerization initiator, or may contain two or more kinds thereof. In a case where two or more kinds of thermal polymerization initiators are contained, the total amount thereof is preferably within the above-described range.

### <Base Generator>

The composition may include a base generator. Here, the base generator is a compound that is capable of generating a base under a physical or chemical action. Examples of the preferred base generator include a thermal-base generator and a photobase generator.

In particular, in a case where the composition includes a heterocyclic ring-containing polymer precursor, the composition preferably includes a base generator. In a case where the composition contains a thermal-base generator, it is possible to, for example, accelerate the cyclization reaction of the precursor by heating, whereby the mechanical properties and chemical resistance of the cured substance are improved and for example, the performance as an interlayer insulating film for a re-distribution layer, included in a semiconductor package, is improved.

The base generator may be an ionic base generator or may be a nonionic base generator. Examples of the base that is generated from the base generator include a secondary amine and a tertiary amine.

The base generator is not particularly limited, and a publicly known base generator can be used. Examples of the publicly known base generator include a carbamoyloxime compound, a carbamoylhydroxylamine compound, a carbamic acid compound, a formamide compound, an acetamide compound, a carbamate compound, a benzylcarbamate compound, a nitrobenzylcarbamate compound, a sulfonamide compound, an imidazole derivative compound, an aminimide compound, a pyridine derivative compound, an α-aminoacetophenone derivative compound, a quaternary ammonium salt derivative compound, an iminium salt, a pyridinium salt, an a-lactone ring derivative compound, a phthalimide derivative compound, and an acyloxyimino compound.

Specific examples of the nonionic base generator include the compounds described in paragraphs 0249 to 0275 of WO2022/145355A. The above description is incorporated in the present specification.

Examples of the base generator include the following compounds; however, the base generator is not limited thereto.

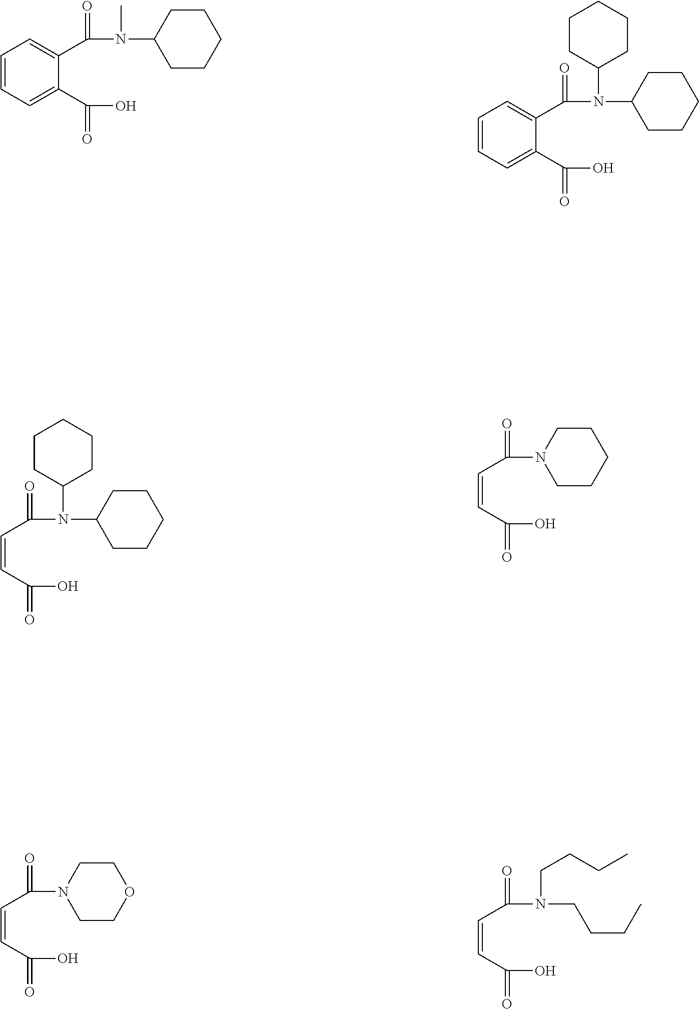 [SMILES: CN(C(=O)c1ccccc1C(=O)O)C1CCCCC1 ; O=C(O)c1ccccc1C(=O)N(C1CCCCC1)C1CCCCC1 ; O=C(O)/C=C\C(=O)N(C1CCCCC1)C1CCCCC1 ; O=C(O)/C=C\C(=O)N1CCCCC1 ; O=C(O)/C=C\C(=O)N1CCOCC1 ; CCCCN(CCCC)C(=O)/C=C\C(=O)O]

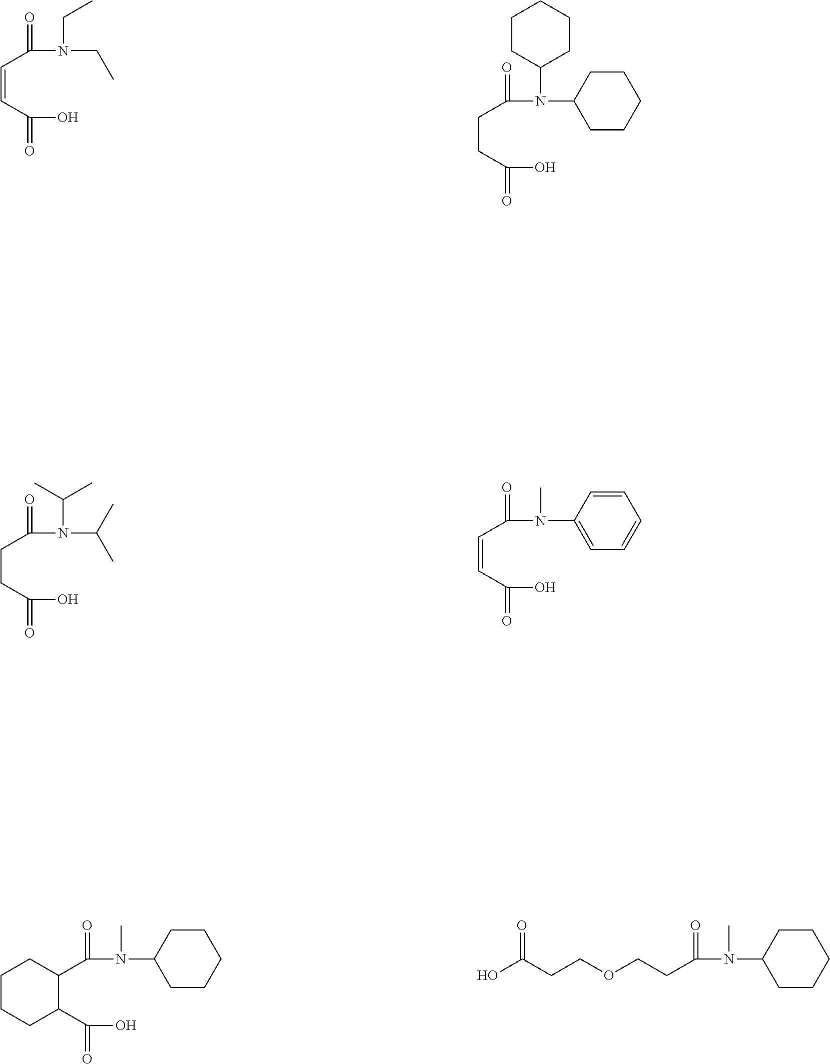 [SMILES: CCN(CC)C(=O)/C=C\C(=O)O ; O=C(O)CCC(=O)N(C1CCCCC1)C1CCCCC1 ; CC(C)N(C(=O)CCC(=O)O)C(C)C ; CN(C(=O)/C=C\C(=O)O)c1ccccc1 ; CN(C(=O)C1CCCCC1C(=O)O)C1CCCCC1 ; CN(C(=O)CCOCCC(=O)O)C1CCCCC1]

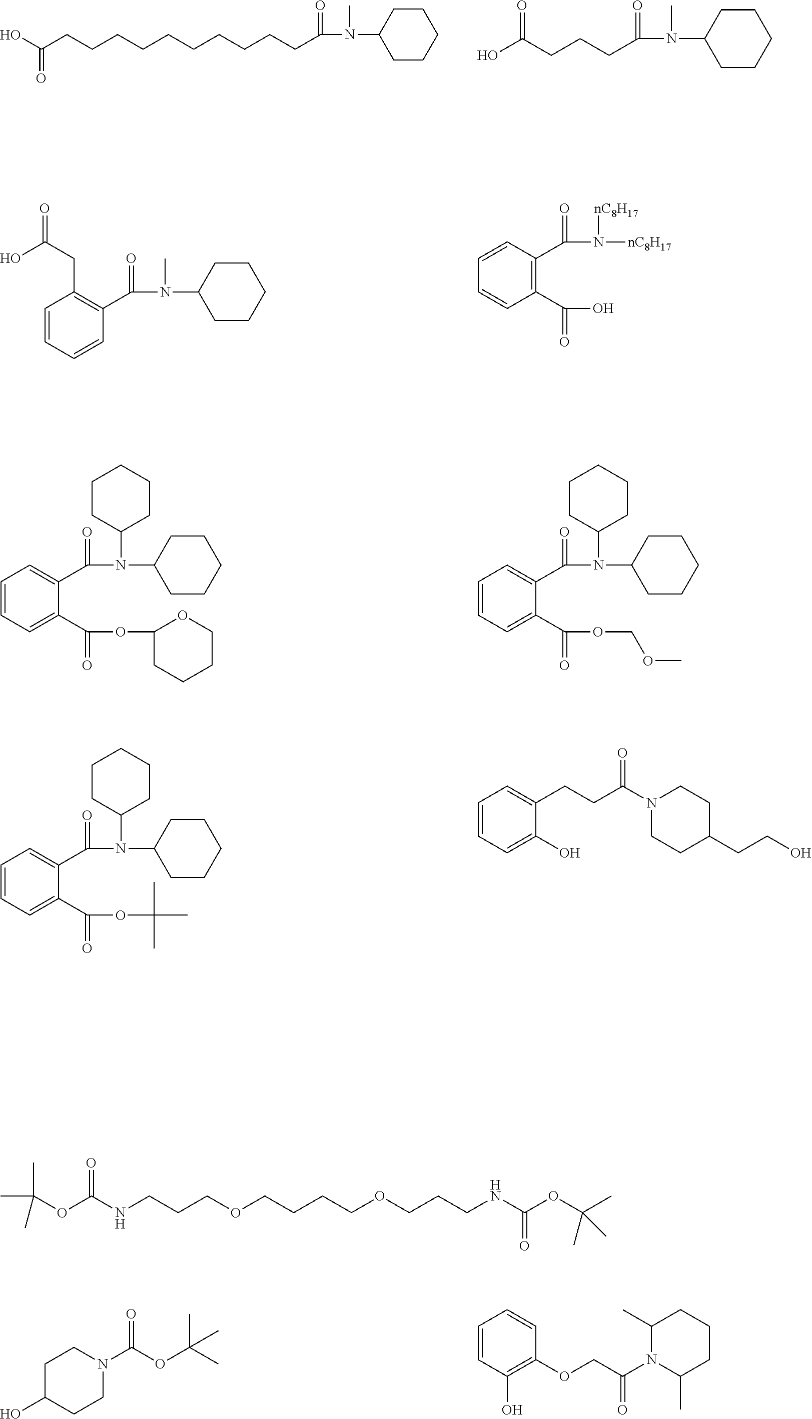

The molecular weight of the nonionic base generator is preferably 800 or less, more preferably 600 or less, and still more preferably 500 or less. The lower limit thereof is preferably 100 or more. more preferably 200 or more. and still more preferably 300 or more.

Examples of the specific preferred compound of the ionic base generator include the compounds described in paragraphs 0148 to 0163 of WO2018/038002A.

Specific examples of the ammonium salt include the following compounds; however, the ammonium salt is not limited thereto.

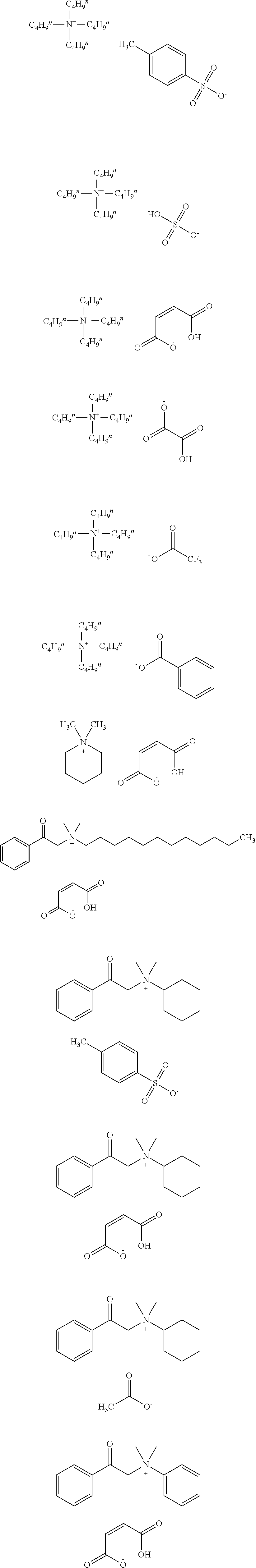

Specific examples of the iminium salt include the following compounds; however, the iminium salt is not limited thereto.

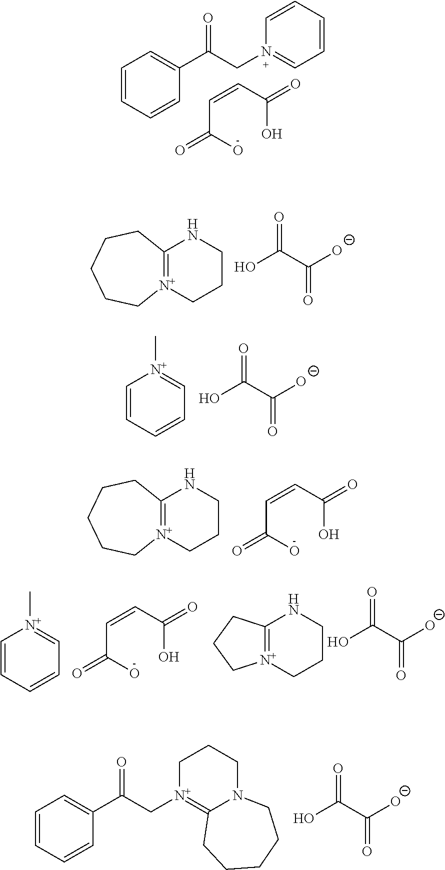

In addition, from the viewpoint of storage stability and generation of a base by deprotection during curing, the base generator is preferably an amine in which an amino group is protected by a t-butoxycarbonyl group.

Examples of the amine compound protected by a t-butoxycarbonyl group include ethanolamine, 3-amino-1-propanol, 1-amino-2-propanol, 2-amino-1-propanol, 4-amino-1-butanol, 2-amino-1-butanol, 1-amino-2-butanol, 3-amino-2,2-dimethyl-1-propanol, 4-amino-2-methyl-1-butanol, valinol, 3-amino-1,2-propanediol, 2-amino-1,3-propanediol, tyramine, norephedrine, 2-amino-1-phenyl-1,3-propanediol, 2-aminocyclohexanol, 4-aminocyclohexanol, 4-aminocyclohexanethanol, 4-(2-aminoethyl)cyclohexanol, N-methylethanolamine, 3-(methylamino)-1-propanol, 3-(isopropylamino)propanol, N-cyclohexylethanolamine, a-[2-(methylamino)ethyl]benzyl alcohol, diethanolamine, diisopropanolamine, 3-pyrrolidinol, 2-pyrrolidinomethanol, 4-hydroxypiperidine, 3-hydroxypiperidine, 4-hydroxy-4-phenylpiperidine, 4-(3-hydroxyphenyl)piperidine, 4-piperidinemethanol, 3-piperidinemethanol, 2-piperidinemethanol, 4-piperidinetanol, 2-piperidinetanol, 2-(4-piperidyl)-2-propanol, 1,4-butanol bis(3-aminopropyl)ether, 1,2-bis(2-aminoethoxy)ethane, 2,2′-oxybis(ethylamine), 1,14-diamino-3,6,9,12-tetraoxatetradecane, 1-aza-15-crown 5-ether, diethylene glycol bis(3-aminopropyl)ether, 1,11-diamino-3,6,9-trioxaundecane, or a compound in which an amino group of an amino acid and a derivative thereof is protected by a t-butoxycarbonyl group, but the present invention is not limited to these examples.

In a case where the composition includes a base generator, a content of the base generator is preferably 0.1 to 50 parts by mass with respect to 100 parts by mass of the resin in the composition. The lower limit thereof is more preferably 0.3 parts by mass or more and still more preferably 0.5 parts by mass or more. The upper limit thereof is more preferably 30 parts by mass or less, still more preferably 20 parts by mass or less, even still more preferably 10 parts by mass or less, even further still more preferably 5 parts by mass or less, and particularly preferably 4 parts by mass or less.

One kind or two or more kinds of base generators can be used. In a case where two or more kinds thereof are used, the total amount is preferably within the above-described range.

### <Solvent>

The composition preferably includes a solvent.

As the solvent, any publicly known solvent can be used. The solvent is preferably an organic solvent. Examples of the organic solvent include compounds such as esters, ethers, ketones, cyclic hydrocarbons, sulfoxides, amides, ureas, and alcohols.

Suitable examples of the esters include ethyl acetate, n-butyl acetate, isobutyl acetate, hexyl acetate, amyl formate, isoamyl acetate, butyl propionate, isopropyl butyrate, ethyl butyrate, butyl butyrate, methyl lactate, ethyl lactate, γ-butyrolactone, ε-caprolactone, δ-valerolactone, γ-valerolactone, alkyl alkyloxyacetate (for example, methyl alkyloxyacetate, ethyl alkyloxyacetate, and butyl alkyloxyacetate (for example, methyl methoxyacetate, ethyl methoxyacetate, butyl methoxyacetate, methyl ethoxyacetate, and ethyl ethoxyacetate)), 3-alkyloxypropionic acid alkyl esters (for example, methyl 3-alkyloxypropionate, and ethyl 3-alkyloxypropionate (for example, methyl 3-methoxypropionate, ethyl 3-methoxypropionate, methyl 3-ethoxypropionate, and ethyl 3-ethoxypropionate)), 2-alkyloxypropionic acid alkyl esters (for example, methyl 2-alkyloxypropionate, ethyl 2-alkyloxypropionate, and propyl 2-alkyloxypropionate (for example, methyl 2-methoxypropionate, ethyl 2-methoxypropionate, propyl 2-methoxypropionate, methyl 2-ethoxypropionate, and ethyl 2-ethoxypropionate)), methyl 2-alkyloxy-2-methylpropionate and ethyl 2-alkyloxy-2-methylpropionate (for example, methyl 2-methoxy-2-methylpropionate and ethyl 2-ethoxy-2-methylpropionate), methyl pyruvate, ethyl pyruvate, propyl pyruvate, methyl acetoacetate, ethyl acetoacetate, methyl 2-oxobutanoate, ethyl 2-oxobutanoate, ethyl hexanoate, ethyl heptanoate, dimethyl malonate, and diethyl malonate.

Suitable examples of ethers include ethylene glycol dimethyl ether, diethylene glycol dimethyl ether, diethylene glycol diethyl ether, diethylene glycol ethyl methyl ether, diethylene glycol butyl methyl ether, triethylene glycol dimethyl ether, tetraethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether, propylene glycol dimethyl ether, propylene glycol monomethyl ether acetate, propylene glycol monoethyl ether acetate, ethylene glycol monobutyl ether, ethylene glycol monobutyl ether acetate, propylene glycol monopropyl ether acetate, and dipropylene glycol dimethyl ether.

Suitable examples of the ketones include methyl ethyl ketone, cyclohexanone, cyclopentanone, 2-heptanone, 3-heptanone, 3-methylcyclohexanone, levoglucosenone, and dihydrolevoglucosenone.

Suitable examples of the cyclic hydrocarbon include aromatic hydrocarbons such as toluene, xylene, and anisole, and cyclic terpenes such as limonene.

Suitable examples of the sulfoxides include dimethyl sulfoxide.

Suitable examples of the amide include N-methyl-2-pyrrolidone, N-ethyl-2-pyrrolidone, N-cyclohexyl-2-pyrrolidone, N,N-dimethylacetamide, N,N-dimethylformamide, N,N-dimethylisobutylamide, 3-methoxy-N,N-dimethylpropionamide, 3-butoxy-N,N-dimethylpropionamide, N-formylmorpholine, and N-acetylmorpholine.

Suitable examples of the urea include N,N,N′,N′-tetramethylurea and 1,3-dimethyl-2-imidazolidinone.

Examples of the alcohols include methanol, ethanol, 1-propanol, 2-propanol, 1-butanol, 1-pentanol, 1-hexanol, benzyl alcohol, ethylene glycol monomethyl ether, 1-methoxy-2-propanol, 2-ethoxyethanol, diethylene glycol monoethyl ether, diethylene glycol monohexyl ether, triethylene glycol monomethyl ether, propylene glycol monoethyl ether, propylene glycol monomethyl ether, polyethylene glycol monomethyl ether, polypropylene glycol, tetraethylene glycol, ethylene glycol monobutyl ether, ethylene glycol monobenzyl ether, ethylene glycol monophenyl ether, methylphenyl carbinol, n-amyl alcohol, methylamyl alcohol, and diacetone alcohol.

From the viewpoint of improving the properties of a coated surface or the like, it is also preferable to mix two or more kinds of solvents.

In the present invention, one solvent selected from methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclopentanone, γ-butyrolactone, y-valerolactone, 3-methoxy-N,N-dimethylpropionamide, toluene, dimethyl sulfoxide, ethyl carbitol acetate, butyl carbitol acetate, N-methyl-2-pyrrolidone, propylene glycol methyl ether, and propylene glycol methyl ether acetate, or a mixed solvent composed of two or more thereof is preferable, and it is more preferable that the solvent includes at least one solvent selected from γ-butyrolactone, dimethyl sulfoxide, and N-methyl-2-pyrrolidone. A combined use of dimethyl sulfoxide and γ-butyrolactone, a combined use of dimethyl sulfoxide and γ-valerolactone, a combined use of 3-methoxy-N,N-dimethylpropionamide and γ-butyrolactone, a combined use of 3-methoxy-N,N-dimethylpropionamide and dimethyl sulfoxide, or, a combined use of N-methyl-2-pyrrolidone and ethyl lactate is particularly preferable. An aspect in which an amount of about 1% to 10% by mass of toluene with respect to the total mass of the solvent is further added to these combinedly used solvents is also one of the preferred aspects of the present invention.

In particular, from the viewpoint of the storage stability or the like of the composition, an aspect in which y-valerolactone is included as the solvent is also one of the preferred aspects of the present invention. In such an aspect, the content of y-valerolactone with respect to the total mass of the solvent is preferably 50% by mass or more, more preferably 60% by mass or more, and still more preferably 70% by mass or more. In addition, the upper limit of the above-described content is not particularly limited, and it may be 100% by mass. The above-described content may be determined in consideration of the solubility of components such as the heterocyclic ring-containing polymer contained in the composition.

In addition, in a case where dimethyl sulfoxide and y-valerolactone are used in combination, with respect to the total mass of the solvent, it is preferable to contain 60% to 90% by mass of γ-valerolactone and 10% to 40% by mass of dimethyl sulfoxide, it is more preferable to contain 70% to 90% by mass of γ-valerolactone and 10% to 30% by mass of dimethyl sulfoxide, and it is still more preferable to contain 75% to 85% by mass of γ-valerolactone and 15% to 25% by mass of dimethyl sulfoxide.

Regarding the content of the solvent, the amount of the solvent is such that, from the viewpoint of coatability, the concentration of the total solid contents of the composition is preferably 5% to 80% by mass, more preferably 5% to 75% by mass, still more preferably 10% to 70% by mass, and even still more preferably 20% to 70% by mass. The content of the solvent may be adjusted depending on the desired thickness of the coating film and the coating method. In a case where two or more kinds of solvents are contained, the total thereof is preferably within the above-described range.

### <Metal Adhesiveness Improving Agent>

From the viewpoint of improving adhesiveness to a metal material used for an electrode, wiring, or the like, the composition preferably includes a metal adhesiveness improver. Examples of the metal adhesiveness improving agent include a silane coupling agent having an alkoxysilyl group, an aluminum-based auxiliary adhesive agent, a titanium-based auxiliary adhesive agent, a compound having a sulfonamide structure and a compound having a thiourea structure, a phosphoric acid derivative compound, a p-ketoester compound, and an amino compound.

### [Silane Coupling Agent]

Examples of the silane coupling agent include the compounds described in paragraph 0316 of WO2021/112189A and the compounds described in paragraphs 0067 to 0078 of JP2018-173573A, the contents of which are incorporated in the present specification. In addition, it is also preferable to use two or more kinds of different silane coupling agents as described in paragraphs 0050 to 0058 of JP2011-128358A. It is also preferable to use the following compound as the silane coupling agent. In the following Formulae, Me represents a methyl group, and Et represents an ethyl group. In addition, examples of R shown below include a structure derived from a blocking agent in a blocked isocyanate group. The blocking agent may be selected depending on the desorption temperature; however, examples thereof include an alcohol compound, a phenol compound, a pyrazole compound, a triazole compound, a lactam compound, and an active methylene compound. It is preferably caprolactam or the like, for example, from the viewpoint of setting the desorption temperature to 160° C. to 180° C. Examples of the commercially available product of such a compound include X-12-1293 (manufactured by Shin-Etsu Chemical Co., Ltd.).

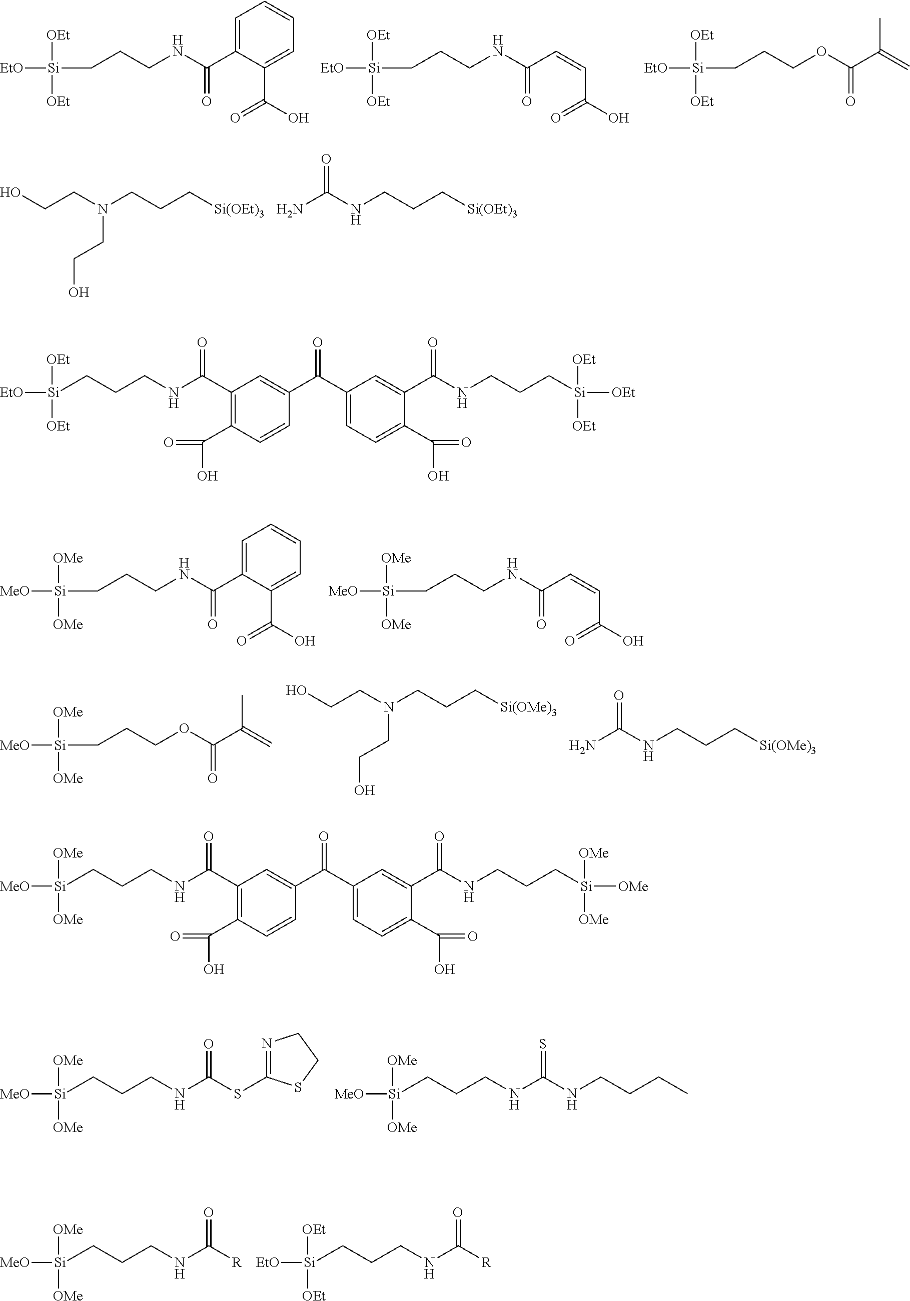

Examples of the other silane coupling agent include vinyltrimethoxysilane, vinyltriethoxysilane, 2-(3,4-epoxycyclohexyl)ethyltrimethoxysilane, 3-glycidoxypropylmethyldimethoxysilane, 3-glycidoxypropyltrimethoxysilane, 3-glycidoxypropylmethyldiethoxysilane, 3-glycidoxypropyltriethoxysilane, p-styryltrimethoxysilane, 3-methacryloxypropylmethyldimethoxysilane, 3-methacryloxypropyltrimethoxysilane, 3-methacryloxypropylmethyldiethoxysilane, 3-methacryloxypropyltriethoxysilane, 3-acryloxypropyltrimethoxysilane, N-2-(aminoethyl)-3-aminopropylmethyldimethoxysilane, N-2-(aminoethyl)-3-aminopropyltrimethoxysilane, 3-aminopropyltrimethoxysilane, 3-aminopropyltriethoxysilane, 3-triethoxysilyl-N-(1,3-dimethyl-butylidene)propylamine, N-phenyl-3-aminopropyltrimethoxysilane, tris-(trimethoxysilylpropyl)isocyanurate, 3-ureidopropyltrialkoxysilane, 3-mercaptopropylmethyldimethoxysilane, 3-mercaptopropyltrimethoxysilane, 3-isocyanatepropyltriethoxysilane, and 3-trimethoxysilylpropylsuccinic acid anhydride. These can be used alone or in a combination of two or more thereof.

In addition, an oligomer type compound having a plurality of alkoxysilyl groups can also be used as the silane coupling agent.

Examples of such an oligomer type compound include a compound containing a repeating unit represented by Formula (S-1).

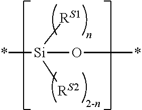

In Formula (S-1), R^{S1} represents a monovalent organic group, R^{S2} represents a hydrogen atom, a hydroxy group, or an alkoxy group, and n represents an integer of 0 to 2.

R^{S1} preferably has a structure including a polymerizable group. Examples of the polymerizable group include a group having an ethylenically unsaturated bond, an epoxy group, an oxetanyl group, a benzoxazolyl group, a blocked isocyanate group, and an amino group. Examples of the group having an ethylenically unsaturated bond include a vinyl group, an allyl group, an isoallyl group, a 2-methylallyl group, a group (for example, a vinylphenyl group) having an aromatic ring that is directly bonded to a vinyl group, and a (meth)acrylamide group, a (meth)acryloyloxy group, where a vinylphenyl group, a (meth)acrylamide group, or a (meth)acryloyloxy group is preferable, a vinylphenyl group or a (meth)acryloyloxy group is more preferable, and a (meth)acryloyloxy group is still more preferable.

R^{S2} is preferably an alkoxy group, and more preferably a methoxy group or an ethoxy group.

n represents an integer of 0 to 2, and it is preferably 1.

Here, structures of a plurality of repeating units represented by Formula (S-1) may be the same, where the plurality of repeating units are contained in the oligomer type compound.

Here, among a plurality of repeating units represented by Formula (S-1), which are contained in the oligomer type compound, it is preferable that at least one repeating unit has n of 1 or 2, it is more preferable that at least two repeating units have n of 1 or 2, and it is still more preferable that at least two repeating units have n of 1.

As such an oligomer type compound, a commercially available product can be used, and examples thereof include KR-513 (manufactured by Shin-Etsu Chemical Co., Ltd.).

### [Aluminum-Based Auxiliary Adhesive Agent]

Examples of the aluminum-based auxiliary adhesive agent include aluminum tris(ethyl acetoacetate), aluminum tris(acetyl acetate), and ethyl acetoacetate aluminum diisopropylate.

As another metal adhesiveness improving agent, the compounds described in paragraphs 0046 to 0049 of JP2014-186186A, and the sulfide-based compounds described in paragraphs 0032 to 0043 of JP2013-072935A can also be used, and the contents of which are incorporated in the present specification.

A content of the metal adhesiveness improver is preferably 0.01 to 30 parts by mass, more preferably 0.1 to 10 parts by mass, and still more preferably 0.5 to 5 parts by mass with respect to 100 parts by mass of the heterocyclic ring-containing polymer. In a case where the content is set to be equal to or higher than the above lower limit value, good adhesiveness between a pattern and a metal layer is exhibited, and in a case where the content is set to be equal to or lower than the above upper limit value, good heat resistance of the pattern and good mechanical characteristics are exhibited. Only one kind of metal adhesiveness improving agent may be used, or two or more kinds thereof may be used. In a case where two or more kinds thereof are used, the total content thereof is preferably within the above-described range.

### <Migration Suppressing Agent>

The composition preferably further includes a migration suppressing agent. For example, in a case where the composition is applied to a metal layer (or metal wiring) to form a film, it is possible to effectively suppress the migration of metal ions derived from the metal layer (or the metal wiring) into the film, in a case where a migration suppressing agent is contained.

The migration suppressing agent is not particularly limited; however, examples thereof include a compound having a heterocyclic ring (a pyrrole ring, a furan ring, a thiophene ring, an imidazole ring, an oxazole ring, a thiazole ring, a pyrazole ring, an isoxazole ring, an isothiazole ring, a tetrazole ring, a pyridine ring, a pyridazine ring, a pyrimidine ring, a pyrazine ring, a piperidine ring, a piperazine ring, a morpholine ring, a 2H-pyran ring and a 6H-pyran ring, or a triazine ring), a compound having thioureas and a sulfanyl group, a hindered phenol-based compound, a salicylic acid derivative-based compound, and a hydrazide derivative-based compound. In particular, it is possible to preferably use a triazole-based compound such as 1,2,4-triazole, benzotriazole, 3-amino-1,2,4-triazole, or 3,5-diamino-1,2,4-triazole, or a tetrazole-based compound such as 1H-tetrazole, 5-phenyltetrazole or 5-amino-1H-tetrazole.

As the migration suppressing agent, an ion trap agent that captures an anion such as a halogen ion can also be used.

The rust inhibitors described in paragraph 0094 of JP2013-015701A, the compounds described in paragraphs 0073 to 0076 of JP2009-283711A, the compounds described in paragraph 0052 of JP2011-059656A, the compounds described in paragraphs 0114, 0116, and 0118 of JP2012-194520A, the compounds described in paragraph 0166 of WO2015/199219A, or the like can be used as the other migration suppressing agents, the contents of which are incorporated in the present specification.

Specific examples of the migration suppressing agent include the following compounds.

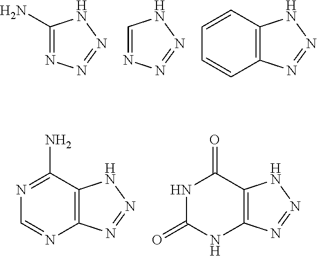

In a case where the composition contains the migration suppressing agent, the content of the migration suppressing agent is preferably 0.01% to 5.0% by mass, more preferably 0.05% to 2.0% by mass, and still more preferably 0.1% to 1.0% by mass, with respect to the total solid content of the composition.

Only one kind of migration suppressing agent may be used alone, or two or more kinds thereof may be used. In a case where two or more kinds of migration suppressing agents are used, the total thereof is preferably within the above-described range.

### <Polymerization Inhibitor>

The composition preferably includes a polymerization inhibitor. Examples of the polymerization inhibitor include a phenol-based compound, a quinone-based compound, an amino-based compound, an N-oxyl-free radical-based compound, a nitro-based compound, a nitroso-based compound, a heteroaromatic ring-based compound, and a metal compound.

Specific examples of the compound of the polymerization inhibitor include the compounds described in paragraph 0310 of WO2021/112189A, p-hydroquinone, o-hydroquinone, a 4-hydroxy-2,2,6,6-tetramethylpiperidine-1-oxyl free radical, phenoxazine, and 1,4,4-trimethyl-2,3-diazabicyclo[3.2.2]nona-2-en-N,N-dioxide. The content thereof is incorporated in the present specification.

In a case where the composition has a polymerization inhibitor, a content of the polymerization inhibitor is preferably 0.01 to 20% by mass, more preferably 0.02 to 15% by mass, and still more preferably 0.05 to 10% by mass with respect to the total solid content of the composition.

Only one kind of polymerization inhibitor may be used, or two or more kinds thereof may be used. In a case where two or more kinds of polymerization inhibitors are used, the total thereof is preferably within the above-described range.

### [Urea Compound, Carbodiimide Compound, and Isourea Compound]

From the viewpoint of breaking elongation and adhesiveness with a metal or a resin layer, the composition may contain at least one compound (hereinafter, also referred to as “urea compound and the like”) selected from the group consisting of a compound having a urea bond (urea compound), a compound having a carbodiimide structure (carbodiimide compound), and a compound having an isourea bond (isourea compound).

Among these, the composition preferably further includes a compound having a urea bond.

The urea compound or the like described here does not include the above-described polymerizable compound and the compound corresponding to the silane coupling agent.

Examples of the urea compound include compounds described in paragraphs 0334 to 0339 of WO2022/070730A.

Specific examples of the urea compound or the like include dicyclohexylurea, diisopropylurea, dicyclohexylcarbodiimide, diisopropylcarbodiimide, dicyclohexylisourea, and diisopropylisourea, which are not limited thereto.

A total content of the urea compound or the like is preferably 0.1 to 10.0 parts by mass, more preferably 0.5 to 8.0 parts by mass, and still more preferably 1.0 to 6.0 parts by mass with respect to 100 parts by mass of the heterocyclic ring-containing polymer.

One kind of urea compound or the like may be used alone, or two or more kinds thereof may be used in combination. In a case where two or more kinds of bases are used in combination in the base-containing treatment liquid, it is preferable that the total content thereof is within the above-described range.

### <Light Absorbing Agent>

The composition preferably includes a compound (light absorbing agent) in which the absorbance at the exposure wavelength is reduced by exposure.

Examples of the light absorbing agent include compounds described in paragraphs 0159 to 0183 of WO2022/202647A and compounds described in paragraphs 0088 to 0108 of JP2019-206689A. The content thereof is incorporated in the present specification.

In addition, an aspect in which a photochromic compound is included as the light absorbing agent is also one of the preferred aspects of the present invention. The photochromic compound refers to a compound in which the absorption spectrum is changed by a change in the geometric structure of the molecule by absorbing light.

Specific examples of the photochromic compound are shown below, but the present invention is not limited thereto.

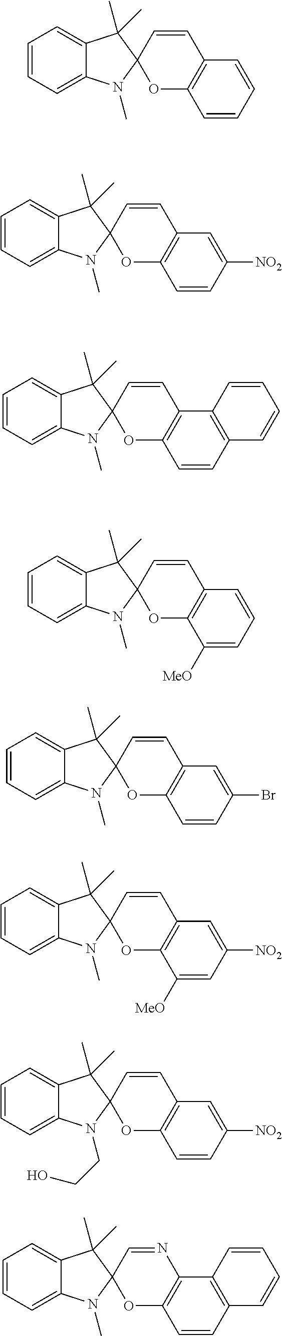

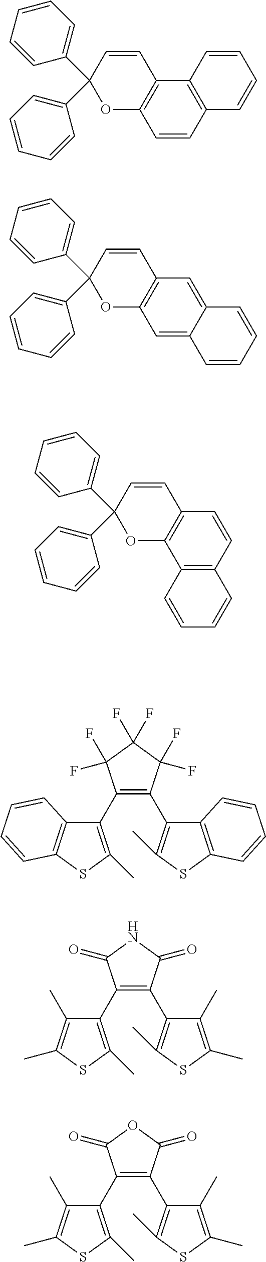

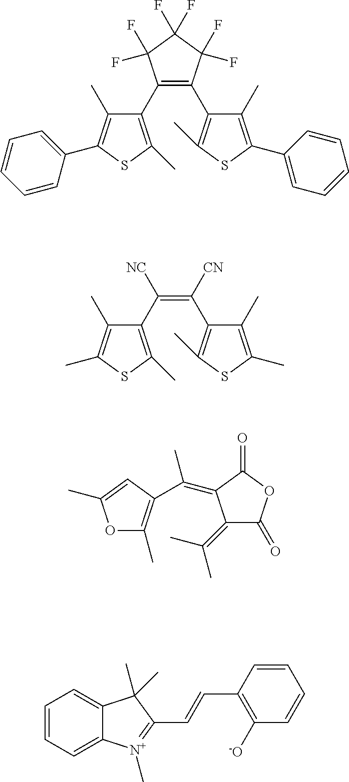

The content of the light absorbing agent with respect to the total solid content of the composition is not particularly limited, but is preferably 0.1% to 20% by mass, more preferably 0.5% to 10% by mass, and still more preferably 1% to 5% by mass.

### <Other Additives>

The composition may contain various additives as necessary, for example, a surfactant, a higher fatty acid derivative, a thermal polymerization initiator, inorganic particles, an ultraviolet absorbing agent, an organic titanium compounds, an antioxidant, a photoacid generator, an aggregation inhibitor, a phenol-based compound, another polymer compound, a plasticizer, and other auxiliary agents (for example, an anti-foaming agent, and a flame retardant) within the scope in which the effect of the present invention is obtained. By appropriately containing these components, properties such as film properties can be adjusted. The details of the components can be found in, for example, paragraph “0183” and subsequent paragraphs of JP2012-003225A (corresponding to paragraph 0237 of US2013/0034812A) and paragraphs 0101 to 0104 and 0107 to 0109 of JP2008-250074A, the contents of which are incorporated in the present specification. In a case of blending these additives, the total content thereof is preferably 3% by mass or less of the solid content of the composition.

### <Properties of Composition>

The viscosity of the composition can be adjusted by the concentration of the solid content of the composition. From the viewpoint of the coating film thickness, it is preferably 1,000 mm²/s to 12,000 mm²/s, more preferably 2,000 mm²/s to 10,000 mm²/s, and still more preferably 2,500 mm²/s to 8,000 mm²/s. Within the above range, it is easy to obtain a coating film having high uniformity. In a case of being 1,000 mm²/s or more, it is easy to carry out coating at a film thickness to be required as, for example, an insulating film for re-distribution of wiring, and in a case of being 12,000 mm²/s or less, a coating film having an excellent coating surface shape is obtained.

A Young's modulus of the coating film obtained by applying the composition and heated at 230° C. for 2 hours is preferably 3.8 GPa or more.

The above-described Young's modulus is preferably 3.9 GPa or more and more preferably 4.0 GPa or more. The upper limit of the Young's modulus is not particularly limited; however, it is, for example, preferably 10.0 GPa or less.

Here, the method of applying the resin composition in the measurement of the above-described Young's modulus is not particularly limited, and a method in which the distance from the substrate to the film surface (that is, the coating film thickness) is, for example, 20 μm may be used, but a spin coating method can be used. In addition, in a case where it is difficult to form a film having the above-described distance of 20 μm by the spin coating method once, the spin coating method may be performed a plurality of times. In addition, even in this case, in a case where it is difficult to form a film having a distance of 20 m by a spin coating method, a coating method may be appropriately selected from known methods such as a dip coating method, an air knife coating method, a curtain coating method, a wire bar coating method, a gravure coating method, an extrusion coating method, a spray coating method, a slit coating method, and an ink jet method.

In a case where the composition includes a solvent, it is preferable to perform drying after the above-described application. In that case, the distance from the base material to the film surface after drying is 20 μm.

It is preferable that the drying is carried out until the amount of the solvent in the film is 0.5% by mass or less.

The drying conditions are not particularly limited, but can be carried out by drying with heating. In addition, in a case where it is difficult to sufficiently dry the composition only by heating, the pressure may be further reduced.

The drying can be carried out in the atmosphere. However, in a case where the resin composition contains a component or the like that is likely to be modified by oxygen, the treatment can also be carried out under an inert gas replacement such as nitrogen, under vacuum, or the like.

The drying means is not particularly limited, and examples thereof include a hot plate. However, in a case where the above-described pressure reduction, inert gas replacement, and the like are required, an oven with a pressure reduction function, an oven with a gas replacement function, or the like can also be used.

In a case of carrying out drying by heating, the heating temperature (drying temperature) can be set to, for example, 100° C. However, in a case where it is difficult to dry at 100° C., the drying temperature may be appropriately changed to 70° C. to 130° C., preferably 90° C. to 120° C., depending on the kind or the like of the solvent contained in the resin composition.

In a case where the drying is performed by heating, the drying time (the time during which the heating is performed at the above-described heating temperature) can be, for example, 5 minutes. However, in a case where it is difficult to carry out drying for 5 minutes, the drying time may be appropriately changed to 30 seconds to 20 minutes, and preferably 1 minute to 10 minutes, depending on the kind or the like of the solvent contained in the resin composition.

In a case where the drying is performed by heating, the temperature rising rate during heating is not particularly limited, and for example, it can be set to 5° C./min. In a case where the drying at the above-described temperature rising rate is difficult, the temperature rising rate may be appropriately changed to 1 to 12° C./min or 2 to 10° C./min depending on the kind or the like of the solvent contained in the resin composition.

The entire surface of the coating film obtained by the above-described application and drying as necessary was exposed to i-rays with an exposure energy of 500 mJ/cm² using a stepper (Nikon NSR 2005 i9C).

The composition layer (resin layer) after the exposure is cured by heating at 230° C. for 2 hours to form a cured substance.

The film of the resin composition obtained by the application is subjected to heating while being exposed as little as possible. In addition, contact with a solvent such as a developer can also be avoided as much as possible.

The heating can be carried out in an oven under a nitrogen atmosphere.

The pressure in the heating is set to 1 atm (101,325 Pa).

The temperature rising rate in the heating can be, for example, 10° C./min. In a case where the drying at the above-described temperature rising rate is difficult, the temperature rising rate may be appropriately changed to 1 to 12° C./min or 2 to 10° C./min depending on the kind or the like of the solvent contained in the resin composition.

The heating time (time exposed to 230° C.) in the above-described heating is set to 2 hours.

The Young's modulus of the cured substance is measured after cooling the cured substance to 25° C.

The Young's modulus is measured according to the method described in JIS K 7161-1: 2014.

### <Restriction on Components of Composition>

The moisture content of the resin composition according to the embodiment of the present invention is preferably less than 2.0% by mass, more preferably less than 1.5% by mass, and still more preferably less than 1.0% by mass. In a case of being less than 2.0%, the storage stability of the composition is improved.

Examples of the method of maintaining the moisture content include adjusting the humidity under storage conditions and reducing the void ratio of the storage container during storage.

From the viewpoint of insulating properties, the metal content of the composition is preferably less than 5 parts per million (ppm) by mass, more preferably less than 1 ppm by mass, and still more preferably less than 0.5 ppm by mass. Examples of the metal include sodium, potassium, magnesium, calcium, iron, copper chromium, and nickel, however, a metal contained as a complex of an organic compound and a metal is excluded. In a case where a plurality of metals are contained, the total of these metals is preferably within the above-described range.

In addition, examples of a method of reducing metal impurities unintentionally contained in the composition include a method of selecting a raw material having a low metal content as a raw material constituting the composition, a method of filtering the raw material constituting the composition, and a method of distilling the composition in a condition in which contamination is suppressed as much as possible by lining the inside of the apparatus with polytetrafluoroethylene or the like.

In the composition, in a case of considering the use application as a semiconductor material, the content of halogen atoms is preferably less than 500 ppm by mass, more preferably less than 300 ppm by mass, and still more preferably less than 200 ppm by mass, from the viewpoint of wire corrosiveness. Among these, in a case of being present in a halogen ion state, the content is preferably less than 5 ppm by mass, more preferably less than 1 ppm by mass, and still more preferably less than 0.5 ppm by mass. Examples of the halogen atom include a chlorine atom and a bromine atom. It is preferable that the total content of the chlorine atom and the bromine atom, or the total content of the chlorine ion and the bromine ion is within the above-described range.

Preferred examples of the method of adjusting the content of halogen atoms include ion exchange treatment.

As a storage container of the composition, a storage container known in the related art can be used. As the storage container, for the purpose of suppressing impurities from being mixed into a raw material or a composition, a multilayer bottle having a container inner wall made of six layers of six kinds of resins or a bottle having a seven-layer structure of six kinds of resins is also preferably used. Examples of such a container include the container described in JP2015-123351A.

### <Preparation of Composition>

The composition can be prepared by mixing the above-described components. The mixing method is not particularly limited, and mixing can be carried out by methods publicly known in the related art.

Examples of the mixing method include mixing with a stirring blade, mixing with a ball mill, and mixing by rotating a tank.

The temperature during the mixing is preferably 10° C. to 30° C., and more preferably 15° C. to 25° C.

It is preferable to perform filtration using a filter in order to remove foreign substances such as dust and fine particles in the composition. The filter pore diameter is, for example, preferably 5 μm or less, more preferably 1 μm or less, still more preferably 0.5 μm or less, and even still more preferably 0.1 μm or less. The material of the filter is preferably polytetrafluoroethylene, polyethylene, or nylon. In a case where the material of the filter is polyethylene, it is more preferable to use high density polyethylene (HDPE). As the filter, a filter which has been washed with an organic solvent in advance may be used. In the filtration step using the filter, a plurality of kinds of filters may be connected in series or in parallel and used. In a case where a plurality of kinds of filters are used, filters having different pore diameters or different materials may be used in combination. Examples of the connection aspect include an aspect in which an HDPE filter having a pore diameter of 1 μm is connected in series as the first stage and an HDPE filter having a pore diameter of 0.2 μm is connected in series as the second stage. In addition, various materials may be filtered a plurality of times. In a case of being filtered a plurality of times, circulation filtration may be used. In addition, filtration may be carried out under pressure. In a case of carrying out pressurization to carry out filtration, the pressure for pressurization is, for example, preferably 0.01 MPa or more and 1.0 MPa or less, more preferably 0.03 MPa or more and 0.9 MPa or less, still more preferably 0.05 MPa or more and 0.7 MPa or less, and even still more preferably 0.05 MPa or more and 0.5 MPa or less.

In addition to filtration using a filter, impurity removal treatment using an adsorbing material may be carried out. The filtration using a filter and the impurity removal treatment using an adsorbing material may be combined. As the adsorbing material, a publicly known adsorbing material can be used. Examples thereof include an inorganic adsorbing material such as silica gel and zeolite and an organic adsorbing material such as activated carbon.

After filtration using a filter, a step of placing a bottle filled with the composition under reduced pressure to carry out degassing may be provided.

### EXAMPLES

Hereinafter, the present invention will be described in detail using examples. Materials, using amounts, proportions, treatment details, treatment content, and the like shown in the following examples can be appropriately changed without departing from the gist of the present invention. Accordingly, the scope of the present invention is not limited to the following specific examples. Unless otherwise specified, “parts” and “%” are based on mass.

### Synthesis of Resin

### Synthesis Example: Synthesis of Polymer 1

20.80 g (40 mmol) of 4,4′-(4,4′-isopropylidenediphenoxy)diphtalic acid anhydride was dissolved in 70 g of N-methylpyrrolidone (NMP). Subsequently, 3.81 g (17.6 mmol) of 3,3′-dihydroxybenzidine and 3.74 g (17.6 mmol) of 2,2′-dimethylbenzidine were dissolved in 50 g of NMP, and the solution was added dropwise thereto over 1 hour at a temperature of 10° C. to 25° C., stirred at 25° C. for 30 minutes, 10 g of toluene was added thereto, the mixture was reacted at 200° C. for 4 hours while flowing nitrogen, and cooled to 25° C. Subsequently, 15.3 g (50 mmol) of 4-(chloromethyl)styrene, 16.6 g (120 mmol) of potassium carbonate, 1.66 g (12 mmol) of potassium iodide, and 0.08 g of 2,2,6,6-tetramethylpiperidine 1-oxide free radical were added thereto, the mixture was reacted at 95° C. for 15 hours, cooled to 25° C., and diluted with 120 g of tetrahydrofuran. Subsequently, the reaction solution was added dropwise to a mixed solution of 1.8 L of methanol and 0.6 L of water, and the mixture was stirred for 15 minutes and a polyimide resin was filtered. Next, the resin was subjected to reslurrying with 1 L of water, filtered, reslurried again with 1 L of methanol, filtered, and dried at 40° C. for 8 hours under reduced pressure. Subsequently, the resin dried as described above was dissolved in 250 g of tetrahydrofuran, 40 g of an ion exchange resin (MB-1: manufactured by ORGANO CORPORATION) was added thereto, the mixture was stirred for 4 hours, the ion exchange resin was filtered and removed, and then the polyimide resin was precipitated in 2 L of methanol and stirred for 15 minutes. The polyimide resin was filtered to be acquired, and dried at 45° C. for 1 day under reduced pressure to obtain a polymer 1. The polymer 1 is a resin having a repeating unit represented by the following formula. The subscript in parentheses of the following repeating unit represents content molar ratios of each repeating unit. The structure of the repeating unit was determined from a ¹H-NMR spectrum. The weight-average molecular weight of the polymer 1 was 25,000, the number-average molecular weight was 10,500, and the imidization rate was 99% or more.

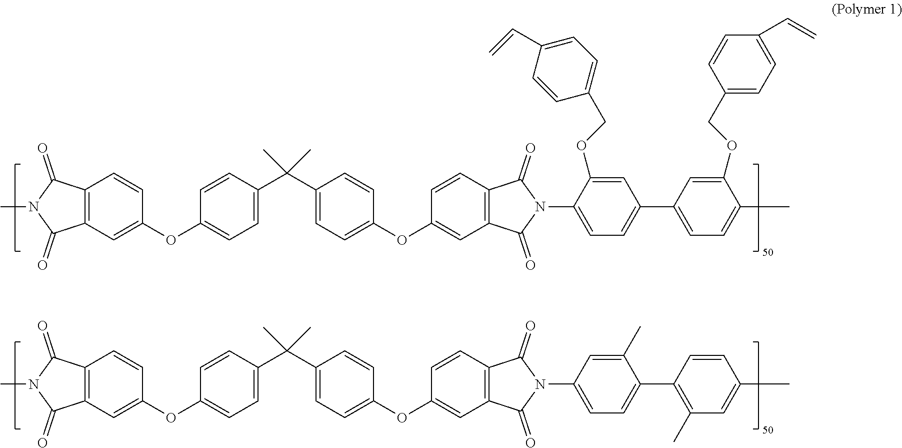

### Synthesis Example: Synthesis of Polymer 2

### —Synthesis of Diamine 2a for Polymer 2 Synthesis—

375 mL of dimethylformamide was mixed with 48.65 g (225 mmol) of 3,3′-dihydroxybenzidine in a flask. 98.21 g (450 millimoles) of di-t-butyl carbonate was added dropwise under ice cooling. Stirring was carried out at a temperature of 60° C. for 5 hours after completion of the dropwise addition. After the completion of the reaction, the mixture was cooled to room temperature, 35 mg of 2,2,6,6-tetramethylpiperidine 1-oxyl free radical, 68.68 g (450 mmol) of p-chloromethylstyrene, 74.63 g (540 mmol) of potassium carbonate, and 8.96 g (54.0 mmol) of potassium iodide were added thereto, and the mixture was stirred at a temperature of 60° C. for 3 hours. After completion of the reaction, filtration was carried out by a suction filtration operation, and the filtrate was added dropwise to 500 mL of water. Since white crystals were precipitated, the precipitated solid was collected by suction filtration. The obtained white solid was recrystallized and purified at 60° C. using 1000 mL of acetone. 125 g (yield: 85.6%) of the following intermediate 2b was obtained.

The structure of 2b is shown below. The following structure was confirmed from the ¹H-NMR spectrum.

¹H-NMR (BRUKER, AVANCE NEO 400): δ(ppm, DMSO-d6)8.04-7.94 (s, 2H), 7.75-7.64 (d, 2H), 7.56-7.42 (m, 8H), 7.27-7.20 (d, 2H), 7.19-7.12 (d, 2H), 6.79-6.64 (2H), 5.89-5.77 (2H), 5.30-5.15 (6H), 1.49-1.43 (s, 18H)

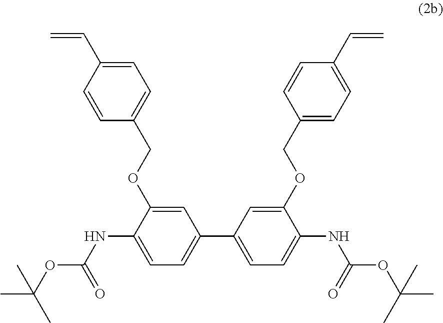 [SMILES: C=Cc1ccc(COc2cc(-c3ccc(NC(=O)OC(C)(C)C)c(OCc4ccc(C=C)cc4)c3)ccc2NC(=O)OC(C)(C)C)cc1]

75.0 g (115.6 millimoles) of 2b and 500 mL of methylene chloride were mixed in a 1 L flask. 131.8 g (1156 mmol) of trifluoroacetic acid was added thereto at room temperature, and the mixture was stirred at a temperature of 40° C. for 5 hours. After completion of the reaction, 250 mL of methanol and then 117.0 g (1156 mmol) of triethylamine were added dropwise under ice cooling. Since pale yellow crystals were precipitated, the precipitated solid was collected by suction filtration. Suspension washing was carried out with 750 mL of methanol to obtain 40.5 g (yield: 73%) of (2a). The structure of 2a is shown below. The following structure was confirmed from the ¹H-NMR spectrum.

¹H-NMR (BRUKER, AVANCE NEO 400): δ(ppm, DMSO-d6)7.53-7.45 (s, 8H), 7.05-6.98 (d, 2H), 6.92-6.85 (d, 2H), 6.79-6.63 (4H), 5.89-5.78 (d, 2H), 5.29-5.22 (d, 2H), 5.20-5.13 (s, 4H), 4.92-4.64 (4H)

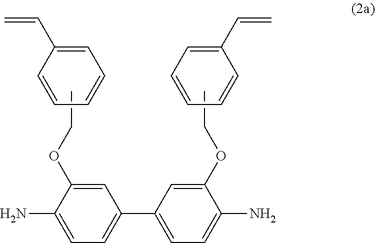

### —Synthesis of Polymer 2—

30.0 g (57.64 mmol) of 4,4′-(4,4′-isopropylidenediphenoxy)diphtalic acid anhydride and 0.08 g of 2,2,6,6-tetramethylpiperidine 1-oxyl free radical were dissolved in 120 g of N-methylpyrrolidone (NMP) to obtain a solution. Subsequently, 5.50 g (25.9 millimoles) of 2,2′-dimethylbenzidine and 11.62 g (25.9 millimoles) of 2a were dissolved in 100 g of NMP, and the solution was added dropwise to the above-described solution at a temperature of 0° C. to 10° C. over 1 hour, and stirred at 25° C. for 60 minutes, and then 18.2 g of pyridine and 14.7 g of acetic anhydride were added thereto, and the mixture was reacted at 80° C. for 4 hours. After completion of the reaction, the mixture was cooled to 25° C. and diluted with 200 g of tetrahydrofuran. Subsequently, the reaction solution was added dropwise to a mixed solution of 2.0 L of methanol and 0.5 L of water, and the mixture was stirred for 15 minutes and a polyimide resin was filtered. Next, the resin was subjected to reslurrying with 1 L of water, filtered, reslurried again with 1 L of methanol, filtered, and dried at 40° C. for 10 hours under reduced pressure. Subsequently, the resin dried as described above was dissolved in 250 g of tetrahydrofuran, 40 g of an ion exchange resin (MB-1: manufactured by ORGANO CORPORATION) was added thereto, the mixture was stirred for 4 hours, the ion exchange resin was filtered and removed, and then the polyimide resin was precipitated in 2 L of methanol and stirred for 15 minutes. The polyimide resin was filtered to be acquired, and dried at 45° C. for 1 day under reduced pressure to obtain a polymer 2. The polymer 2 is a resin having a repeating unit represented by the following formula. The subscript in parentheses of the following repeating unit represents content molar ratios of each repeating unit. The weight-average molecular weight of the polymer 2 was 25,000, the number-average molecular weight was 12,500, and the imidization rate was 99% or more. The structure of the repeating unit was determined from a ¹H-NMR spectrum.

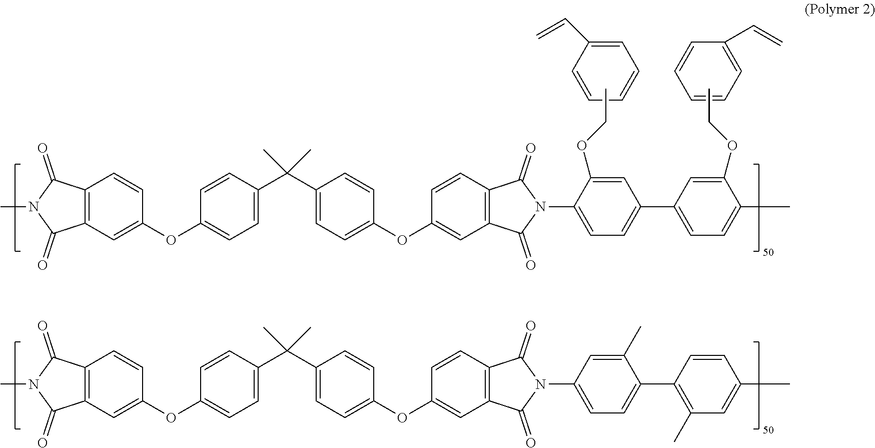

### Synthesis Example: Synthesis of Polymers 5 to 7

Polymers 5 to 7 were synthesized by the same method as in the polymer 2, except that the raw materials used were appropriately changed.

Polymers 5 to 7 are resins having a repeating unit represented by the following formula, respectively. The structure of each repeating unit was determined from a ¹H-NMR spectrum. In the following structures, the subscript of the parentheses represents the molar ratio of each structure. The weight-average molecular weight, the number-average molecular weight, and the imidization rate of these resins are described in the table below.

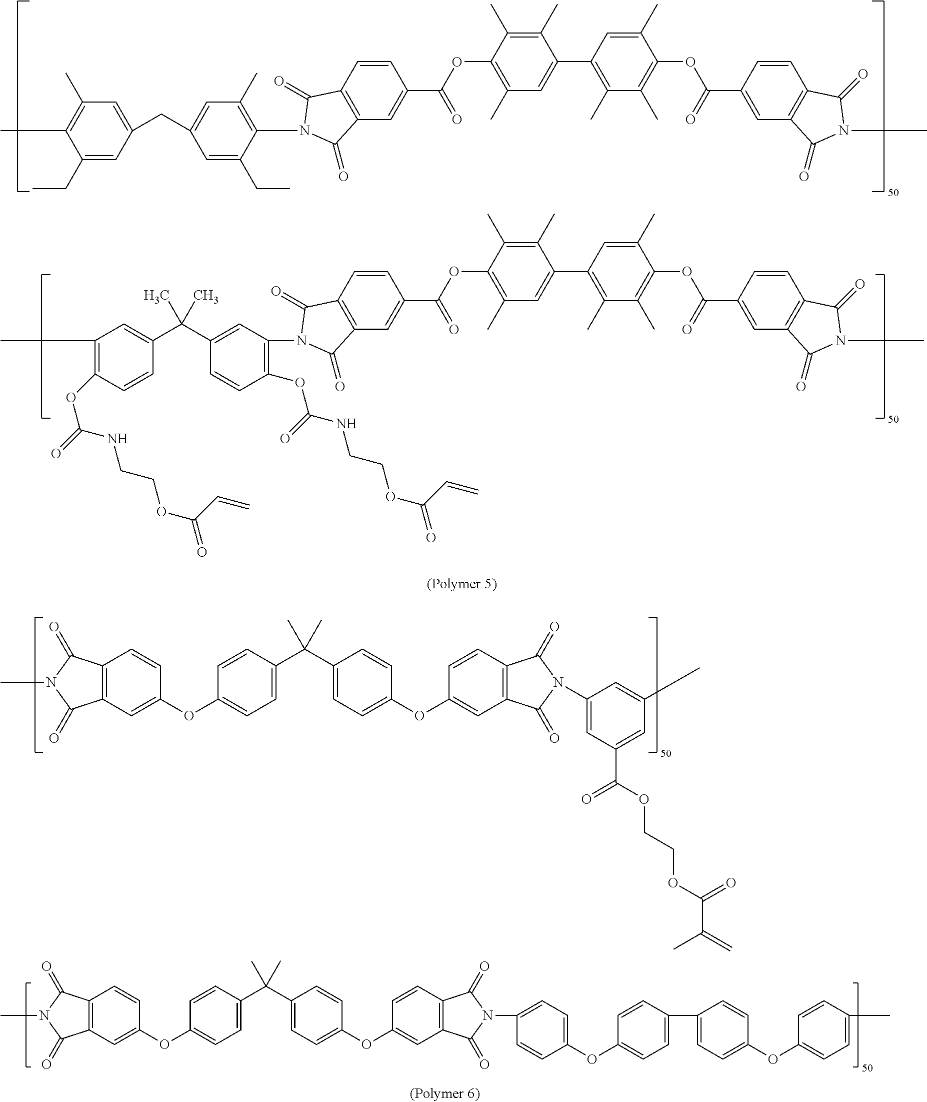

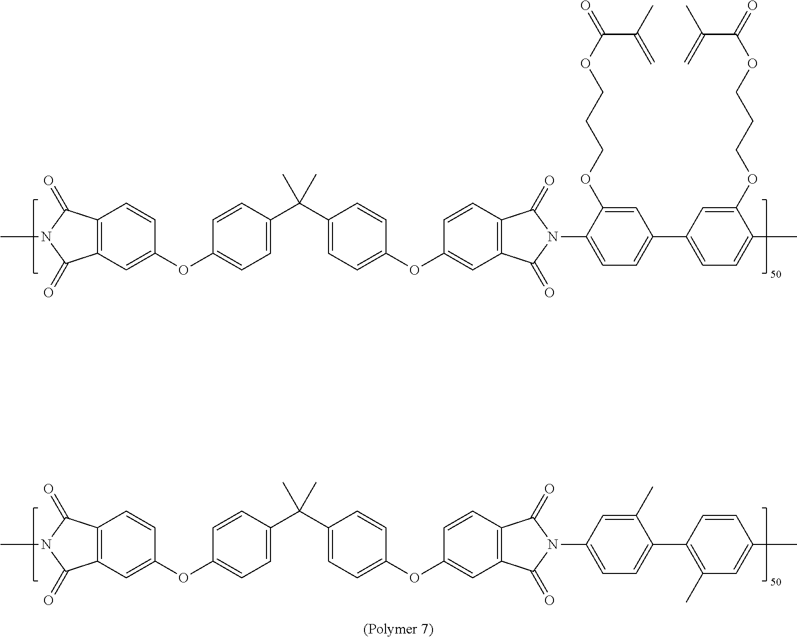

TABLE 1

| | Weight-average | Number-average | |
|---|---|---|---|
| | molecular weight | molecular | Imidization |
| Resin | (Mw) | weight (Mn) | rate (%) |
| Polymer 5 | 25,000 | 10,200 | 99% or more |
| Polymer 6 | 25,000 | 12,000 | 99% or more |
| Polymer 7 | 25,000 | 11,500 | 99% or more |

### Synthesis Example: Synthesis of Polymer 3

10.4 g (47.6 millimoles) of pyromellitic acid anhydride, 10.6 g (20.4 millimoles) of 4,4′-(4,4′-isopropylidenediphenoxy)bis(phthalic acid anhydride), 17.8 g (137 millimoles) of 2-hydroxyethyl methacrylate, 0.05 g of hydroquinone, 22.8 g (289 millimoles) of pyridine, and 75 g of diglyme were mixed and stirred at a temperature of 60° C. for 5 hours to produce a diester between each of pyromellitic acid anhydride and 4,4′-(4,4″-isopropylidenediphenoxy)bis(phthalic acid anhydride), and 2-hydroxyethyl methacrylate. Next, the mixture was cooled to −20° C., 17.70 g (141 millimoles) of thionyl chloride was subsequently added dropwise over 90 minutes, and stirring was carried out for 2 hours to obtain a white precipitate of pyridinium hydrochloride.

Next, a solution obtained by dissolving 19.3 g (60.5 millimoles) of 4,4′-diamino-2,2′-bis(trifluoromethyl)biphenyl in 100 mL of N-methyl-2-pyrrolidone (NMP) was added dropwise thereto over 2 hours. Next, 10.0 g (217 millimoles) of ethanol was added, and the mixture was stirred for 2 hours. Next, a polyimide precursor was precipitated in 4 L of water, and the water-polyimide precursor mixture was stirred at a speed of 500 rpm for 15 minutes. The polyimide precursor was filtered to be acquired, and stirred again in 4 L of water for 30 minutes and filtered again. Next, the obtained polyimide precursor was dried at 45° C. for 2 days under reduced pressure to obtain a polyimide precursor (polymer 3). The weight-average molecular weight (Mw) of the obtained polyimide precursor (polymer 3) was 25,000, and the number-average molecular weight (Mn) was 10,000. It is presumed that the polyimide precursor (polymer 3) has a structure including two repeating units represented by the following formula (polymer 3). The subscript in parentheses of the following repeating unit represents content molar ratios of each repeating unit. The weight-average molecular weight of the polymer 3 was 25,000, the number-average molecular weight was 10,000, and the imidization rate was less than 5%.

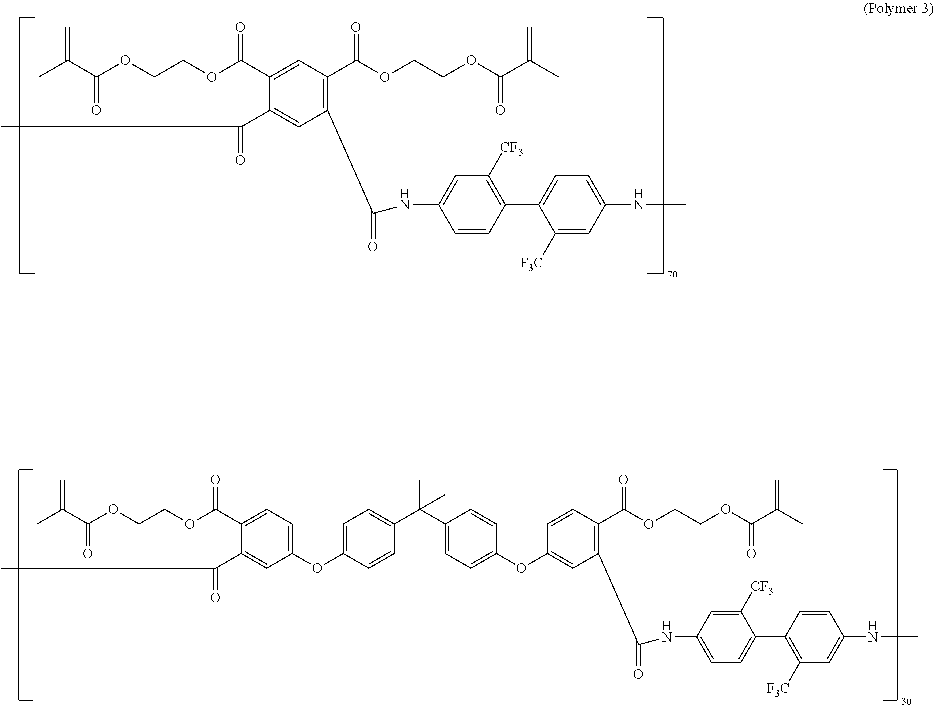

### Synthesis Example: Synthesis of Polymer 4

7.43 g (34.0 millimoles) of pyromellitic acid anhydride, 17.7 g (34.0 millimoles) of 4,4′-(4,4′-isopropylidenediphenoxy)bis(phthalic acid anhydride), 17.8 g (137 millimoles) of 2-hydroxyethyl methacrylate, 0.05 g of hydroquinone, 22.8 g (289 millimoles) of pyridine, and 75 g of diglyme were mixed and stirred at a temperature of 60° C. for 5 hours to produce a diester between each of pyromellitic acid anhydride and 4,4′-(4,4″-isopropylidenediphenoxy)bis(phthalic acid anhydride), and 2-hydroxyethyl methacrylate. Next, the mixture was cooled to −20° C., 17.70 g (141 millimoles) of thionyl chloride was subsequently added dropwise over 90 minutes, and stirring was carried out for 2 hours to obtain a white precipitate of pyridinium hydrochloride.

Next, 12.7 g (59.8 millimoles) of 2,2′-dimethylbenzidine dissolved in 100 mL of NMP (N-methyl-2-pyrrolidone) was added dropwise thereto over 2 hours. Next, 10.0 g (217 millimoles) of ethanol was added, and the mixture was stirred for 2 hours. Next, a polyimide precursor was precipitated in 4 L of water, and the water-polyimide precursor mixture was stirred at a speed of 500 rpm for 15 minutes. The polyimide precursor was filtered to be acquired, and stirred again in 4 L of water for 30 minutes and filtered again. Next, the obtained polyimide precursor was dried at 45° C. for 2 days under reduced pressure to obtain a polyimide precursor (polymer 4). The weight-average molecular weight (Mw) of the obtained polyimide precursor (polymer 4) was 25,000, and the number-average molecular weight (Mn) was 9,950. It is presumed that the polyimide precursor (polymer 4) has a structure including two repeating units represented by the following formula (polymer 4). The subscript in parentheses of the following repeating unit represents content molar ratios of each repeating unit. The weight-average molecular weight of the polymer 4 was 25,000, the number-average molecular weight was 9,950, and the imidization rate was less than 5%.

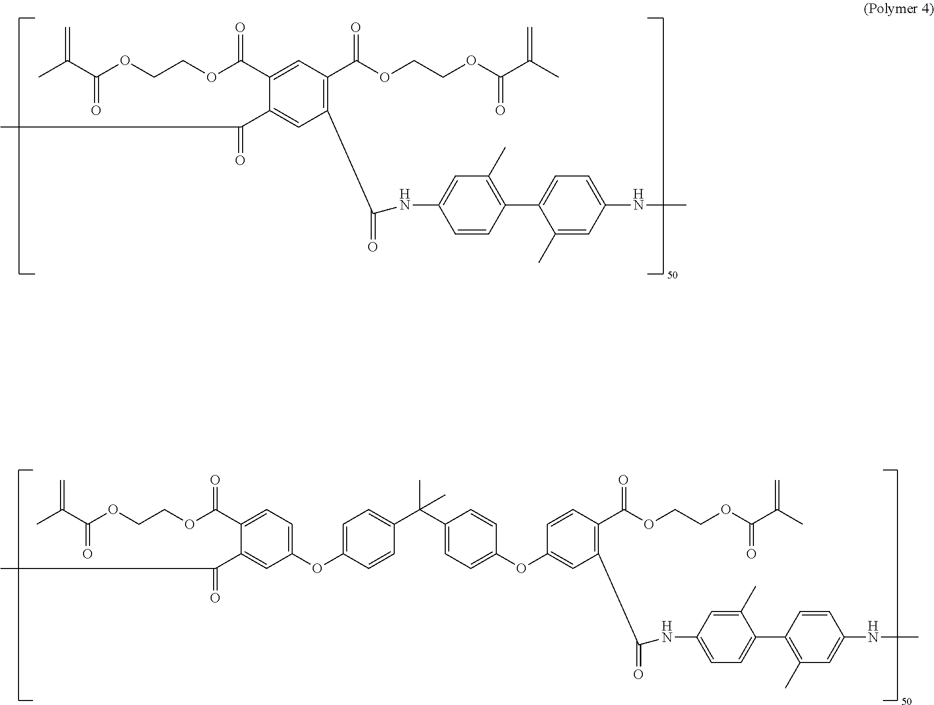

### Synthesis Example: Synthesis of Polymer 8

23.5 g (75.7 millimoles) of 4,4′-oxydiphthalic acid dianhydride (ODPA) and 22.3 g (75.7 millimoles) of bisphthalic acid dianhydride (BPDA) were placed in a separable flask, 39.7 g of 2-hydroxyethyl methacrylate (HEMA) and 136.8 g of tetrahydrofuran were added thereto, and the mixture was stirred at room temperature (25° C.), and 24.7 g of pyridine was added thereto while stirring to obtain a reaction mixture. After the heat generation due to the reaction was stopped, the mixture was allowed to cool to room temperature and left to stand for 16 hours.

Next, Next, under ice-cooling, a solution obtained by dissolving 62.5 g of dicyclohexylcarbodiimide (DCC) in 61.6 g of tetrahydrofuran was added to the reaction mixture over 40 minutes with stirring, and subsequently a suspension obtained by suspending 27.6 g (137.8 mmol) of 4,4′-diaminodiphenyl ether (DADPE) in 119.7 g of tetrahydrofuran was added thereto over 60 minutes with stirring. Further, the mixture was stirred at room temperature for 2 hours, 7.17 g of ethanol was added thereto, and the mixture was stirred for 1 hour, and then 136.8 g of tetrahydrofuran was added thereto. The precipitate formed in the reaction mixture was removed by filtration to obtain a reaction solution.

The obtained reaction solution was added to 716.2 g of ethanol to generate a precipitate consisting of a crude polymer. The generated crude polymer was filtered out and then dissolved in 403.5 g of tetrahydrofuran to obtain a crude polymer solution. The obtained crude polymer solution was added dropwise to 8470 g of water to precipitate the polymer, and the obtained precipitate was filtered. Next, the obtained polyimide precursor was dried at 45° C. for 2 days under reduced pressure to obtain a polyimide precursor (polymer 8). The weight-average molecular weight (Mw) of the obtained polyimide precursor (polymer 8) was 25,300, and the number-average molecular weight (Mn) was 10,150. It is presumed that the polyimide precursor (polymer 8) has a structure including two repeating units represented by the following formula (polymer 8). The subscript in parentheses of the following repeating unit represents content molar ratios of each repeating unit. The weight-average molecular weight of the polymer 8 was 25,000, the number-average molecular weight was 10,150, and the imidization rate was 20%.

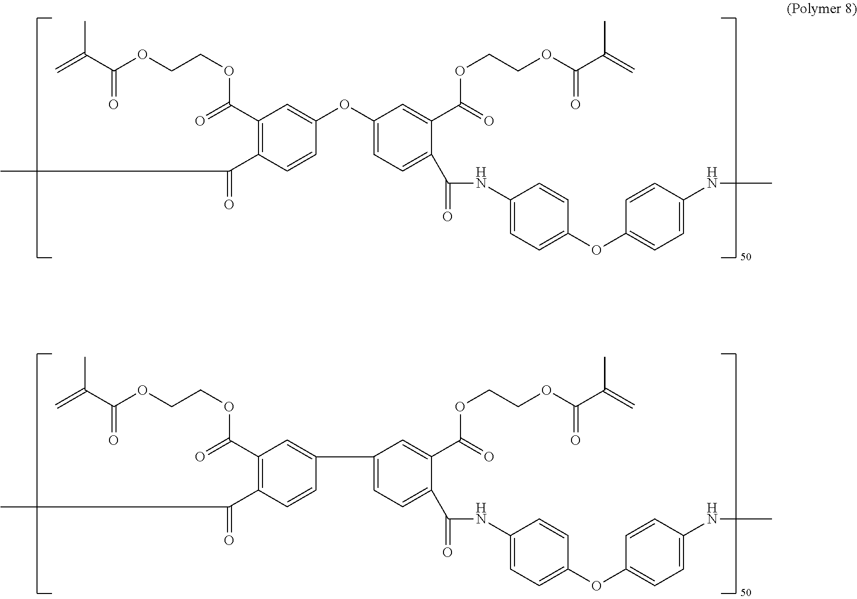

### Synthesis Example: Synthesis of Polymers 9 to 15

Polymers 9 to 15 were synthesized by the same method as in the polymer 3 and the polymer 4, except that the raw materials used were appropriately changed. Each polymer is a resin having a repeating unit represented by the following formula. The structure of each repeating unit was determined from a ¹H-NMR spectrum. In the following structures, the subscript of the parentheses represents the molar ratio of each structure.

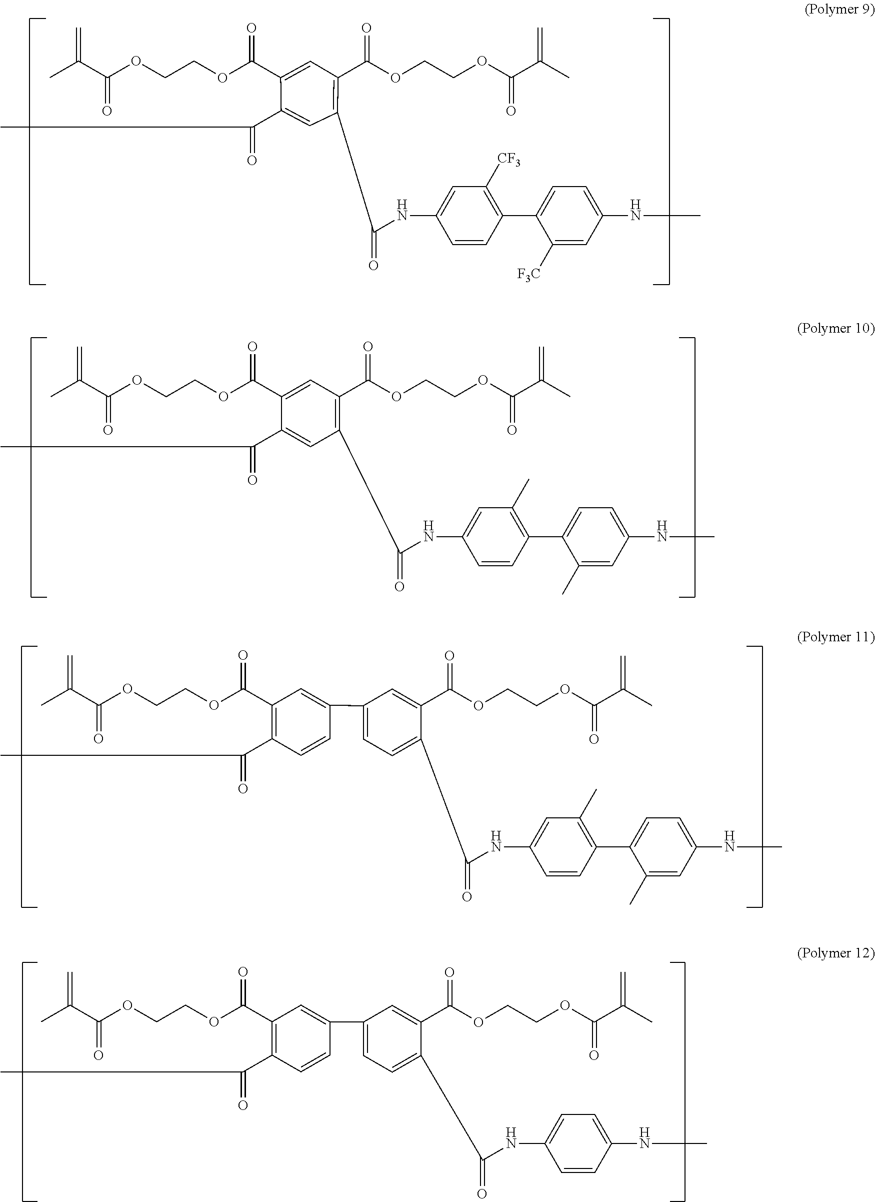

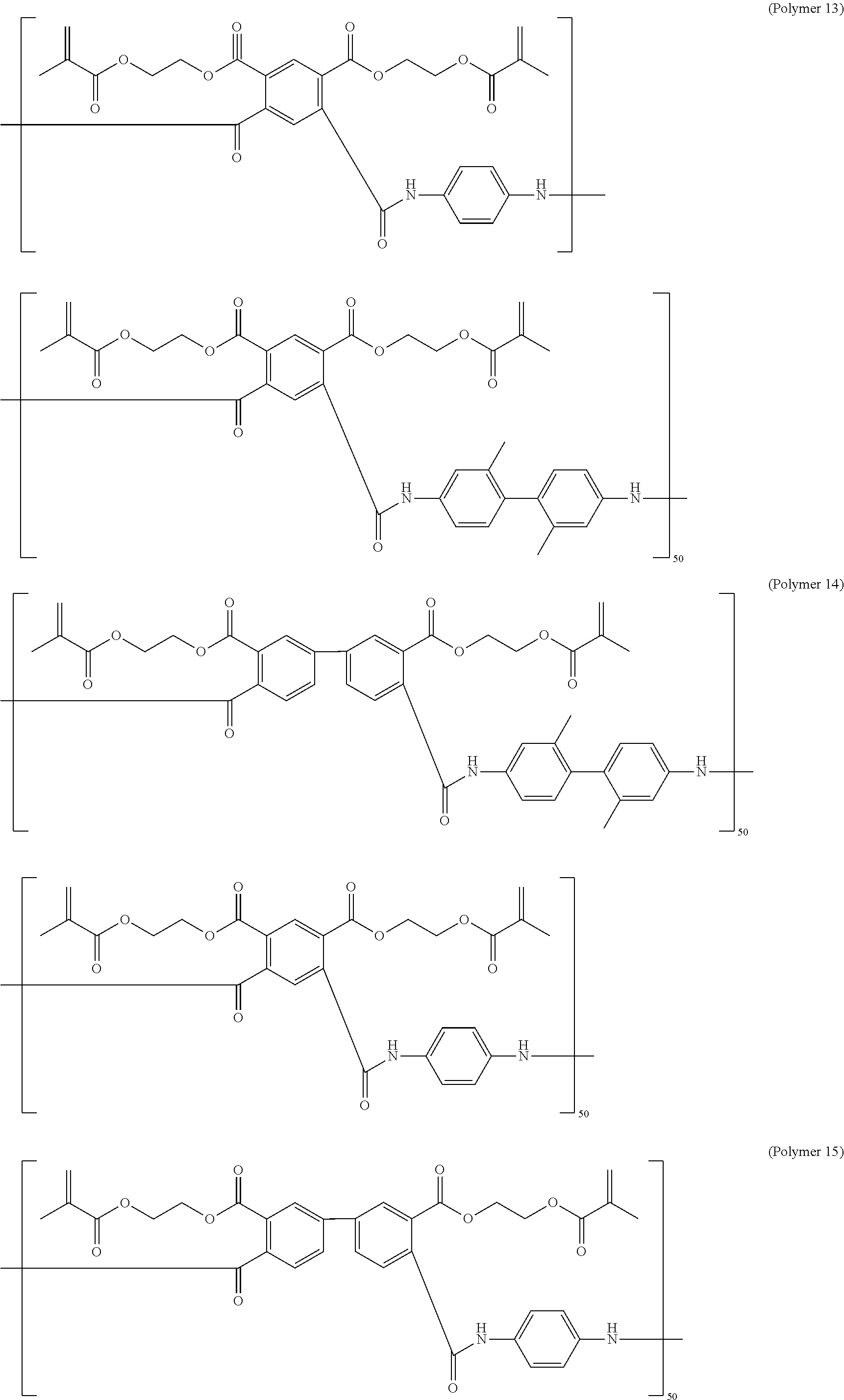

TABLE 2

| | Weight-average | Number-average | |
|---|---|---|---|
| | molecular | molecular | Imidization |
| Resin | weight (Mw) | weight (Mn) | rate (%) |
| Polymer 9 | 25,000 | 10,000 | 2 |
| Polymer 10 | 25,000 | 10,000 | 0 |
| Polymer 11 | 25,000 | 10,500 | 10 |
| Polymer 12 | 25,000 | 10,500 | 10 |
| Polymer 13 | 25,000 | 10,000 | 2 |
| Polymer 14 | 25,000 | 11,000 | 20 |
| Polymer 15 | 25,000 | 12,500 | 15 |

### EXAMPLES

In each of Examples, the components shown in the following table were mixed to obtain each composition for forming an insulating pattern A.

Specifically, the content of each component described in the table was set to the amount (in terms of parts by mass) described in the column of “Parts by mass” of each column of the table.

The obtained composition for forming an insulating pattern A and the comparative composition were pressurized and filtered using a filter made of polypropylene having a pore width of 0.45 μm.

In addition, in the table, the description of “-” indicates that the corresponding component is not contained in the composition.

TABLE 3

| | | Example 1 | Example 2 | Example 3 | Example 4 | Example 5 | Example 6 | Example 7 |
|---|---|---|---|---|---|---|---|---|
| Polymer | Name | Polymer 1 | Polymer 1 | Polymer 1 | Polymer 2 | Polymer 3 | Polymer 4 | Polymer 4 |
| | Parts by | 75.16 | 75.16 | 73.16 | 75.16 | 75.16 | 75.16 | 75.16 |
| | mass | | | | | | | |
| Polymer- | Name | Polymer- | Polymer- | Polymer- | Polymer- | Polymer- | Polymer- | Polymer- |
| izable | | izable | izable | izable | izable | izable | izable | izable |
| compound | | compound 2 | compound 2 | compound 1 | compound 2 | compound 2 | compound 1 | compound 2 |
| | Parts by | 18.50 | 18.50 | 18.50 | 18.50 | 18.50 | 18.50 | 18.50 |
| | mass | | | | | | | |
| Polymer- | Name | Polymer- | Polymer- | Polymer- | Polymer- | Polymer- | Polymer- | Polymer- |
| ization | | ization | ization | ization | ization | ization | ization | ization |
| initiator | | initiator 1 | initiator 1 | initiator 1 | initiator 1 | initiator 1 | initiator 1 | initiator 1 |
| | Parts by | 4.31 | 4.31 | 4.31 | 4.31 | 4.31 | 4.31 | 4.31 |
| | mass | | | | | | | |
| | Name | — | — | — | — | — | — | — |
| | Parts by | — | — | — | — | — | — | — |
| | mass | | | | | | | |
| | Name | — | — | — | — | — | — | — |
| | Parts by | — | — | — | — | — | — | — |
| | mass | | | | | | | |
| Migration | Name | Migration | Migration | Migration | Migration | Migration | Migration | Migration |
| suppressing | | suppressing | suppressing | suppressing | suppressing | suppressing | suppressing | suppressing |
| agent | | agent 1 | agent 1 | agent 1 | agent 1 | agent 1 | agent 1 | agent 1 |
| | Parts by | 0.27 | 0.27 | 0.27 | 0.27 | 0.27 | 0.27 | 0.27 |
| | mass | | | | | | | |
| Metal ad- | Name | Metal ad- | Metal ad- | Metal ad- | Metal ad- | Metal ad- | Metal ad- | Metal ad- |
| hesiveness | | hesiveness | hesiveness | hesiveness | hesiveness | hesiveness | hesiveness | hesiveness |
| improving | | improving | improving | improving | improving | improving | improving | improving |
| agent | | agent 1 | agent 1 | agent 1 | agent 1 | agent 1 | agent 1 | agent 1 |
| | Parts by | 1.64 | 1.64 | 1.64 | 1.64 | 1.64 | 1.64 | 1.64 |
| | mass | | | | | | | |
| Light | Name | — | — | Light | — | Light | — | — |
| absorbing | | | | absorbing | | absorbing | | |
| agent | | | | agent 1 | | agent 1 | | |
| | Parts by | — | — | 2.00 | — | 2.00 | — | — |
| | mass | | | | | | | |
| Organic | Name | Organic | — | — | — | — | Organic | Organic |
| titanium | | titanium | | | | | titanium | titanium |
| compound | | compound 1 | | | | | compound 1 | compound 1 |
| | Parts by | 2.00 | — | — | — | — | 2.00 | 2.00 |
| | mass | | | | | | | |
| Polymer- | Name | Polymer- | Polymer- | Polymer- | Polymer- | Polymer- | Polymer- | Polymer- |
| ization | | ization | ization | ization | ization | ization | ization | ization |
| inhibitor | | inhibitor 1 | inhibitor 1 | inhibitor 1 | inhibitor 1 | inhibitor 1 | inhibitor 1 | inhibitor 1 |
| | Parts by | 0.11 | 0.11 | 0.11 | 0.11 | 0.11 | 0.11 | 0.11 |
| | mass | | | | | | | |
| Base | Name | — | Base | — | — | Base | — | Base |
| generator | | | generator 1 | | | generator 1 | | generator 1 |
| | Parts by | — | 2.04 | — | — | 2.04 | — | 2.04 |
| | mass | | | | | | | |
| Solvent | Name | Solvent 1 | Solvent 2 | Solvent 1 | Solvent 1 | Solvent 1 | Solvent 1 | Solvent 1 |
| | Parts by | 160.00 | 200.00 | 160.00 | 160.00 | 160.00 | 160.00 | 160.00 |
| | mass | | | | | | | |
| | Name | Solvent 3 | — | Solvent 3 | Solvent 3 | Solvent 3 | Solvent 3 | Solvent 3 |
| | Parts by | 40.00 | — | 40.00 | 40.00 | 40.00 | 40.00 | 40.00 |
| | mass | | | | | | | |
| | | Example 8 | Example 9 | Example 10 | Example 11 | Example 12 | Example 13 | Example 14 |
| Polymer | Name | Polymer 5 | Polymer 6 | Polymer 7 | Polymer 9 | Polymer 10 | Polymer 11 | Polymer 12 |
| | Parts by | 75.16 | 75.16 | 75.16 | 75.16 | 75.16 | 75.16 | 75.16 |
| | mass | | | | | | | |
| Polymer- | Name | Polymer- | Polymer- | Polymer- | Polymer- | Polymer- | Polymer- | Polymer- |
| izable | | izable | izable | izable | izable | izable | izable | izable |
| compound | | compound 1 | compound 2 | compound 2 | compound 1 | compound 2 | compound 2 | compound 1 |
| | Parts by | 18.50 | 18.50 | 18.50 | 18.50 | 18.50 | 18.50 | 18.50 |
| | mass | | | | | | | |
| Polymer- | Name | Polymer- | Polymer- | Polymer- | Polymer- | Polymer- | Polymer- | Polymer- |
| ization | | ization | ization | ization | ization | ization | ization | ization |
| initiator | | initiator 1 | initiator 1 | initiator 1 | initiator 1 | initiator 1 | initiator 1 | initiator 1 |
| | Parts by | 4.31 | 4.31 | 4.31 | 4.31 | 4.31 | 4.31 | 4.31 |
| | mass | | | | | | | |
| | Name | — | — | — | — | — | — | — |
| | Parts by | — | — | — | — | — | — | — |
| | mass | | | | | | | |
| | Name | — | — | — | — | — | — | — |
| | Parts by | — | — | — | — | — | — | — |
| | mass | | | | | | | |
| Migration | Name | Migration | Migration | Migration | Migration | Migration | Migration | Migration |
| suppressing | | suppressing | suppressing | suppressing | suppressing | suppressing | suppressing | suppressing |
| agent | | agent 1 | agent 1 | agent 1 | agent 1 | agent 1 | agent 1 | agent 1 |
| | Parts by | 0.27 | 0.27 | 0.27 | 0.27 | 0.27 | 0.27 | 0.27 |
| | mass | | | | | | | |
| Metal ad- | Name | Metal ad- | Metal ad- | Metal ad- | Metal ad- | Metal ad- | Metal ad- | Metal ad- |
| hesiveness | | hesiveness | hesiveness | hesiveness | hesiveness | hesiveness | hesiveness | hesiveness |
| improving | | improving | improving | improving | improving | improving | improving | improving |
| agent | | agent 1 | agent 1 | agent 1 | agent 1 | agent 1 | agent 1 | agent 1 |
| | Parts by | 1.64 | 1.64 | 1.64 | 1.64 | 1.64 | 1.64 | 1.64 |
| | mass | | | | | | | |
| Light | Name | — | Light | — | — | — | — | Light |
| absorbing | | | absorbing | | | | | absorbing |
| agent | | | agent 1 | | | | | agent 1 |
| | Parts by | — | 2.00 | — | — | — | — | 2.00 |
| | mass | | | | | | | |
| Organic | Name | Organic | Organic | Organic | Organic | — | Organic | Organic |
| titanium | | titanium | titanium | titanium | titanium | | titanium | titanium |
| compound | | compound 1 | compound 1 | compound 1 | compound 1 | | compound 1 | compound 1 |
| | Parts by | 2.00 | 2.00 | 2.00 | 2.00 | — | 2.00 | 2.00 |
| | mass | | | | | | | |
| Polymer- | Name | Polymer- | Polymer- | Polymer- | Polymer- | Polymer- | Polymer- | Polymer- |
| ization | | ization | ization | ization | ization | ization | ization | ization |
| inhibitor | | inhibitor 1 | inhibitor 1 | inhibitor 1 | inhibitor 1 | inhibitor 1 | inhibitor 1 | inhibitor 1 |
| | Parts by | 0.11 | 0.11 | 0.11 | 0.11 | 0.11 | 0.11 | 0.11 |
| | mass | | | | | | | |
| Base | Name | Base | Base | — | Base | — | — | — |
| generator | | generator 1 | generator 1 | | generator 1 | | | |
| | Parts by | 2.04 | 2.04 | — | 2.04 | — | — | — |
| | mass | | | | | | | |
| Solvent | Name | Solvent 1 | Solvent 1 | Solvent 1 | Solvent 1 | Solvent 1 | Solvent 1 | Solvent 1 |
| | Parts by | 160.00 | 160.00 | 160.00 | 160.00 | 160.00 | 160.00 | 160.00 |
| | mass | | | | | | | |
| | Name | Solvent 3 | Solvent 3 | Solvent 3 | Solvent 3 | Solvent 3 | Solvent 3 | Solvent 3 |
| | Parts by | 40.00 | 40.00 | 40.00 | 40.00 | 40.00 | 40.00 | 40.00 |
| | mass | | | | | | | |

TABLE 4

| | | | | | Comparative |
|---|---|---|---|---|---|
| | | Example 15 | Example 16 | Example 17 | Example 1 |
| Polymer | Name | Polymer 13 | Polymer 14 | Polymer 15 | Polymer 8 |
| | Parts by | 75.16 | 75.16 | 75.16 | 75.16 |
| | mass | | | | |
| Polymerizable | Name | Polymerizable | Polymerizable | Polymerizable | Polymerizable |
| compound | | compound 2 | compound 1 | compound 1 | compound 1 |
| | Parts by | 18.50 | 18.50 | 18.50 | 18.50 |
| | mass | | | | |
| Polymerization | Name | Polymerization | Polymerization | Polymerization | Polymerization |
| initiator | | initiator 1 | initiator 1 | initiator 1 | initiator 2 |
| | Parts by | 4.31 | 4.31 | 4.31 | 2.20 |
| | mass | | | | |
| | Name | — | — | — | Polymerization |
| | | | | | initiator 3 |
| | Parts by | — | — | — | 1.50 |
| | mass | | | | |
| | Name | — | — | — | Polymerization |
| | | | | | initiator 4 |
| | Parts by | — | — | — | 1.50 |
| | mass | | | | |
| Migration | Name | Migration | Migration | Migration | Migration |
| suppressing | | suppressing | suppressing | suppressing | suppressing |
| agent | | agent 1 | agent 1 | agent 1 | agent 1 |
| | Parts by | 0.27 | 0.27 | 0.27 | 0.27 |
| | mass | | | | |
| Metal | Name | Metal | Metal | Metal | Metal |
| adhesiveness | | adhesiveness | adhesiveness | adhesiveness | adhesiveness |
| improving | | improving | improving | improving | improving |
| agent | | agent 1 | agent 1 | agent 1 | agent 1 |
| | Parts by | 1.64 | 1.64 | 1.64 | 1.64 |
| | mass | | | | |
| Light | Name | — | — | Light | — |
| absorbing | | | | absorbing | |
| agent | | | | agent 1 | |
| | Parts by | — | — | — | — |
| | mass | | | | |
| Organic | Name | — | Organic | Organic | — |
| titanium | | | titanium | titanium | |
| compound | | | compound 1 | compound 1 | |
| | Parts by | — | 2.00 | 2.00 | — |
| | mass | | | | |
| Polymerization | Name | Polymerization | Polymerization | Polymerization | Polymerization |
| inhibitor | | inhibitor 1 | inhibitor 1 | inhibitor 1 | inhibitor 1 |
| | Parts by | 0.11 | 0.11 | 0.11 | 0.11 |
| | mass | | | | |
| Base generator | Name | Base generator 1 | Base generator 1 | — | — |
| | Parts by | 2.04 | 2.04 | — | — |
| | mass | | | | |
| Solvent | Name | Solvent 1 | Solvent 1 | Solvent 1 | Solvent 1 |
| | Parts by | 160.00 | 160.00 | 160.00 | 160.00 |
| | mass | | | | |
| | Name | Solvent 3 | Solvent 3 | Solvent 3 | Solvent 3 |
| | Parts by | 40.00 | 40.00 | 40.00 | 40.00 |
| | mass | | | | |

Details of each of the components listed in the table are as follows.

### [Polymer (Resin)]

Polymers 1 to 8: polymers 1 to 8 synthesized above

### [Polymerizable Compound]

Polymerizable compound 1: compound having the following structure
Polymerizable compound 2: compound having the following structure (in the following structure, the number represents the molar ratio of each structure)

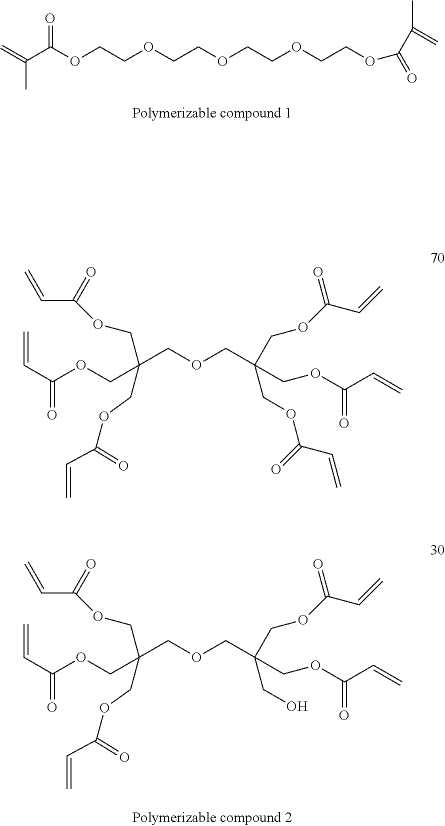 [SMILES: C=C(C)C(=O)OCCOCCOCCOCCOC(=O)C(=C)C ; C=CC(=O)OCC(COCC(COC(=O)C=C)(COC(=O)C=C)COC(=O)C=C)(COC(=O)C=C)COC(=O)C=C ; C=CC(=O)OCC(CO)(COCC(COC(=O)C=C)(COC(=O)C=C)COC(=O)C=C)COC(=O)C=C]

### [Polymerization Initiator]

Polymerization initiators 1 to 4 compound having the following structure

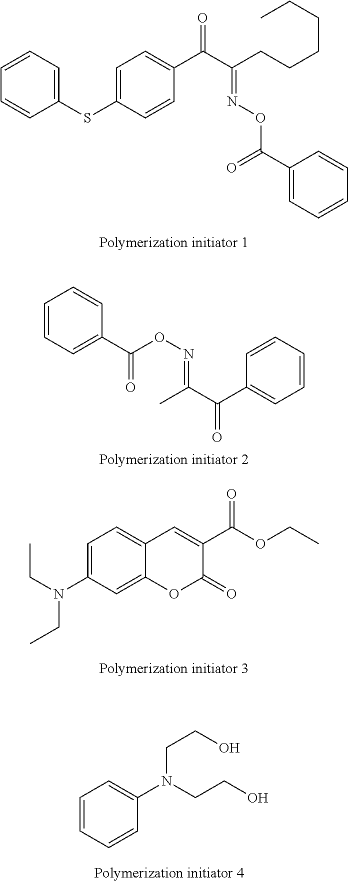 [SMILES: CCCCCC/C(=N\OC(=O)c1ccccc1)C(=O)c1ccc(Sc2ccccc2)cc1 ; C/C(=N\OC(=O)c1ccccc1)C(=O)c1ccccc1 ; CCOC(=O)c1cc2ccc(N(CC)CC)cc2oc1=O ; OCCN(CCO)c1ccccc1]

### [Migration Suppressing Agent]

Migration suppressing agent 1: compound having the following structure

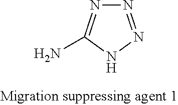

### [Metal Adhesiveness Improving Agent]

Metal adhesiveness improver 1: compound having the following structure

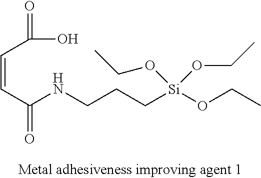 [SMILES: CCO[Si](CCCNC(=O)/C=C\C(=O)O)(OCC)OCC]

### [Light Absorbing Agent]

Light absorbing agent 1: compound having the following structure

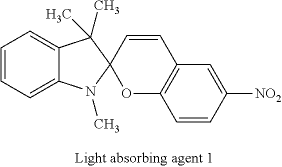 [SMILES: CN1c2ccccc2C(C)(C)C12C=Cc1cc([N+](=O)[O-])ccc1O2]

### [Organic Titanium Compound]

Organic titanium compound 1: compound having the following structure

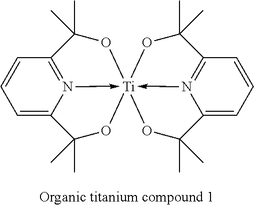

### [Polymerization Inhibitor]

Polymerization inhibitor 1: compound having the following structure

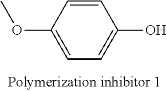

### [Base Generator]

Base generator 1: compound having the following structure

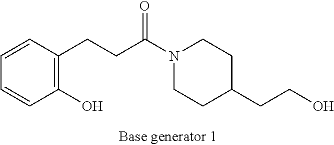 [SMILES: O=C(CCc1ccccc1O)N1CCC(CCO)CC1]

### [Solvent]

Solvent 1: GBL (7-butyrolactone)
Solvent 2: NMP (N-methyl-2-pyrrolidone)
Solvent 3: DMSO (dimethyl sulfoxide)

### <Evaluation>

### [Evaluation of Mass Reduction Rate]

In each of Examples, the resin composition was applied onto a silicon wafer by a spin coating method to form a resin composition layer. The silicon wafer to which the obtained resin composition layer was applied was dried on a hot plate at 100° C. for 5 minutes. The entire surface of the obtained resin composition layer was exposed to i-rays at an exposure energy of 500 mJ/cm² using a stepper (Nikon NSR 2005 i9C). After the above-described exposure, the resin composition layer was developed for 60 seconds using cyclopentanone as a developer, and rinsed for 30 seconds using PGMEA.

The resin composition layer (resin layer) after the above-described rinsing was heated to 230° C. at a temperature rising rate of 10° C./min in a nitrogen atmosphere, and heated for 3 hours after reaching 230° C. The resin layer (cured substance) after the curing was immersed in an aqueous solution of 4.9% by mass hydrofluoric acid solution, and the cured substance was peeled off from the silicon wafer. The film peeled off as described above was put into an aluminum pan in an amount of 1 to 5 mg, and the mass reduction rate was measured under the following conditions using a TG-DTA2500 manufactured by NETZSCH Japan Co., Ltd.

### —Measurement Conditions—

In a nitrogen atmosphere, the temperature conditions were changed in the following order of (1) to (2), the mass (mass A) before (1) and the mass (mass B) after (2) were measured, and the mass reduction rate was calculated according to the following expression.
(1) The temperature is raised from 25° C. to 250° C. at a rate of 10° C./min and maintained at 250° C. for 1 hour.
(2) The temperature is cooled to 25° C.

$$Mass reduction rate ( \% ) = ( 1 - mass B / mass A ) \times 100$$

The evaluation was performed according to the following evaluation standard, and the evaluation results are shown in the column of “Mass reduction rate” in the table.

### —Evaluation Standards—

A: The mass reduction rate was less than 5%.
B: The mass reduction rate was 5% or more and 7.5% or less.
C: The mass reduction rate was more than 7.5% and 10% or less.
D: The mass reduction rate was more than 10%.

### [Evaluation of Long-Term Reliability]

A copper thin film was sputtered on a silicon substrate, and a copper wiring pattern was formed by photolithography using a known method. The composition shown in Table 2 was applied onto the copper wiring pattern using a spin coater, dried at 100° C. for 5 minutes, and then baked at 250° C. for 1 hour to produce a test piece for reliability evaluation. The copper wiring pattern of the test piece was a line & space pattern consisting of a line of 10 μm and a space of 10 μm, and the thickness of the copper wiring was 1 μm.

A voltage of 5 V was applied to the copper terminal portion of the test piece, and the conductivity state after 100 hours was evaluated.

### —Evaluation Standards—

4: Among 10 test pieces put into the test, there was no test piece with conductivity failure.
3: Among 10 test pieces put into the test, 1 test piece had conductivity failure.
2: Among 10 test pieces put into the test, 2 to 3 test pieces had conductivity failure.
1: Among 10 test pieces put into the test, there were 4 or more test pieces with conductivity failure.

TABLE 5

| | Mass reduction rate | Long-term reliability |
|---|---|---|
| Example 1 | A | 4 |
| Example 2 | A | 4 |
| Example 3 | A | 4 |
| Example 4 | A | 3 |
| Example 5 | B | 3 |
| Example 6 | B | 4 |
| Example 7 | B | 3 |
| Example 8 | A | 4 |
| Example 9 | A | 4 |
| Example 10 | A | 4 |
| Example 11 | B | 4 |
| Example 12 | A | 4 |
| Example 13 | B | 3 |
| Example 14 | B | 4 |
| Example 15 | A | 3 |
| Example 16 | B | 3 |
| Example 17 | A | 4 |
| Comparative | D | 1 |
| Example 1 | | |

### EXPLANATION OF REFERENCES

10: laminate
12: sealing layer
14: re-distribution layer A
16: re-distribution layer B
18: member having circuit
20: circuit
22: semiconductor member
24: sealing material
26: conductive through via
28: connecting member A
30: connecting member B
32: other functional die
34: circuit member
50: laminate
62: carrier wafer
64: second carrier wafer
66: third carrier wafer
102: connecting member A
104: insulating pattern A
106: barrier layer
108: conductive pattern A
110: solder member
112: pillar

What is claimed is:

1. A laminate comprising:
a sealing layer including a member having a circuit and a sealing material;
a re-distribution layer A in contact with one surface of the sealing layer and connected to the circuit of the member; and
a re-distribution layer B in contact with the other surface of the sealing layer and not directly connected to the circuit of the member,
wherein the re-distribution layer A and the re-distribution layer B are formed to be electrically connectable to other members,
the re-distribution layer A includes an insulating pattern A and a conductive pattern A existing between patterns of the insulating pattern A,
the re-distribution layer B includes an insulating pattern B and a conductive pattern B existing between patterns of the insulating pattern B, and
the insulating pattern A is formed of a composition having a mass reduction rate of 10% or less when a cured product obtained by curing the composition at 230° C. for 3 hours is held at 250° C. for 1 hour.

2. The laminate according to claim 1,
wherein the member having the circuit is a functional die.

3. The laminate according to claim 2, further comprising:
a functional die electrically connected to the re-distribution layer A.

4. The laminate according to claim 1,
wherein the member having the circuit is a wiring layer, and the laminate further includes two or more semiconductor devices electrically connected to the re-distribution layer A.

5. The laminate according to claim 1, further comprising:
a circuit member connected to the re-distribution layer B and including wiring and an insulating layer.

6. The laminate according to claim 1,
wherein the re-distribution layer A and the re-distribution layer B are connected to each other through wiring.

7. The laminate according to claim 1,
wherein the re-distribution layer A includes two or more layers including the insulating pattern A and the conductive pattern A.

8. The laminate according to claim 1,
wherein the conductive pattern A includes a line pattern, and a minimum line width of the line pattern is 0.1 to 10 μm.

9. The laminate according to claim 1,
wherein a thickness of the re-distribution layer A is 1 to 100 μm.

10. The laminate according to claim 1,
wherein at least a part of the conductive pattern A has a barrier layer.

11. The laminate according to claim 1, further comprising:
a connecting member A provided on a surface of the re-distribution layer A different from a surface of the re-distribution layer A in contact with the sealing layer.

12. The laminate according to claim 11,
wherein the connecting member A has a substantially spherical cap shape.

13. The laminate according to claim 12,
wherein a height of the connecting member A is 50 μm or less.

14. The laminate according to claim 11,
wherein the connecting member A has a substantially columnar shape.

15. The laminate according to claim 14,
wherein a height of the connecting member A is 20 μm or less.

16. The laminate according to claim 11,
wherein the connecting member A includes a bonding pad structure having an average diameter of 5 μm or less.

17. A manufacturing method of a laminate, comprising:
a sealing layer forming step of embedding a member having a circuit in a sealing material, and forming a sealing layer in which the circuit of the member is exposed on one surface and the circuit of the member is not exposed on the other surface;
a re-distribution layer A forming step of forming a re-distribution layer A, which includes an insulating pattern A and a conductive pattern A existing between patterns of the insulating pattern A, on the surface of the sealing layer on which the circuit is exposed; and
a re-distribution layer B forming step of forming a re-distribution layer B, which includes an insulating pattern B and a conductive pattern B existing between patterns of the insulating pattern B, on the surface of the sealing layer on which the circuit is not exposed,
wherein the insulating pattern A has a mass reduction rate of 10% or less when held at 250° C. for 1 hour.

18. The manufacturing method of a laminate according to claim 17,
wherein the member having the circuit is a functional die.

19. The manufacturing method of a laminate according to claim 17,
wherein the member having the circuit is a wiring layer, and the manufacturing method further includes a step of bonding two or more functional dies to the re-distribution layer A.

20. The manufacturing method of a laminate according to claim 17,
wherein the re-distribution layer A forming step includes applying a composition for forming the insulating pattern A onto the sealing material to form a film.

21. The manufacturing method of a laminate according to claim 20,
wherein the composition for forming the insulating pattern A contains a resin having at least one repeating unit selected from the group consisting of a repeating unit represented by Formula (2) and a repeating unit represented by Formula (4), 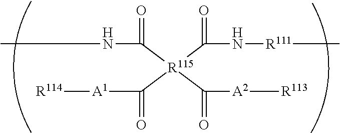
in Formula (2), A¹ and A² each independently represent an oxygen atom or —NR^{z}—, R¹¹¹ represents a divalent organic group, R¹¹⁵ represents a tetravalent organic group, R¹¹³ and R¹¹⁴ each independently represent a hydrogen atom or a monovalent organic group, and R^{z} represents a hydrogen atom or a monovalent organic group, 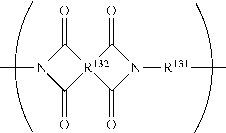
in Formula (4), R¹³¹ represents a divalent organic group, and R¹³² represents a tetravalent organic group.

22. The manufacturing method of a laminate according to claim 20,
wherein the composition for forming the insulating pattern A includes at least one solvent selected from γ-butyrolactone, dimethyl sulfoxide, or N-methyl-2-pyrrolidone.

23. The manufacturing method of a laminate according to claim 20,
wherein the composition for forming the insulating pattern A further includes a polymerizable compound.

24. The manufacturing method of a laminate according to claim 23,
wherein the polymerizable compound includes a compound having two or more ethylenically unsaturated bonds.

25. The manufacturing method of a laminate according to claim 20,
wherein the composition for forming the insulating pattern A further includes a photopolymerization initiator.

26. The manufacturing method of a laminate according to claim 25,
wherein the photopolymerization initiator includes an oxime compound.
